(19) United States
(12) Patent Application Publication
(10) Pub. No.: US 2025/0169175 A1
(43) Pub. Date: May 22, 2025

(54) SEMICONDUCTOR DEVICE

(71) Applicant: Semiconductor Energy Laboratory Co., Ltd., Atsugi-shi, Kanagawa-ken (JP)

(72) Inventors: Yasuharu HOSAKA, Tochigi (JP); Yukinori SHIMA, Tatebayashi (JP); Masami JINTYOU, Shimotsuga (JP); Masataka NAKADA, Tochigi (JP); Junichi KOEZUKA, Tochigi (JP); Kenichi OKAZAKI, Atsugi (JP)

(21) Appl. No.: 18/839,558

(22) PCT Filed: Feb. 21, 2023
(86) PCT No.: PCT/IB2023/051554

§ 371 Date: Aug. 19, 2024

(30) Foreign Application Priority Data
Mar. 4, 2022 (JP) 2022-033435
Mar. 11, 2022 (JP) 2022-038026
Mar. 18, 2022 (JP) 2022-044001
Mar. 31, 2022 (JP) 2022-058775

(51) Int. Cl. H10D 84/85; H10D 30/01; H10D 30/67; H10D 86/01; H10D 86/40; H10D 86/60

(52) U.S. Cl. CPC H10D 84/856; H10D 30/6706; H10D 30/6728; H10D 30/6744; H10D 30/6745; H10D 30/6746; H10D 30/675; H10D 30/6756; H10D 30/6758; H10D 86/471; H10D 86/60; H10D 30/0321; H10D 86/0223

(57) ABSTRACT

A novel semiconductor device is provided. The semiconductor device combines a lateral-channel transistor and a vertical-channel transistor. The lateral-channel transistor is employed as a p-channel transistor and the vertical-channel transistor is employed as an n-channel transistor to achieve a CMOS semiconductor device. An opening is provided in the insulating layer in a region overlapping with a gate electrode of the lateral-channel transistor, and the vertical-channel transistor is formed in the opening. An oxide semiconductor is used for a semiconductor layer of the vertical-channel transistor.

### TECHNICAL FIELD

One embodiment of the invention disclosed in this specification and the like relates to an object, a method, or a manufacturing method. Alternatively, one embodiment of the invention disclosed in this specification and the like relates to a process, a machine, manufacture, or a composition of matter. In particular, the invention relates to a semiconductor device and a method for manufacturing the semiconductor device.

One embodiment of the present invention is not limited to the above technical field. Examples of the technical field of one embodiment of the invention disclosed in this specification and the like include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, an electronic device, and the like themselves are semiconductor devices and also include a semiconductor device.

### BACKGROUND ART

In a display device that is a kind of semiconductor devices, forming at least part of a driver circuit together with a pixel circuit over the same substrate is known as a means for achieving a reduction in weight and a narrow bezel. To achieve a bezel which is further narrowed, downsizing of the driver circuit is required.

The driver circuit is commonly formed using a CMOS (Complementary Metal Oxide Semiconductor) circuit. The CMOS circuit is formed with a combination of n-channel transistors and p-channel transistors and has high design flexibility.

Meanwhile, to achieve a narrower bezel, a driver circuit including only n-channel transistors or p-channel transistors has also been studied. A circuit having such a structure is also referred to as a “circuit having the same conductivity type”. For example, Patent Document 1 discloses a technology in which a shift register is formed using circuits having the same conductivity type.

### REFERENCE

### Patent Document

[Patent Document 1] Japanese Published Patent Application No. 2002-049333

### SUMMARY OF THE INVENTION

### Problems to be Solved by the Invention

An object of one embodiment of the present invention is to provide a semiconductor device that occupies a small area. Another object is to provide a semiconductor device with low power consumption. Another object is to provide a highly reliable semiconductor device. Another object is to provide a novel semiconductor device.

Note that the descriptions of these objects do not disturb the existence of other objects. One embodiment of the present invention does not need to achieve all the objects. Objects other than these will be apparent from the descriptions of the specification, the drawings, the claims, and the like, and objects other than these can be derived from the descriptions of the specification, the drawings, the claims, and the like.

### Means for Solving the Problems

(1) One embodiment of the present invention is a semiconductor device including: a first semiconductor layer provided over an insulating surface; a first insulating layer over the first semiconductor layer; a first conductive layer over the first insulating layer; a second conductive layer electrically connected to part of the first semiconductor layer; a third conductive layer electrically connected to another part of the first semiconductor layer; a second insulating layer covering the first conductive layer, the second conductive layer, and the third conductive layer; a third insulating layer over the second insulating layer; a fourth insulating layer over the third insulating layer; a fourth conductive layer over the fourth insulating layer; an opening penetrating the second insulating layer, the third insulating layer, the fourth insulating layer, and the fourth conductive layer; a second semiconductor layer comprising a region covering a side surface and a bottom portion of the opening; a fifth insulating layer comprising a region overlapping with the side surface of the opening and a region overlapping with the bottom portion of the opening, with the second semiconductor layer therebetween; and a fifth conductive layer comprising a region overlapping with the side surface of the opening and a region overlapping with the bottom portion of the opening, with the second semiconductor layer and the fifth insulating layer therebetween. The second semiconductor layer and the second conductive layer are electrically connected to each other.

In (1), the second semiconductor layer may include a region overlapping with the first semiconductor layer with the second conductive layer therebetween.

(2) Another embodiment of the present invention is a semiconductor device including: a first semiconductor layer provided over an insulating surface; a first insulating layer over the first semiconductor layer; a first conductive layer over the first insulating layer; a second conductive layer electrically connected to the first semiconductor layer; a third conductive layer electrically connected to the first semiconductor layer; a second insulating layer covering the first conductive layer, the second conductive layer, and the third conductive layer; a third insulating layer over the second insulating layer; a fourth insulating layer over the third insulating layer; a fourth conductive layer over the fourth insulating layer; an opening penetrating the second insulating layer, the third insulating layer, the fourth insulating layer, and the fourth conductive layer; a second semiconductor layer comprising a region covering a side surface and a bottom portion of the opening; a fifth insulating layer comprising a region overlapping with the side surface of the opening and a region overlapping with the bottom portion of the opening, with the second semiconductor layer therebetween; and a fifth conductive layer comprising a region overlapping with the side surface of the opening and a region overlapping with the bottom portion of the opening, with the second semiconductor layer and the fifth insulating layer therebetween. The second semiconductor layer and the first conductive layer are electrically connected to each other.

In (1) and (2) above, the second insulating layer preferably contains silicon and nitrogen. The third insulating layer preferably contains silicon and oxygen. The fourth insulating layer preferably contains silicon and nitrogen.

In (1) and (2) above, the first semiconductor layer preferably has a composition different from a composition of the second semiconductor layer. For example, silicon may be used for the first semiconductor layer and an oxide semiconductor may be used for the second semiconductor layer.

In (1) and (2) above, the first semiconductor layer preferably contains one or both of a Group 13 element and a Group 15 element.

The oxide semiconductor preferably contains one or both of indium and zinc.

### Effect of the Invention

One embodiment of the present invention can provide a semiconductor device that occupies a small area. A semiconductor device with low power consumption can be provided. A semiconductor device with high reliability can be provided. A novel semiconductor device can be provided.

Note that the descriptions of these effects do not disturb the existence of other effects. One embodiment of the present invention does not need to have all the effects. Effects other than these will be apparent from the descriptions of the specification, the drawings, the claims, and the like, and effects other than these can be derived from the descriptions of the specification, the drawings, the claims, and the like.

### BRIEF DESCRIPTION OF THE DRAWINGS

FIG. 1A is a top view of a semiconductor device. FIG. 1B is a cross-sectional view of the semiconductor device. FIG. 1C is an equivalent circuit diagram of the semiconductor device. FIG. 1D is a timing chart of the semiconductor device. FIG. 1E illustrates a circuit symbol of an inverter circuit.

FIG. 2 is a cross-sectional view of a semiconductor device.

FIG. 3A is a cross-sectional view of a semiconductor device. FIG. 3B is a top view of an opening. FIG. 3C is a cross-sectional view of the semiconductor device.

FIG. 4A is a top view of a semiconductor device. FIG. 4B is a cross-sectional view of the semiconductor device. FIG. 4C and FIG. 4D are equivalent circuit diagrams of the semiconductor device.

FIG. 5A is a top view of a semiconductor device. FIG. 5B is a cross-sectional view of the semiconductor device. FIG. 5C and FIG. 5D are equivalent circuit diagrams of the semiconductor device.

FIG. 6A is a top view of a semiconductor device. FIG. 6B is a cross-sectional view of the semiconductor device. FIG. 6C and FIG. 6D are equivalent circuit diagrams of the semiconductor device.

FIG. 7A is a top view of a semiconductor device. FIG. 7B is a cross-sectional view of the semiconductor device. FIG. 7C and FIG. 7D are equivalent circuit diagrams of the semiconductor device.

FIG. 8A is a top view of a semiconductor device. FIG. 8B is a cross-sectional view of the semiconductor device. FIG. 8C and FIG. 8D are equivalent circuit diagrams of the semiconductor device.

FIG. 9A is a top view of a semiconductor device. FIG. 9B is a cross-sectional view of the semiconductor device. FIG. 9C and FIG. 9D are equivalent circuit diagrams of the semiconductor device.

FIG. 10A is a top view of a semiconductor device. FIG. 10B is a cross-sectional view of the semiconductor device. FIG. 10C and FIG. 10D are equivalent circuit diagrams of the semiconductor device.

FIG. 11A is a top view of a semiconductor device. FIG. 11B is a cross-sectional view of the semiconductor device. FIG. 11C and FIG. 11D are equivalent circuit diagrams of the semiconductor device.

FIG. 12A is a top view of a semiconductor device. FIG. 12B is a cross-sectional view of the semiconductor device. FIG. 12C and FIG. 12D are equivalent circuit diagrams of the semiconductor device.

FIG. 13A is a top view of a semiconductor device. FIG. 13B is a cross-sectional view of the semiconductor device. FIG. 13C and FIG. 13D are equivalent circuit diagrams of the semiconductor device.

FIG. 14A is a top view of a semiconductor device. FIG. 14B is a cross-sectional view of the semiconductor device. FIG. 14C and FIG. 14D are equivalent circuit diagrams of the semiconductor device.

FIG. 15A to FIG. 15E are diagrams illustrating a method for manufacturing a semiconductor device.

FIG. 16A to FIG. 16D are diagrams illustrating the method for manufacturing a semiconductor device.

FIG. 17A to FIG. 17D are diagrams illustrating the method for manufacturing a semiconductor device.

FIG. 18A to FIG. 18C are diagrams illustrating the method for manufacturing a semiconductor device.

FIG. 19A to FIG. 19C are diagrams illustrating the method for manufacturing a semiconductor device.

FIG. 20A is a perspective view of a display device. FIG. 20B is a block diagram of the display device.

FIG. 21A to FIG. 21F are diagrams illustrating structure examples of logic circuits.

FIG. 22A and FIG. 22B are diagrams illustrating structure examples of a D flip-flop circuit.

FIG. 23 is a diagram illustrating a structure example of a shift register circuit.

FIG. 24A and FIG. 24B are circuit diagrams of latch circuits.

FIG. 25A to FIG. 25D are circuit diagrams of demultiplexer circuits.

FIG. 26A to FIG. 26D are circuit diagrams of pixel circuits.

FIG. 27A to FIG. 27D are circuit diagrams of pixel circuits.

FIG. 28A and FIG. 28B are circuit diagrams of pixel circuits.

FIG. 29A and FIG. 29B are circuit diagrams of pixel circuits.

FIG. 30 is a diagram illustrating a structure example of a pixel circuit.

FIG. 31A to FIG. 31G are diagrams illustrating examples of pixels.

FIG. 32A to FIG. 32K are diagrams illustrating examples of pixels.

FIG. 33A to FIG. 33F are diagrams illustrating structure examples of light-emitting devices.

FIG. 34A to FIG. 34C are diagrams illustrating structure examples of light-emitting devices.

FIG. 35A and FIG. 35B are diagrams illustrating a structure example of a display device.

FIG. 36A to FIG. 36D are diagrams illustrating structure examples of a display device.

FIG. 37A to FIG. 37C are diagrams illustrating structure examples of a display device.

FIG. 38A to FIG. 38D are diagrams illustrating structure examples of a display device.

FIG. 39A to FIG. 39F are diagrams illustrating structure examples of a display device.

FIG. 40A to FIG. 40F are diagrams illustrating structure examples of a display device.

FIG. 41A to FIG. 41F are diagrams illustrating examples of electronic devices.

FIG. 42A to FIG. 42F are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be interpreted as being limited to the description of embodiments below. Note that in the structures of the invention described below, the same portions or portions having similar functions are denoted by the same reference numerals in different drawings, and description thereof is not repeated in some cases.

Furthermore, the position, size, range, and the like of each component illustrated in the drawings and the like do not represent the actual position, size, range, and the like in some cases for easy understanding of the invention. Therefore, the disclosed invention is not necessarily limited to the position, size, range, and the like as disclosed in the drawings and the like. For example, in the actual manufacturing process, a layer, a resist mask, or the like might be unintentionally reduced in size by treatment such as etching, which is not illustrated in some cases for easy understanding of the invention.

Some components might not be illustrated, especially in a top view (also referred to as a “plan view”), a perspective view, or the like, for easy understanding of the invention. In addition, the description of some hidden lines and the like might be omitted.

Ordinal numbers such as “first” and “second” in this specification and the like are used in order to avoid confusion among components and do not denote the priority or the order such as the order of steps or the stacking order. A term without an ordinal number in this specification and the like might be provided with an ordinal number in the scope of claims in order to avoid confusion among components. An ordinal number used in this specification and the like and an ordinal number used in the scope of claims might be different from each other. Furthermore, even when a term is provided with an ordinal number in this specification and the like, the ordinal number might be omitted in the scope of claims and the like.

In this specification and the like, the term such as an “electrode” or a “wiring” does not limit a function of the component. For example, an “electrode” is used as part of a “wiring” in some cases, and vice versa. Furthermore, the term “electrode” or “wiring” can also mean the provision of a plurality of “electrodes” and “wirings” in an integrated manner.

In this specification and the like, in the case where an etching step (a removal step) is performed after a resist mask is formed in a photolithography method, the resist mask is removed after the etching step, unless otherwise specified.

Note that the terms “film” and “layer” can be interchanged with each other depending on the case or circumstances. For example, the term “conductive layer” can be changed into the term “conductive film” in some cases. For another example, the term “insulating film” can be changed into the term “insulating layer” in some cases.

In this specification and the like, a transistor is an element having at least three terminals including a gate, a drain, and a source. In addition, the transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Functions of a “source” and a “drain” of a transistor are sometimes switched when a transistor of opposite polarity is used or when the direction of current flow is changed in circuit operation, for example. Therefore, the terms “source” and “drain” can be used interchangeably in this specification and the like.

Unless otherwise specified, a transistor described in this specification and the like is an enhancement-mode (a normally-off mode) field-effect transistor. In the case where a transistor in this specification and the like is an n-channel transistor and unless otherwise specified, and the threshold voltage (also referred to as “Vth”) of the transistors is higher than 0 V. In the case where the transistor in this specification and the like is a p-channel transistor and unless otherwise specified, the threshold voltage (also referred to as “Vth”) of the transistor is lower than or equal to 0 V.

Unless otherwise specified, off-state current in this specification and the like refers to a drain current (also referred to as “Id”) of a transistor in an off state (also referred to as a non-conducting state or a cutoff state). Unless otherwise specified, the off state of an n-channel transistor refers to a state where the potential difference between its gate and source based on the source (also referred to as “gate voltage” or “Vg”) is lower than the threshold voltage, and the off state of a p-channel transistor refers to a state where Vg is higher than the threshold voltage. For example, the off-state current of an n-channel transistor sometimes refers to a drain current at the time when Vg is lower than Vth.

In this specification and the like, leakage current sometimes expresses the same meaning as off-state current. Furthermore, in this specification and the like, the off-state current sometimes refers to current that flows between a source and a drain of a transistor in an off state, for example.

In this specification and the like, a high power supply potential VDD (hereinafter also simply referred to as VDD or a potential H) is a power supply potential higher than a low power supply potential VSS. The low power supply potential VSS (hereinafter also simply referred to as VSS or a potential L) is a power supply potential lower than the high power supply potential VDD. In addition, a ground potential GND (also simply referred to as “GND”) can be used as VDD or VSS. For example, VSS is a potential lower than GND when VDD is GND, and VDD is a potential higher than GND when VSS is GND.

A “voltage” usually refers to a potential difference between a given potential and a reference potential (e.g., a ground potential or a source potential). A “potential” is a relative value, and a potential supplied to a wiring or the like changes depending on the reference potential in some cases. Therefore, the terms “voltage” and “potential” can be replaced with each other in some cases. Note that in this specification and the like, VSS is the reference voltage unless otherwise specified.

In this specification and the like, terms for describing arrangement, such as “over”, “above”, “under”, and “below”, are sometimes used for convenience to describe the positional relation between components with reference to drawings. The positional relation between components is changed as appropriate in accordance with the direction from which each component is described. Thus, the positional relation is not limited to that described with a term used in this specification and the like and can be explained with another term as appropriate depending on the situation. For example, the expression “an insulator over (on) a top surface of a conductor” can be replaced with the expression “an insulator on a bottom surface of a conductor” when the direction of a diagram showing these components is rotated by 180°.

Note that the term “over” or “below” does not necessarily mean that a component is placed “directly over” or “directly below” and “directly in contact with” another component. For example, the expression “electrode B over insulating layer A” does not necessarily mean that the electrode B is on and in direct contact with the insulating layer A and can mean the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and includes the case where the electrode B is formed under the insulating layer A and the case where the electrode B is formed on the right (or left) side of the insulating layer A.

The terms “adjacent” and “close” in this specification and the like do not necessarily mean that a component is directly in contact with another component. For example, the expression “electrode B adjacent to insulating layer A” does not necessarily mean that the electrode B is formed in direct contact with the insulating layer A and can mean the case where another component is provided between the insulating layer A and the electrode B.

In this specification, the “parallel” indicates that the angle formed between two straight lines is greater than or equal to −10° and less than or equal to 10°. Thus, the case where the angle is greater than or equal to −5° and less than or equal to 5° is also included. The terms “approximately parallel” and “substantially parallel” indicate that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. The terms “approximately perpendicular” and “substantially perpendicular” indicate that the angle formed between two straight lines is greater than or equal to 60° and less than or equal to 120°.

In this specification and the like, the terms “identical”, “the same”, “equal”, “uniform”, or the like (including synonyms thereof) used in describing calculation values and measurement values contain an error of ±20% unless otherwise specified.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, a conductive layer 108 is described as a conductive layer 108a and a conductive layer 108b in some cases.

### Embodiment 1

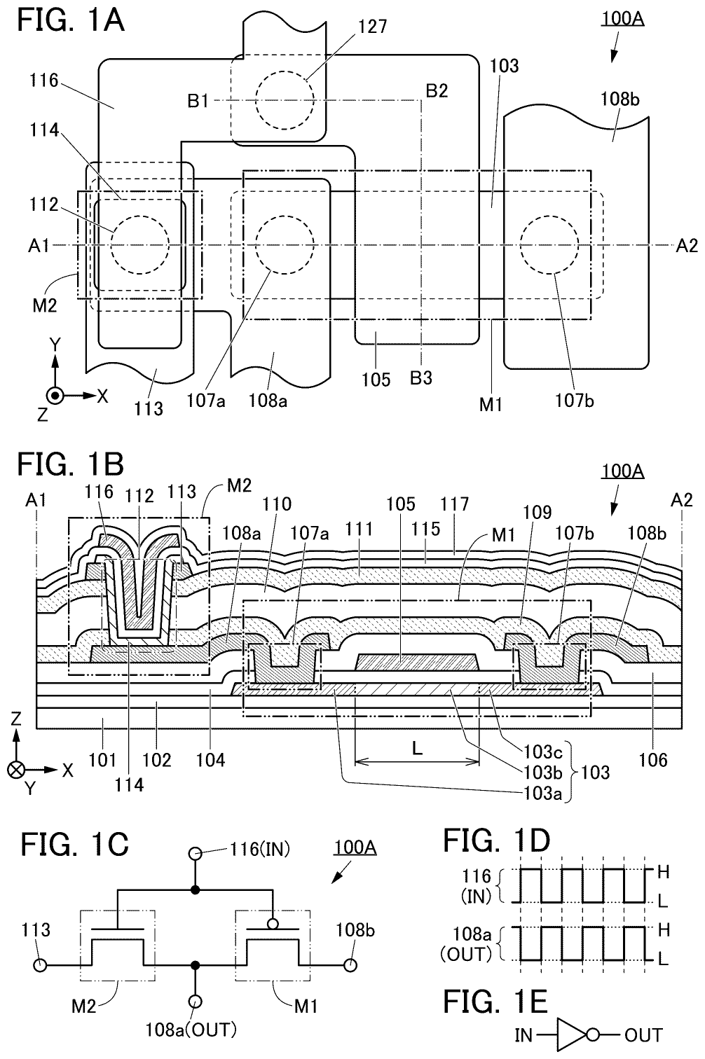

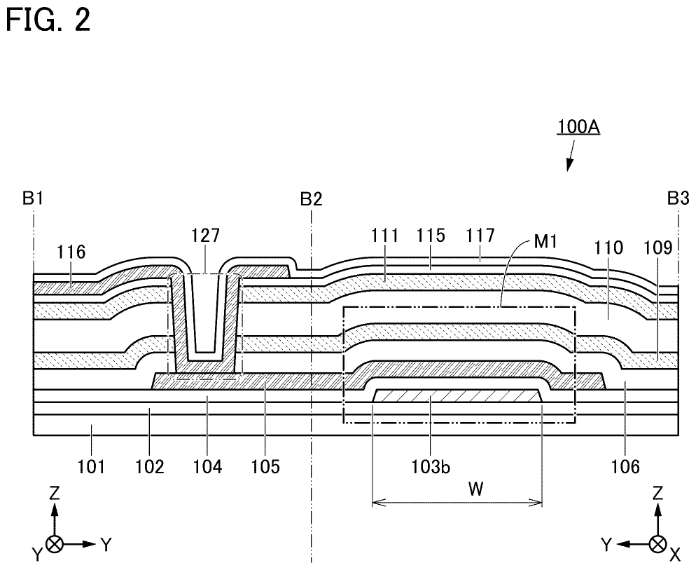

A semiconductor device 100A of one embodiment of the present invention will be described. FIG. 1A is a top view of the semiconductor device 100A. FIG. 1B is a cross-sectional schematic view of a portion indicated by the dashed-dotted line A1-A2 in FIG. 1A. FIG. 1C is an equivalent circuit diagram of the semiconductor device 100A. FIG. 2 is a cross-sectional schematic view of a portion indicated by the dashed-dotted line B1-B2-B3 in FIG. 1A. Note that in FIG. 1A, some components such as an insulating layer are not illustrated for easy understanding of the structure of the semiconductor device.

### Structure Example

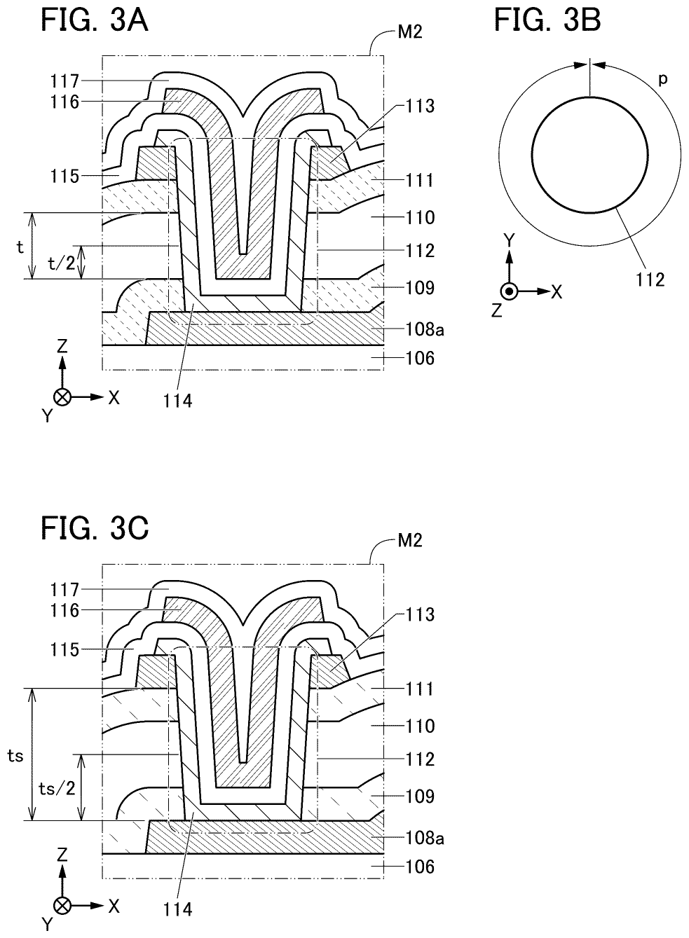

The semiconductor device 100A includes a transistor M1 and a transistor M2. The transistor M1 is a p-channel transistor, and the transistor M2 is an n-channel transistor. FIG. 3A and FIG. 3C are enlarged views of the transistor M2 illustrated in FIG. 1B. FIG. 3B is a view of an opening 112 seen from the Z direction.

The semiconductor device 100A includes an insulating layer 102 over a substrate 101 and a semiconductor layer 103 over the insulating layer 102. An insulating layer 104 is provided over the insulating layer 102 and the semiconductor layer 103. A conductive layer 105 is provided over the insulating layer 104. The semiconductor layer 103 and the conductive layer 105 have an overlapping region.

An insulating layer 106 is provided over the insulating layer 104 and the conductive layer 105. The insulating layer 104 and the insulating layer 106 are provided with an opening 107a in a region overlapping with part of the semiconductor layer 103. The insulating layer 104 and the insulating layer 106 are provided with an opening 107b in a region overlapping with another part of the semiconductor layer 103.

The conductive layer 108a is provided over the insulating layer 106 and the opening 107a, and the conductive layer 108b is provided over the insulating layer 106 and the opening 107b. The conductive layer 108a is electrically connected to the semiconductor layer 103 in the opening 107a. The conductive layer 108b is electrically connected to the semiconductor layer 103 in the opening 107b.

The semiconductor layer 103 includes a drain region 103a, a channel formation region 103b, and a source region 103c. The region in the semiconductor layer 103 overlapping with the conductive layer 105 functions as the channel formation region 103b. Thus, the length of the channel formation region 103b in the X direction is the channel length L of the transistor M1 (see FIG. 1B). The length of the channel formation region 103b in the Y direction is the channel width W of the transistor M1 (see FIG. 2).

The drain region 103a is electrically connected to the conductive layer 108a, and the source region 103c is electrically connected to the conductive layer 108b.

An insulating layer 109 is provided over the insulating layer 106, the conductive layer 108a, and the conductive layer 108b, an insulating layer 110 is provided over the insulating layer 109, and an insulating layer 111 is provided over the insulating layer 110. A conductive layer 113 is provided over the insulating layer 111.

In a region overlapping with part of the conductive layer 108a, the opening 112 is provided in the conductive layer 113, the insulating layer 111, the insulating layer 110, and the insulating layer 109 (see FIG. 1B and FIG. 3A). A semiconductor layer 114 is provided over the opening 112. The semiconductor layer 114 includes a region overlapping with a bottom portion of the opening 112 and a region overlapping with a side surface of the opening 112. A part of the semiconductor layer 114 is electrically connected to the conductive layer 113, and another part of the semiconductor layer 114 is electrically connected to the conductive layer 108a.

An insulating layer 115 is provided over the insulating layer 111, the conductive layer 113, and the semiconductor layer 114, and a conductive layer 116 is provided over the insulating layer 115. An insulating layer 117 is provided over the insulating layer 115 and the conductive layer 116. The insulating layer 115 includes a region overlapping with the side surface of the opening 112 with the semiconductor layer 114 therebetween. The conductive layer 116 includes a region overlapping with the side surface of the opening 112 with the insulating layer 115 and the semiconductor layer 114 therebetween.

In a region overlapping with the conductive layer 105, an opening 127 is provided in the insulating layer 115, the insulating layer 111, the insulating layer 110, the insulating layer 109, and the insulating layer 106. In the opening 127, the conductive layer 105 and the conductive layer 116 are electrically connected to each other.

The semiconductor layer 103 functions as a semiconductor layer of the transistor M1 where a channel is formed; the insulating layer 104 functions as a gate insulating layer; and the conductive layer 105 functions as a gate electrode. The conductive layer 108a functions as a drain electrode of the transistor M1 and the conductive layer 108b functions as a source electrode thereof.

The semiconductor layer 114 functions as a semiconductor layer of the transistor M2 where a channel is formed; the insulating layer 115 functions as a gate insulating layer; and the conductive layer 116 functions as a gate electrode. The conductive layer 108a functions as a drain electrode of the transistor M2 and the conductive layer 113 functions as a source electrode thereof. The transistor M2 is provided in a region including the opening 112.

Since the source electrode and the drain electrode of the transistor M2 are placed in the Z direction, Id flows in the Z direction (the vertical direction). In other words, Id flows in the direction perpendicular or substantially perpendicular to the surface of the substrate 101. A transistor in which Id flows in the vertical direction is also referred to as a “vertical-channel transistor”

Since the source electrode and the drain electrode of the transistor M1 are placed in the X direction, Id flows in the X direction (the lateral direction). In other words, Id flows in the direction parallel or substantially parallel to the surface of the substrate 101. A transistor in which Id flows in the lateral direction is also referred to as a “lateral-channel transistor”. Note that a transistor in which Id flows in the Y direction is also referred to as a “lateral-channel transistor”.

Since the source electrode and the drain electrode of a vertical-channel transistor are provided in the Z direction, the area occupied by the vertical-channel transistor can be significantly reduced than that by a lateral-channel transistor.

Here, materials that can be used for the semiconductor device or the like of one embodiment of the present invention are described.

### [Substrate]

There is no particular limitation on a material used for the substrate. The material is determined in accordance with the purpose in consideration of whether it has a light-transmitting property, heat resistance high enough to withstand heat treatment, or the like. For example, a glass substrate of barium borosilicate glass, aluminoborosilicate glass, or the like; a ceramic substrate; a quartz substrate; a sapphire substrate; or the like can be used. Alternatively, a semiconductor substrate, a flexible substrate, an attachment film, a base film, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. For the semiconductor substrate, a single crystal semiconductor or a polycrystalline semiconductor may be used.

When the semiconductor device of one embodiment of the present invention is used for a display device, a large-sized glass substrate of the 6th generation (1500 mm×1850 mm), the 7th generation (1870 mm×2200 mm), the 8th generation (2200 mm×2400 mm), the 9th generation (2400 mm×2800 mm), or the 10th generation (2950 mm×3400 mm), for example, can be used. Thus, a large-sized display device can be manufactured. With the increase in substrate size, a larger number of display devices can be produced from one substrate, which can reduce production cost.

In order to increase the flexibility of the semiconductor device, a flexible substrate, an attachment film, a base film, or the like may be used as the substrate.

As the materials of the flexible substrate, the attachment film, the base film, and the like, for example, polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, cycloolefin, polystyrene, polyamide imide, polyurethane, polyvinyl chloride, polyvinylidene chloride, polypropylene, polytetrafluoroethylene (PTFE), an ABS resin, cellulose nanofiber, or the like can be used.

When the above-described material is used for the substrate, a lightweight semiconductor device can be provided. Furthermore, when the above-described material is used for the substrate, a shock-resistant semiconductor device can be provided. Moreover, when the above-described material is used for the substrate, a semiconductor device that is less likely to be broken can be provided.

The flexible substrate used as the substrate preferably has a lower coefficient of linear expansion because deformation due to an environment is inhibited. For the flexible substrate used as the substrate, for example, a material whose coefficient of linear expansion is lower than or equal to 1×10⁻³/K, lower than or equal to 5×10⁻⁵/K, or lower than or equal to 1×10⁻⁵/K is used. In particular, aramid is suitable for the flexible substrate because of its low coefficient of linear expansion.

### [Conductive Layer]

As a conductive material that can be used for the gate electrode, the source electrode, and the drain electrode of the transistor and conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), and the like; an alloy containing the above metal element as a component; an alloy containing the above metal elements in combination; or the like can be used. Alternatively, a semiconductor typified by polycrystalline silicon containing an impurity element such as phosphorus, or silicide such as nickel silicide may be used. There is no particular limitation on the formation method of the conductive material, and a variety of formation methods such as an evaporation method, a CVD method, a sputtering method, and a spin coating method can be employed.

A Cu—X alloy (X is Mn, Ni, Cr, Fe, Co, Mo, Ta, or Ti) may be used as the conductive material. A layer formed using a Cu—X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added, can be used. Moreover, a conductive material containing nitrogen, such as titanium nitride, tantalum nitride, or tungsten nitride, can be used. In addition, a stacked-layer structure in which a conductive material containing oxygen, a conductive material containing nitrogen, and a material containing the above-described metal element are combined as appropriate can be used for the conductive layer.

For example, the conductive layer may have a single layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure including a titanium layer, an aluminum layer stacked over the titanium layer, and a titanium layer stacked thereover.

A plurality of conductive layers formed using the above-described materials may be stacked and used. The conductive layer may have a stacked-layer structure in which a material containing the above-described metal element and a conductive material containing oxygen are combined, for example. Alternatively, a stacked-layer structure in which a material containing the above-described metal element and a conductive material containing nitrogen are combined may be used. Alternatively, a stacked-layer structure in which a material containing the above-described metal element, a conductive material containing oxygen, and a conductive material containing nitrogen are combined may be used.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

### [Insulating Layer]

For each of the insulating layers, a single layer or a stack layer of materials selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like. A material in which a plurality of materials selected from an oxide material, a nitride material, an oxynitride material, and a nitride oxide material are mixed may be used.

Note that in this specification and the like, a nitride oxide refers to a material that contains more nitrogen than oxygen. An oxynitride refers to a material that contains more oxygen than nitrogen. The content of each element can be measured by Rutherford backscattering spectrometry (RBS), for example.

For example, it is preferable that the insulating layer 102 and the insulating layer 117 be formed using an insulating material through which impurities are less likely to pass. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of the insulating material through which impurities are less likely to pass include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities are less likely to pass is used for the insulating layer 102, impurity diffusion from the substrate 101 side can be inhibited, and the reliability of the semiconductor device can be improved. When the insulating material through which impurities are less likely to pass is used for the insulating layer 117, impurity diffusion from the above the insulating layer 117 can be inhibited, and the reliability of the semiconductor device can be improved.

In the case where an oxide semiconductor is used for the semiconductor layer 114, an insulating material through which impurities are less likely to pass is preferably used for the insulating layer 106. When the insulating material through which impurities are less likely to pass is used for the insulating layer 106, impurity diffusion from a component below the insulating layer 106 can be inhibited, and the reliability of the semiconductor device can be improved.

As the insulating layer, an insulating layer that can function as a planarization layer may be used. The insulating layer that can function as a planarization layer can be formed using an organic material having heat resistance, such as polyimide, an acrylic resin, a benzocyclobutene resin, polyamide, or an epoxy resin. Other than such organic materials, it is also possible to use a low-dielectric constant material (a low-k material), a siloxane resin, PSG (phosphosilicate glass), BPSG (borophosphosilicate glass), or the like. Note that a plurality of insulating layers formed of these materials may be stacked.

Note that the siloxane resin corresponds to a resin including a Si—O—Si bond formed using a siloxane-containing material as a starting material. The siloxane resin may include an organic group (e.g., an alkyl group or an aryl group) or a fluoro group as a substituent. In addition, the organic group may include a fluoro group.

A surface of the insulating layer or the like may be subjected to CMP treatment. By the CMP treatment, unevenness of a sample surface can be reduced, and coverage with an insulating layer or a conductive layer formed later can be increased.

### [Semiconductor Layer]

For the semiconductor layer 103 and the semiconductor layer 114, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, or a nitride semiconductor may be used. As the compound semiconductor, an organic substance having semiconductor characteristics or a metal oxide having semiconductor characteristics (also referred to as an oxide semiconductor) can be used. These semiconductor materials may contain an impurity as a dopant.

An oxide semiconductor has a band gap of 2 eV or more; thus, a transistor using an oxide semiconductor, which is a kind of metal oxide, used for a semiconductor layer where a channel is formed (also referred to as an “OS transistor”) has an extremely low off-state current. Thus, the power consumption of the semiconductor device 100A can be reduced. The OS transistor operates stably even in a high-temperature environment and has small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. Therefore, the semiconductor device including the OS transistor can operate stably and have high reliability even in a high-temperature environment.

Meanwhile, it is difficult to achieve a p-channel OS transistor. In the case where a CMOS circuit is formed with an OS transistor, a p-channel transistor formed with another semiconductor material is preferably combined with the OS transistor.

In this embodiment, a transistor using silicon in a semiconductor layer where a channel is formed (also referred to as a “Si transistor”) is used as the transistor M1. When a p-type semiconductor is used for the drain region 103a and the source region 103c of the semiconductor layer 103, the transistor M1 is used as a p-channel transistor.

As silicon that is used for the semiconductor layer, single crystal silicon, polycrystalline silicon, microcrystalline silicon, and amorphous silicon can be given. As the polycrystalline silicon, low-temperature polysilicon (LTPS) can be given, for example.

The transistor including amorphous silicon in the semiconductor layer can be formed over a large glass substrate, and can be manufactured at low cost. The transistor including polycrystalline silicon in the semiconductor layer has high field-effect mobility and enables high-speed operation. The transistor including microcrystalline silicon in the semiconductor layer has higher field-effect mobility and enables higher speed operation than the transistor including amorphous silicon.

In this embodiment, an OS transistor is used as the transistor M2. Since an OS transistor has a high breakdown voltage between the source and the drain, the channel length can be shortened. Thus, the on-state current can be increased.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three kinds selected from indium, an element M, and zinc. The element Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more kinds selected from aluminum, gallium, yttrium, and tin.

For example, any of indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide), and indium gallium aluminum zinc oxide (In—Ga—Al—Zn oxide, also referred to as IGAZO or IAGZO) can be used. Alternatively, indium tin oxide containing silicon, or the like can also be used.

In particular, the element M is preferably one or more kinds selected from gallium, aluminum, yttrium, and tin. In particular, gallium is preferable as the element M.

Here, the composition of the metal oxide that is used for the semiconductor layer greatly affects the electrical characteristics and reliability of the OS transistor.

For example, higher indium content percentage in the metal oxide enables the transistor to have a high on-state current.

In the case of using In—Zn oxide for the semiconductor layer of the OS transistor, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case of using In—Sn oxide for the semiconductor layer of the OS transistor, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In—Sn—Zn oxide for the semiconductor layer of the OS transistor, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In—Al—Zn oxide for the semiconductor layer of the OS transistor, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In—Ga—Zn oxide for the semiconductor layer of the OS transistor, a metal oxide in which the proportion of the number of indium atoms in the number of atoms of the metal elements is higher than the proportion of the number of gallium atoms can be used. It is further preferable to use a metal oxide in which the proportion of the number of zinc atoms is higher than the proportion of the number of gallium atoms. For example, a metal oxide having any of the following atomic ratios of metal elements can be used for the semiconductor layer: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

In the case of using In-M-Zn oxide for the semiconductor layer of the OS transistor, a metal oxide in which the proportion of the number of indium atoms in the number of atoms of the metal elements is higher than the proportion of the number of element M atoms can be used. It is further preferable to use a metal oxide in which the proportion of the number of zinc atoms is higher than the proportion of the number of element M atoms. For example, a metal oxide having any of the following atomic ratios of metal elements can be used for the semiconductor layer: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the neighborhood thereof.

In the case where a plurality of metal elements are contained as the element M, the sum of the proportions of the numbers of atoms of the metal elements can be the proportion of the number of element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of element M atoms. The atomic ratio of indium to the element M to zinc is preferably within the ranges given above.

It is preferable to use a metal oxide in which the proportion of the number of indium atoms in the number of atoms of the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case of using In—Ga—Zn oxide for the semiconductor layer, the proportion of the number of indium atoms in the sum of the numbers of atoms of indium, the element M, and zinc is preferably within the ranges given above.

In this specification and the like, the proportion of the number of indium atoms in the number of atoms of the contained metal elements is sometimes referred to as indium content percentage. The same applies to other metal elements.

Higher indium content percentage in the metal oxide enables the transistor to have a high on-state current. With use of the transistor, a circuit capable of high-speed operation can be fabricated. Furthermore, the area occupied by the circuit can be reduced. The application of the transistor to a large display device or a high-definition display device can reduce signal delay in wirings and reduce display unevenness even if the number of wirings is increased, for example. In addition, since the area occupied by the circuit can be reduced, the bezel of the display device can be narrowed.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has a low gallium content percentage in the semiconductor layer, the transistor can be highly reliable against positive bias application. In other words, the amount of change in the threshold voltage of the transistor in the PBTS test can be small. Meanwhile, with use of a metal oxide that contains gallium, the gallium content percentage is preferably lower than the indium content percentage. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide film containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where In—Ga—Zn oxide is used for the semiconductor layer, a metal oxide in which the atomic proportion of indium is higher than the atomic proportion of gallium can be used for the semiconductor layer. It is further preferable to use a metal oxide in which the atomic proportion of zinc is higher than the atomic proportion of gallium. In other words, a metal oxide in which the atomic proportions of metal elements satisfy In >Ga and Zn>Ga is preferably used for the semiconductor layer.

For example, a metal oxide having any of the following atomic ratios of metal elements can be used for the semiconductor layer of the OS transistor: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

The semiconductor layer of the OS transistor is preferably formed using a metal oxide having the following compositions; the proportion of the number of gallium atoms in the number of atoms of the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that oxygen vacancy (Vo) is less likely to be generated in the metal oxide when the metal oxide contains gallium.

A metal oxide not containing gallium may be used for the semiconductor layer of the OS transistor. For example, In—Zn oxide can be used for the semiconductor layer. In this case, when the ratio of the number of indium atoms in the number of atoms of the metal elements contained in the metal oxide is increased, the field-effect mobility of the transistor can be increased. By contrast, when the ratio of the number of zinc atoms in the number of atoms of the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer. The use of a metal oxide not containing gallium can make a change in the threshold voltage particularly in the PBTS test extremely small.

For example, an oxide containing indium and zinc can be used for the semiconductor layer. In that case, for example, a metal oxide where the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer. Furthermore, a metal oxide in which the atomic proportion of zinc is higher than the atomic proportion of the element M is preferably used.

The use of a metal oxide having a low content percentage of the element M for the semiconductor layer enables the transistor to be highly reliable against positive bias application. With use of the transistor as a transistor that is required to have high reliability against positive bias application, a highly reliable semiconductor device can be provided.

Next, the reliability of a transistor against light is described.

Light irradiation on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content percentage of the element M in the metal oxide used for the semiconductor layer enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide included in the semiconductor layer is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, the semiconductor layer can include a metal oxide having any of the following atomic ratios: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer, in particular, it is preferable to use a metal oxide in which the proportion of the number of element M atoms in the number of atoms of the contained metal elements is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

In the case where In—Ga—Zn oxide is used for the semiconductor layer, a metal oxide in which the ratio of the number of indium atoms in the number of atoms of the contained metal elements is lower than or equal to the ratio of the number of gallium atoms can be used. For example, it is possible to use a metal oxide having any of the following atomic ratios: In:Ga:Zn=1:1:1, In:Ga:Zn=1:1:1.2, In:Ga:Zn=1:3:2, In:Ga:Zn=1:3:3, In:Ga:Zn=1:3:4, and the neighborhood thereof.

For the semiconductor layer, in particular, it is preferable to use a metal oxide in which the proportion of the number of gallium atoms in the number of atoms of the contained metal elements is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, further preferably higher than or equal to 40 atomic % and lower than or equal to 60 atomic %, further preferably higher than or equal to 50 atomic % and lower than or equal to 60 atomic %.

The use of a metal oxide having a high content percentage of the element M for the semiconductor layer enables the transistor to be highly reliable against light. With use of the transistor as a transistor that is required to have high reliability against light, a highly reliable semiconductor device can be provided.

As described above, electrical characteristics and reliability of a transistor depend on the composition of the metal oxide used for the semiconductor layer. Therefore, by determining the composition of the metal oxide in accordance with the electrical characteristics and reliability required for the transistor, the display device can have both good electrical characteristics and high reliability.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which enables the display device to have high reliability.

The higher the crystallinity of the metal oxide layer used as the semiconductor layer is, the lower the density of defect states in the semiconductor layer can be. By contrast, the use of a metal oxide layer having low crystallinity enables a transistor to flow a large amount of current.

In the case where a metal oxide layer is formed by a sputtering method, the crystallinity of the metal oxide layer can be increased as the substrate temperature (the stage temperature) in formation is higher. The crystallinity of the metal oxide layer can be increased as the proportion of a flow rate of an oxygen gas to the whole formation gas (also referred to as oxygen flow rate ratio) used in formation is higher.

The semiconductor layer of the OS transistor may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer may have different compositions.

The channel length L of the transistor M2 described in this embodiment is determined by the thickness of an insulating layer provided between the conductive layer 113 and the conductive layer 108a. Thus, a transistor with a short channel length can be formed with high accuracy. Furthermore, variations in characteristics among the transistors M2 are also reduced. Accordingly, the operation of a semiconductor device including the transistor M2 can be stabilized and the reliability thereof can be improved. When the variations in characteristics is reduced, the circuit design flexibility of the semiconductor device is increased and the operation voltage can be reduced. As a result, power consumption of the semiconductor device can also be reduced.

In the case where an oxide semiconductor is used for the semiconductor layer 114, a material containing hydrogen is preferably used for the insulating layer 109 and the insulating layer 111. When the insulating layer containing hydrogen is in contact with the oxide semiconductor, the oxide semiconductor becomes n-type and can function as a source region or a drain region. For example, silicon nitride containing hydrogen or silicon nitride oxide containing hydrogen may be used.

In the case where an oxide semiconductor is used for the semiconductor layer 114, a conductive material that makes the oxide semiconductor have n-type conductivity is preferably used for the conductive layer 108 in contact with the semiconductor layer 114 and the conductive layer 113 in contact with the semiconductor layer 114. For example, a conductive material containing nitrogen may be used. For example, a conductive material containing nitrogen and titanium or tantalum may be used. Another conductive material may be provided so as to overlap with the conductive material containing nitrogen.

In contrast, for the insulating layer 110, a material which contains oxygen and in which the amount of hydrogen is reduced is preferably used. For example, silicon oxide (SiOx) may be used. Since hydrogen is an impurity element in an oxide semiconductor, when the semiconductor layer 114, which is an oxide semiconductor, and the insulating layer 110, in which the amount of hydrogen is reduced, are in contact with each other, the semiconductor layer 114 is less likely to become n-type. Furthermore, when the semiconductor layer 114, which is an oxide semiconductor, and the insulating layer 110 containing oxygen are in contact with each other, oxygen vacancies in the semiconductor layer 114 are reduced and the transistor M2 has stable characteristics, improving the reliability.

When an oxide semiconductor is used for the semiconductor layer 114, the insulating layer 110 preferably contains excess oxygen. In this specification and the like, oxygen that is released by heating is referred to as excess oxygen. In the case where a material containing excess oxygen is used for the insulating layer 110, a material through which oxygen is less likely to pass is preferably used for the insulating layer 109 and the insulating layer 111. Examples of the material through which oxygen is less likely to pass include a nitride of silicon and an oxide containing aluminum and/or hafnium. With the use of the material through which oxygen is less likely to pass for the insulating layer 109 and the insulating layer 111, excess oxygen contained in the insulating layer 110 is less likely to be released to a lower layer or an upper layer. Thus, sufficient oxygen can be supplied to the oxide semiconductor.

In the case where an oxide semiconductor is used for the semiconductor layer 114, the thickness t of the insulating layer 110 corresponds to the channel length L of the transistor M2 (see FIG. 3A). Since the semiconductor layer 114 is provided in the opening 112, the length p of the outer perimeter of the opening 112 corresponds to the channel width W of the transistor M2 (see FIG. 3B). Specifically, the length p of the outer perimeter at the position of half (t/2) of the thickness t of the insulating layer 110 corresponds to the channel width W of the transistor M2. Note that the length p of the outer perimeter of the opening 112 at an arbitrary position may be regarded as the channel width W as necessary. For example, the length p of the outer perimeter at the lowest portion of the opening 112 may be regarded as the channel width W, or the length p of the outer perimeter at the uppermost portion may be regarded as the channel width W.

A material that contains no hydrogen or an extremely small amount of hydrogen may be used for the insulating layer 109 and the insulating layer 111. For example, silicon nitride that contains an extremely small amount of hydrogen or silicon nitride oxide that contains an extremely small amount of hydrogen may be used. In that case, the region of the semiconductor layer 114 in contact with the insulating layer 109 and the region of the semiconductor layer 114 in contact with the insulating layer 111 do not have n-type conductivity. In that case, a thickness ts obtained by combining the thicknesses of the insulating layer 109, the insulating layer 110, and the insulating layer 111 corresponds to the channel length L of the transistor M2 (see FIG. 3C). Furthermore, the length p of the outer perimeter at the position of half (ts/2) of the thickness ts corresponds to the channel width W of the transistor M2.

When materials with different compositions are used for the semiconductor layers of the transistor M1 and the transistor M2 as described above, a CMOS circuit that occupies a smaller area can be achieved. That is, a semiconductor device that occupies a smaller area can be achieved. A CMOS circuit with reduced power consumption can be achieved. That is, a semiconductor device with reduced power consumption can be achieved. In addition, a CMOS circuit with a small variation in characteristics and high reliability can be achieved. That is, a semiconductor device with a small variation in characteristics and high reliability can be achieved.

The semiconductor device 100A illustrated in FIG. 1 functions as a CMOS inverter circuit (also referred to as an “inverter circuit” or a “NOT circuit”) in which the conductive layer 116 serves as an input terminal (IN) and the conductive layer 108a serves as an output terminal (OUT) by supplying the potential L (VSS) to the conductive layer 113 and supplying the potential H (VDD) to the conductive layer 108b (see FIG. 1C). The inverter circuit outputs the potential L from the output terminal when the potential H is input to the input terminal, and outputs the potential H from the output terminal when the potential L is input to the input terminal. FIG. 1D is a timing chart showing an operation example of the semiconductor device 100A functioning as an inverter circuit. FIG. 1E illustrates a circuit symbol of an inverter circuit.

### Modification Example 1

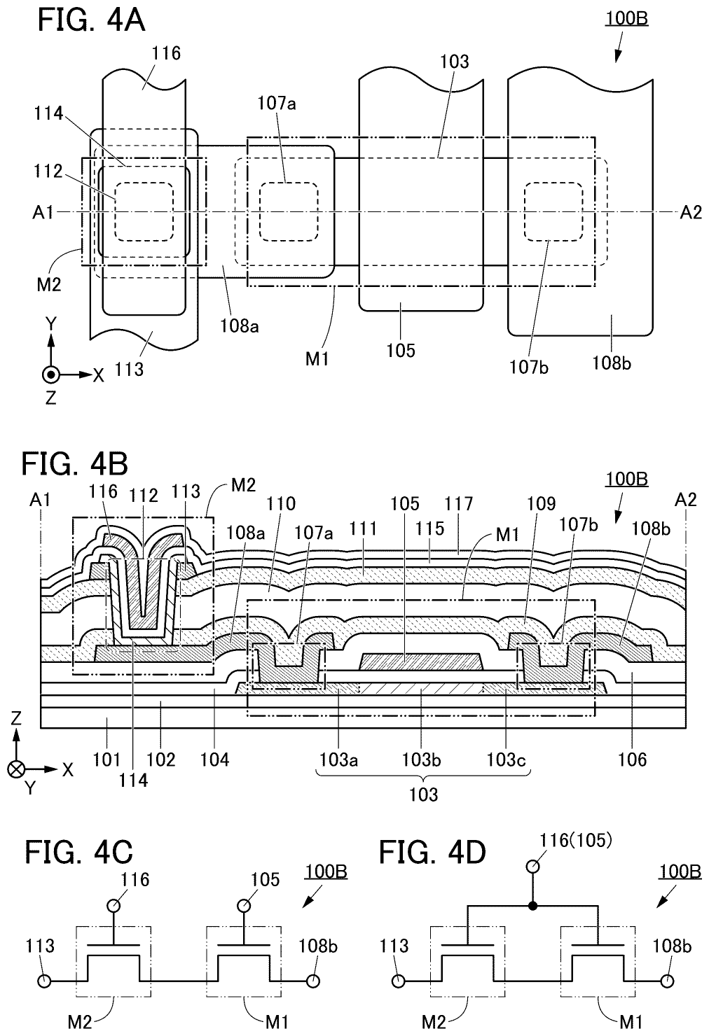

A semiconductor device 100B, which is a modification example of the semiconductor device 100A, is described. In order to reduce repeated description, differences of the semiconductor device 100B from the semiconductor device 100A are mainly described. FIG. 4A is a top view of the semiconductor device 100B. FIG. 4B is a cross-sectional schematic view of a portion indicated by the dashed-dotted line A1-A2 in FIG. 4A. FIG. 4C is an equivalent circuit diagram of the semiconductor device 100B.

An n-channel transistor may be used as the transistor M1. When an n-type semiconductor is used for the drain region 103a and the source region 103c of the semiconductor layer 103, the transistor M1 can have n-channel conductivity. In the semiconductor device 100B, an n-channel transistor is used as the transistor M1.

An LDD (Lightly Doped Drain) region may be provided between the drain region 103a and the channel formation region 103b in the semiconductor layer 103. Providing the LDD region can reduce the electric field between the gate and the drain and reduce the degradation of the characteristics of the transistor M1.

Note that in a transistor in which a source and a drain are switched depending on circuit operation, an LDD region is provided not only between the drain region 103a and the channel formation region 103b but also between the source region 103c and the channel formation region 103b.

Although the semiconductor device 100B illustrated in FIG. 4A to FIG. 4C is an example in which gate electrodes of the transistor M1 and the transistor M2 are not electrically connected to each other, the gate electrodes may be electrically connected to each other. FIG. 4D is an equivalent circuit diagram of the semiconductor device 100B in which the gate electrodes of the transistor M1 and the transistor M2 are electrically connected to each other.

When the gate electrodes of the transistor M1 and the transistor M2 are electrically connected to each other, the transistor M1 and the transistor M2 can function as substantially one transistor. With such a structure, the withstand voltage between the source and the drain can be increased. In addition, the off-state current can be reduced.

### Modification Example 2

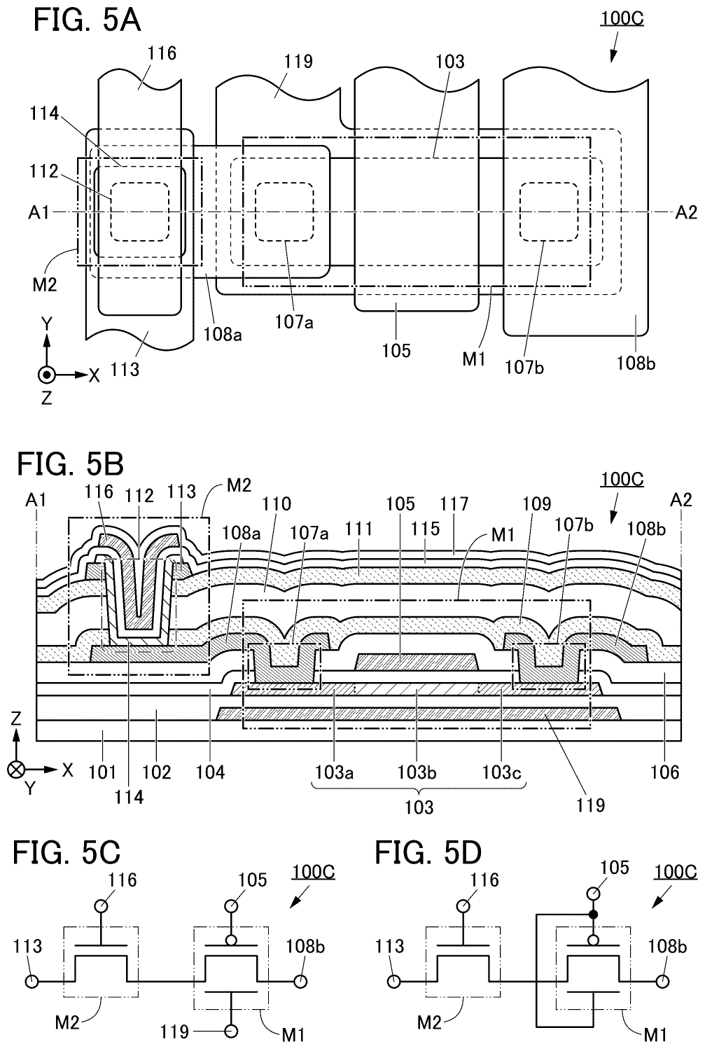

A semiconductor device 100C, which is a modification example of the semiconductor device 100A and the semiconductor device 100B, is described. In order to reduce repeated description, differences of the semiconductor device 100C from the semiconductor device 100A and the semiconductor device 100B are mainly described. FIG. 5A is a top view of the semiconductor device 100C. FIG. 5B is a cross-sectional schematic view of a portion indicated by the dashed-dotted line A1-A2 in FIG. 5A. FIG. 5C and FIG. 5D are equivalent circuit diagrams of the semiconductor device 100C.

The semiconductor device 100C is different from the semiconductor device 100A and the semiconductor device 100B in that a conductive layer 119 is provided between the substrate 101 and the insulating layer 102. The conductive layer 119 functions as a back gate electrode of the transistor M1. Accordingly, it is preferable that the conductive layer 119 overlap with the channel formation region 103b and extend beyond the end portion of the channel formation region 103b. That is, the conductive layer 119 is preferably larger than the channel formation region 103b. The conductive layer 119 preferably extends beyond the end portion of the semiconductor layer 103. That is, the conductive layer 119 is preferably larger than the semiconductor layer 103.

The back gate electrode is positioned so that the channel formation region of the semiconductor layer is sandwiched between the gate electrode and the back gate electrode. By changing the potential of the back gate electrode, the threshold voltage of the transistor can be changed. The potential of the back gate electrode may be a ground potential or a freely selected potential.

The back gate electrode is formed using a conductive layer and can function in a manner similar to that of the gate electrode. For example, the back gate electrode may have the same potential as the gate electrode. FIG. 5D is an equivalent circuit diagram in the case where the back gate electrode and the gate electrode of the transistor M1 are electrically connected to each other. Note that although the transistor M1 is illustrated as a p-channel transistor in the equivalent circuit diagrams in FIG. 5C and FIG. 5D, the transistor M1 may be an n-channel transistor.

The back gate electrode may be formed using a material and a method similar to those used for the gate electrode, a source electrode, a drain electrode, or the like. The gate electrode and the back gate electrode are formed using conductive layers and thus each have a function of preventing an electric field generated outside the transistor from influencing the semiconductor layer in which the channel is formed (in particular, an electric field blocking function against static electricity). That is, a variation in the electrical characteristics of the transistor due to the influence of an external electric field such as static electricity can be prevented. By providing the back gate electrode, the amount of change in threshold voltage of the transistor in a BT (bias-temperature) stress test can be reduced. By providing the back gate electrode, a variation in transistor characteristics can be reduced, improving the reliability of the semiconductor device.

### Modification Example 3

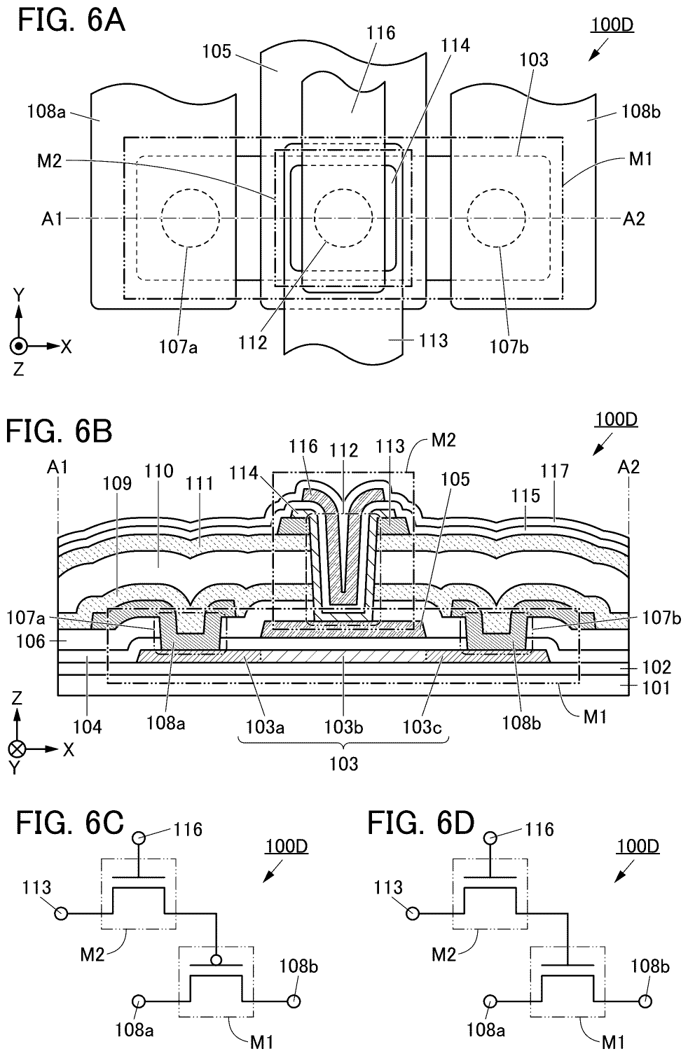

A semiconductor device 100D, which is a modification example of the semiconductor device 100A, is described. In order to reduce repeated description, differences of the semiconductor device 100D from the semiconductor device 100A are mainly described. The semiconductor device 100D can be regarded as a modification example of the semiconductor device 100B and the semiconductor device 100C. FIG. 6A is a top view of the semiconductor device 100D. FIG. 6B is a cross-sectional schematic view of a portion indicated by the dashed-dotted line A1-A2 in FIG. 6A. FIG. 6C and FIG. 6D are equivalent circuit diagrams of the semiconductor device 100D.

The semiconductor device 100D is different from the semiconductor device 100A in that the opening 112 overlaps with the conductive layer 105 functioning as the gate electrode of the transistor M1. Accordingly, in the semiconductor device 100D, the transistor M2 is provided over the gate electrode of the transistor M1. In the semiconductor device 100D, the opening 112 is formed by selectively removing parts of the conductive layer 113, the insulating layer 111, the insulating layer 110, the insulating layer 109, and the insulating layer 106 in a region overlapping with the conductive layer 105.

Although the opening 112 overlaps with the channel formation region 103b in FIG. 6A and FIG. 6B, one embodiment of the present invention is not limited to this example. A structure may be employed in which the opening 112 does not overlap with the channel formation region 103b but overlaps with the conductive layer 105. In the semiconductor device 100D, the conductive layer 105 functions as the gate electrode of the transistor M1 and the drain electrode of the transistor M2.

When the transistor M1 and the transistor M2 overlap with each other, a semiconductor device that occupies a smaller area can be achieved.

Note that although the transistor M1 is illustrated as a p-channel transistor in the equivalent circuit diagram in FIG. 6C, the transistor M1 may be an n-channel transistor as illustrated in the equivalent circuit diagram in FIG. 6D.

### Modification Example 4

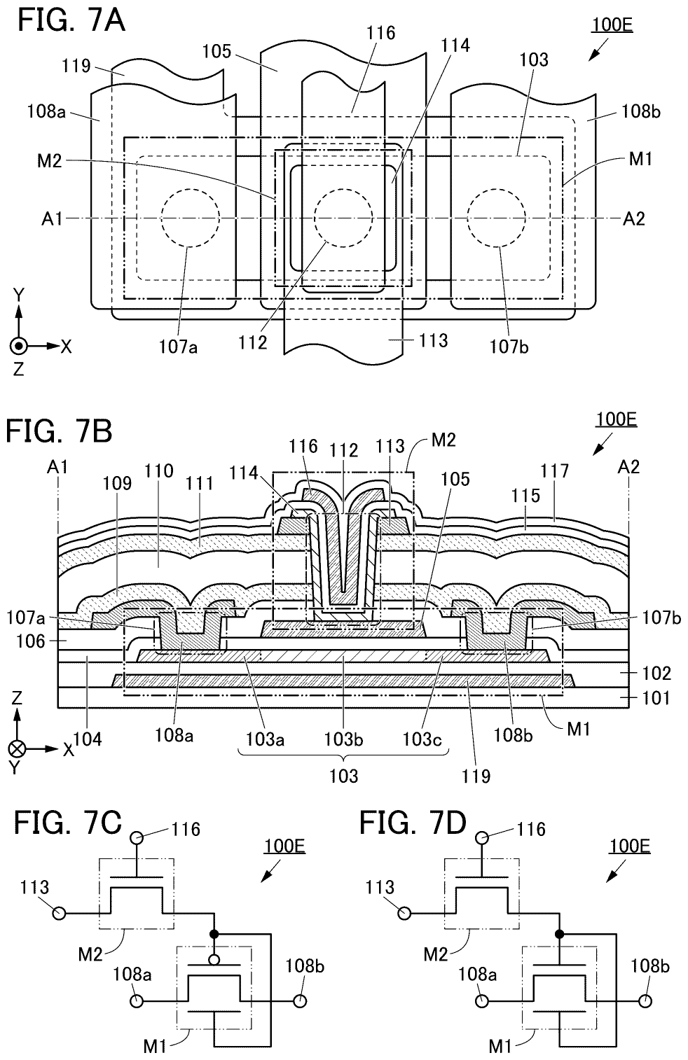

A semiconductor device 100E, which is a modification example of the semiconductor device 100D, is described. In order to reduce repeated description, differences of the semiconductor device 100E from the semiconductor device 100D are mainly described. FIG. 7A is a top view of the semiconductor device 100E. FIG. 7B is a cross-sectional schematic view of a portion indicated by the dashed-dotted line A1-A2 in FIG. 7A. FIG. 7C and FIG. 7D are equivalent circuit diagrams of the semiconductor device 100E.

The semiconductor device 100E is different from the semiconductor device 100D in that the conductive layer 119 is provided between the substrate 101 and the insulating layer 102, as in the semiconductor device 100C. As described in Modification example 2, the conductive layer 119 functions as the back gate electrode of the transistor M1. By providing the back gate electrode, variation in transistor characteristics can be reduced, improving the reliability of the semiconductor device.

Note that although the transistor M1 is illustrated as a p-channel transistor in the equivalent circuit diagram in FIG. 7C, the transistor M1 may be an n-channel transistor as illustrated in the equivalent circuit diagram in FIG. 7D. Although the back gate electrode and the gate electrode of the transistor M1 are electrically connected to each other in FIG. 7C and FIG. 7D, a given potential may be supplied to the back gate electrode without electrical connection between the back gate electrode and the gate electrode.

### Modification Example 5

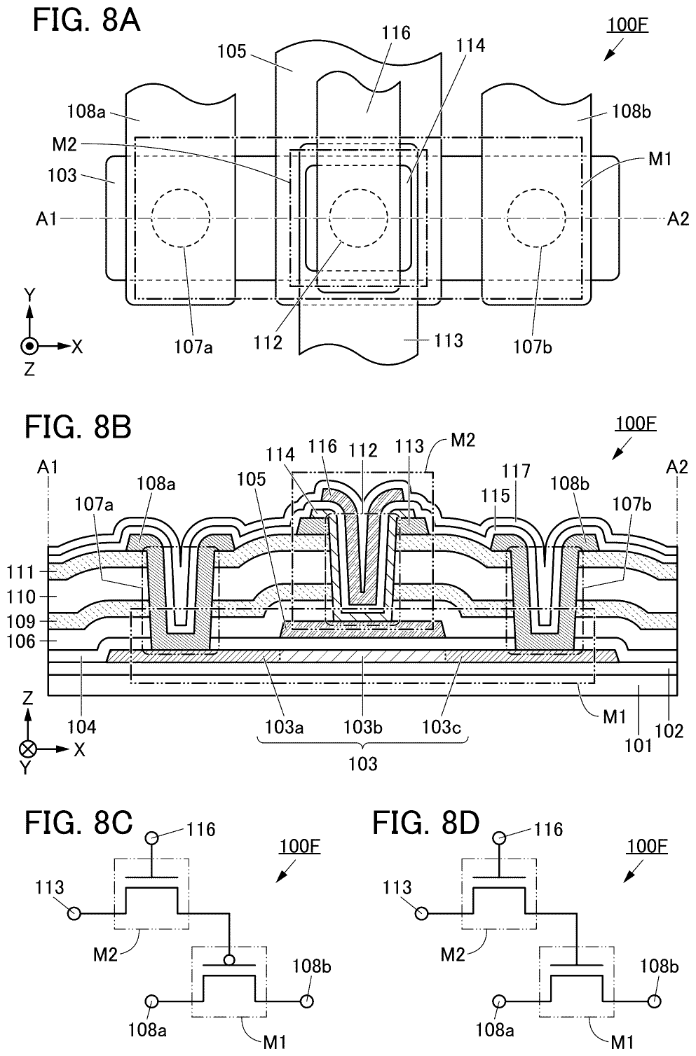

A semiconductor device 100F, which is a modification example of the semiconductor device 100D, is described. In order to reduce repeated description, differences of the semiconductor device 100F from the semiconductor device 100D are mainly described. FIG. 8A is a top view of the semiconductor device 100F. FIG. 8B is a cross-sectional schematic view of a portion indicated by the dashed-dotted line A1-A2 in FIG. 8A. FIG. 8C and FIG. 8D are equivalent circuit diagrams of the semiconductor device 100F.

The semiconductor device 100F is different from the semiconductor device 100D in the structures of the opening 107 (the opening 107a and the opening 107b) and the conductive layer 108 (the conductive layer 108a and the conductive layer 108b).

In the semiconductor device 100F, the opening 107a is formed by selectively removing parts of the insulating layer 111, the insulating layer 110, the insulating layer 109, the insulating layer 106, and the insulating layer 104 in a region overlapping with the drain region 103a of the semiconductor layer 103. In the semiconductor device 100F, the opening 107b is formed by selectively removing parts of the insulating layer 111, the insulating layer 110, the insulating layer 109, the insulating layer 106, and the insulating layer 104 in a region overlapping with the source region 103c of the semiconductor layer 103.

In the semiconductor device 100F, the conductive layer 108a is provided over the insulating layer 111 and is electrically connected to the drain region 103a at a bottom portion of the opening 107a. In the semiconductor device 100F, the conductive layer 108b is provided over the insulating layer 111 and is electrically connected to the source region 103c at a bottom portion of the opening 107b.

In the semiconductor device 100F, the conductive layer 108 and the conductive layer 113 can be formed with the same material at the same time in the same step. The conductive layer 108 and the conductive layer 113 do not need to be formed separately; thus, the manufacturing process of the semiconductor device can be shortened and the productivity of the semiconductor device can be increased.

Note that although the transistor M1 is illustrated as a p-channel transistor in the equivalent circuit diagram in FIG. 8C, the transistor M1 may be an n-channel transistor as illustrated in the equivalent circuit diagram in FIG. 8D.

### Modification Example 6

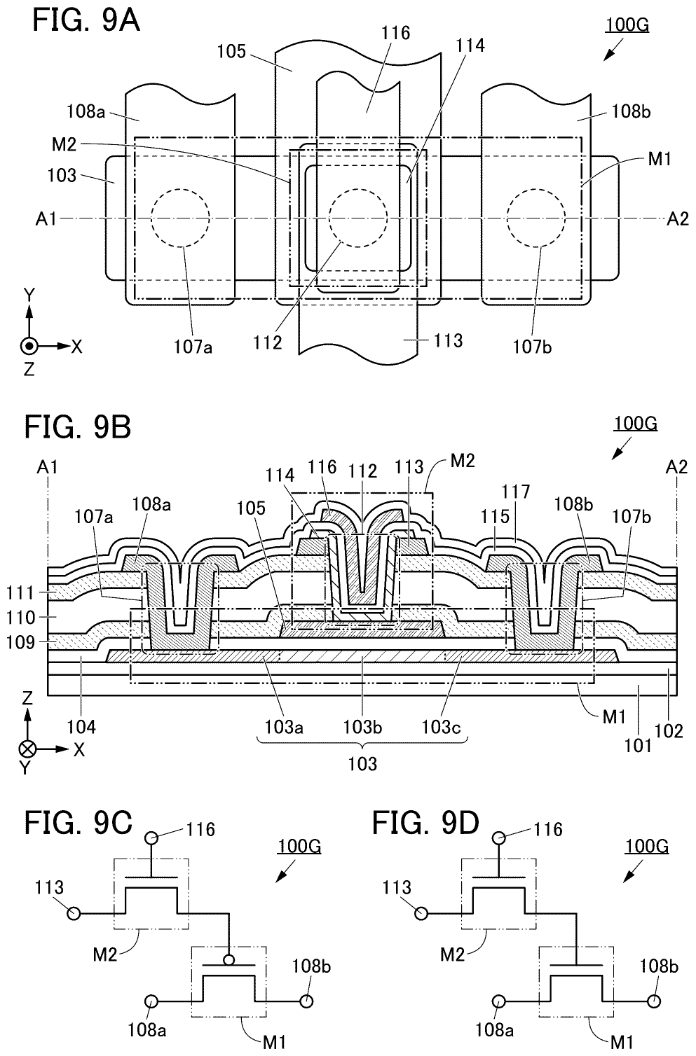

A semiconductor device 100G, which is a modification example of the semiconductor device 100F, is described. In order to reduce repeated description, differences of the semiconductor device 100G from the semiconductor device 100F are mainly described. FIG. 9A is a top view of the semiconductor device 100G. FIG. 9B is a cross-sectional schematic view of a portion indicated by the dashed-dotted line A1-A2 in FIG. 9A. FIG. 9C and FIG. 9D are equivalent circuit diagrams of the semiconductor device 100G.

The semiconductor device 100G is different from the semiconductor device 100F in that the insulating layer 106 is not included. The formation of the insulating layer 106 may be omitted with use of an insulating material through which impurities are less likely to pass for the insulating layer 109. When the insulating layer 106 is not provided, the number of layers to be removed at the time of forming the openings (the opening 107a, the opening 107b, the opening 112, and the like) is reduced; thus, the manufacturing process of the semiconductor device can be shortened and the productivity of the semiconductor device can be increased.

### Modification Example 7

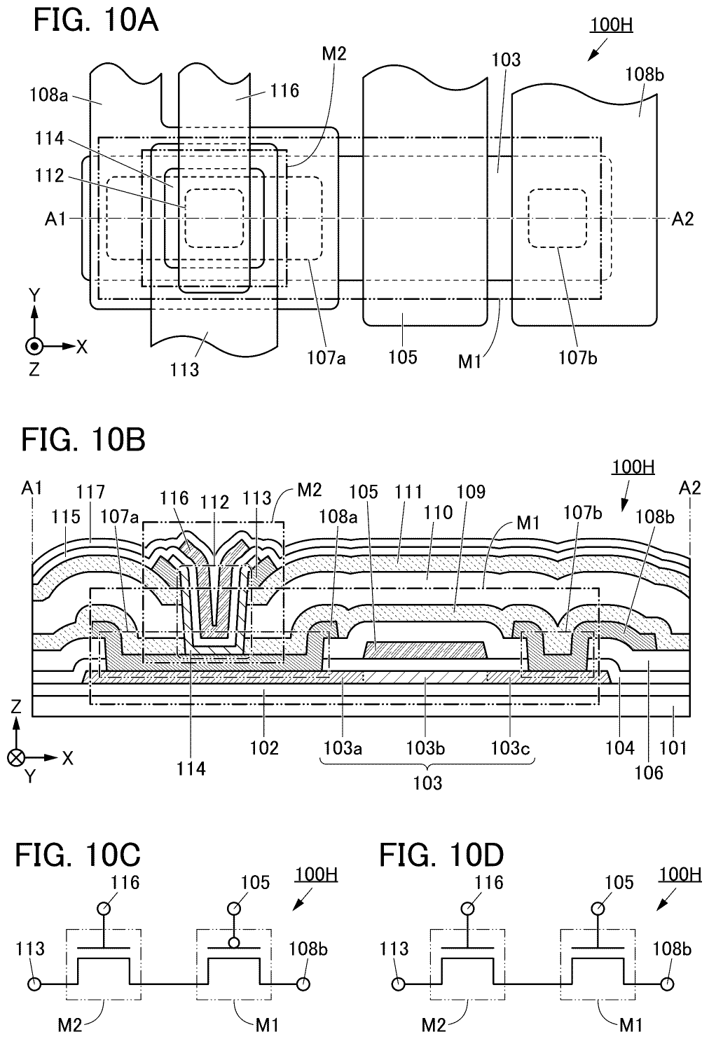

A semiconductor device 100H, which is a modification example of the semiconductor device 100A, is described. In order to reduce repeated description, differences of the semiconductor device 100H from the semiconductor device 100A are mainly described. FIG. 10A is a top view of the semiconductor device 100H. FIG. 10B is a cross-sectional schematic view of a portion indicated by the dashed-dotted line A1-A2 in FIG. 10A. FIG. 10C and FIG. 10D are equivalent circuit diagrams of the semiconductor device 100H.

The semiconductor device 100H is different from the semiconductor device 100A in that the transistor M2 is provided to overlap with the drain region 103a. In the semiconductor device 100H, the opening 112 is provided to overlap with the drain region 103a. Thus, the semiconductor device 100H includes a region where the transistor M1 and the transistor M2 overlap with each other. Specifically, the semiconductor device 100H includes a region where the semiconductor layer 114 and the semiconductor layer 103 overlap with each other. More specifically, the drain region 103a that is part of the semiconductor layer 103 and the semiconductor layer 114 overlap with each other with the conductive layer 108a therebetween.

When the transistor M1 and the transistor M2 overlap with each other, a semiconductor device that occupies a smaller area can be achieved

As in the semiconductor device 100C illustrated in FIG. 5, the conductive layer 119 functioning as a back gate electrode may be provided between the substrate 101 and the insulating layer 102. Note that although the transistor M1 is illustrated as a p-channel transistor in FIG. 10C, the transistor M1 may be an n-channel transistor as illustrated in FIG. 10D.

### Modification Example 8

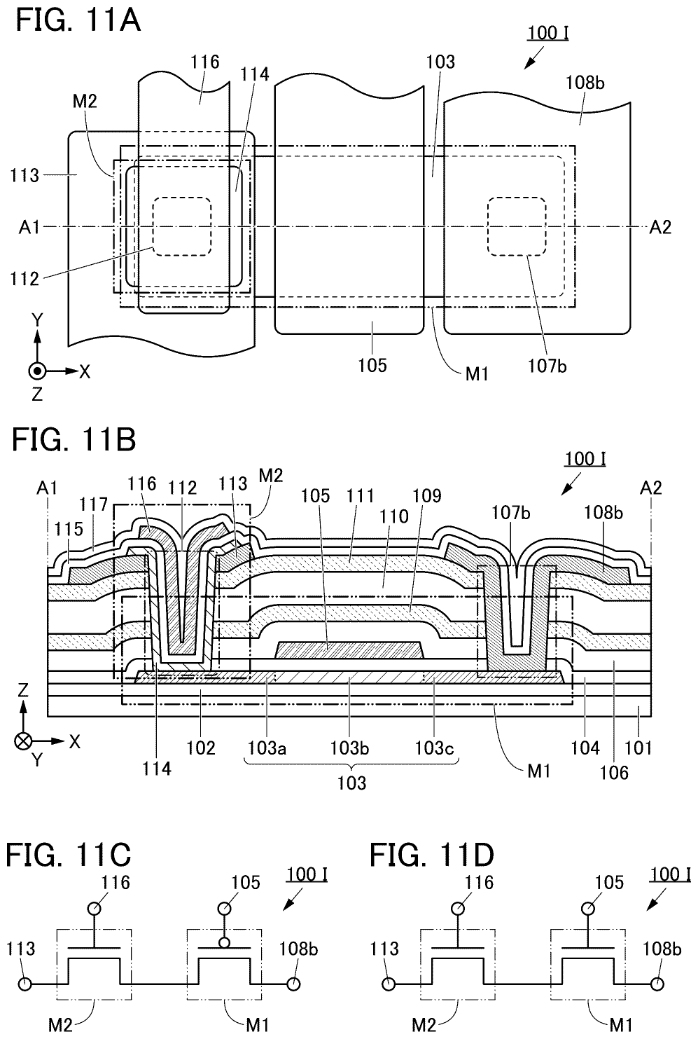

A semiconductor device 100I, which is a modification example of the semiconductor device 100H, is described. In order to reduce repeated description, differences of the semiconductor device 100I from the semiconductor device 100H are mainly described. FIG. 11A is a top view of the semiconductor device 100I. FIG. 11B is a cross-sectional schematic view of a portion indicated by the dashed-dotted line A1-A2 in FIG. 11A. FIG. 11C and FIG. 11D are equivalent circuit diagrams of the semiconductor device 100I.

The semiconductor device 100I is different from the semiconductor device 100H in that the conductive layer 108a is not included. In the semiconductor device 100I, the opening 112 can be regarded as serving as the opening 107a. The semiconductor device 100I includes a region where the semiconductor layer 114 and the semiconductor layer 103 overlap with each other. In the semiconductor device 100I, the semiconductor layer 114 and the semiconductor layer 103 are directly connected to each other at the bottom portion of the opening 112.

In the semiconductor device 100I, the opening 107b is provided to penetrate parts of the insulating layer 104, the insulating layer 106, the insulating layer 109, the insulating layer 110, and the insulating layer 111. In the semiconductor device 100I, the conductive layer 108b is provided in the opening 107b and over the insulating layer 111.

The opening 107b is formed by selectively removing parts of the insulating layer 104, the insulating layer 106, the insulating layer 109, the insulating layer 110, and the insulating layer 111 in a region overlapping with the source region 103c. The conductive layer 108b provided over the insulating layer 111 is electrically connected to the source region 103c of the semiconductor layer 103 at the bottom portion of the opening 107b.

When the conductive layer 108a is not provided, a semiconductor device that occupies a smaller area can be achieved. Note that in the semiconductor device 100I illustrated in FIG. 11B, the semiconductor layer 103 and the semiconductor layer 114 are in contact with each other at the bottom portion of the opening 112; thus, the semiconductor layer 103 and the semiconductor layer 114 preferably contain a common element. When the semiconductor layer 103 and the semiconductor layer 114 contain a common element, the contact resistance can be reduced. For example, an oxide semiconductor may be used for both the semiconductor layer 103 and the semiconductor layer 114.

Although the transistor M1 is illustrated as a p-channel transistor in FIG. 11C, the transistor M1 may be an n-channel transistor, as illustrated in FIG. 11D.

### Modification Example 9

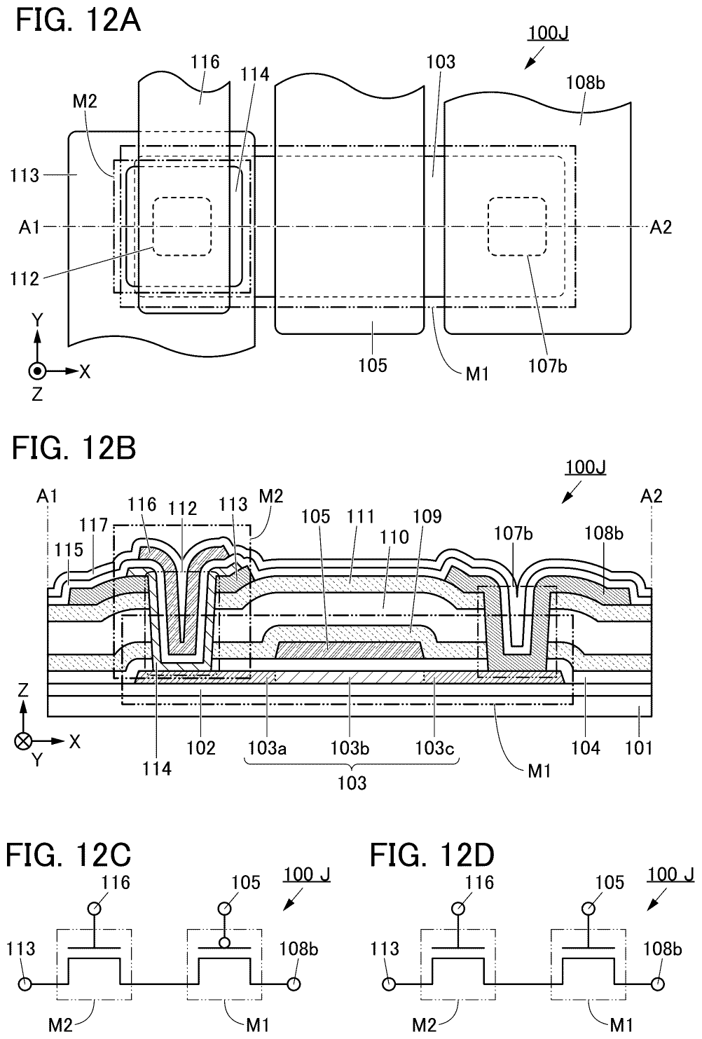

A semiconductor device 100J, which is a modification example of the semiconductor device 100I, is described. In order to reduce repeated description, differences of the semiconductor device 100J from the semiconductor device 100I are mainly described. FIG. 12A is a top view of the semiconductor device 100J. FIG. 12B is a cross-sectional schematic view of a portion indicated by the dashed-dotted line A1-A2 in FIG. 12A. FIG. 12C and FIG. 12D are equivalent circuit diagrams of the semiconductor device 100J.

The semiconductor device 100J is different from the semiconductor device 100I in that the insulating layer 106 is not included. The formation of the insulating layer 106 may be omitted with use of an insulating material through which impurities are less likely to pass for the insulating layer 109. When the insulating layer 106 is not provided, the number of layers to be removed at the time of forming the openings (the opening 107b, the opening 112, and the like) is reduced; thus, the manufacturing process of the semiconductor device can be shortened and the productivity of the semiconductor device can be increased.

### Modification Example 10

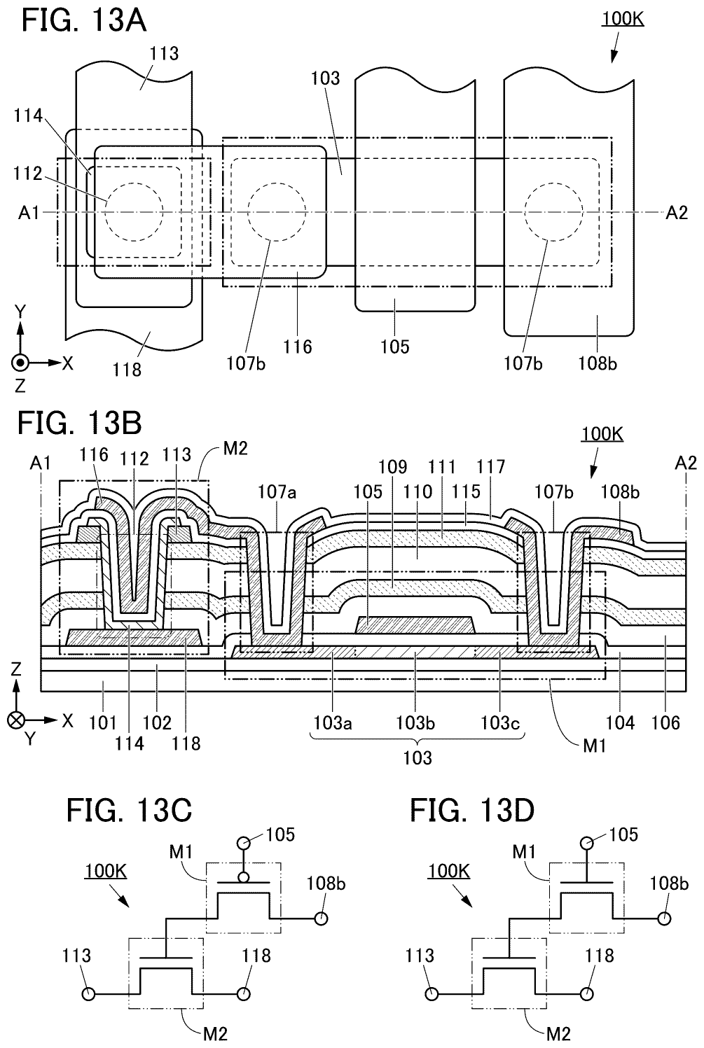

Next, a semiconductor device 100K is described. The semiconductor device 100K is also a modification example of the semiconductor device 100A, the semiconductor device 100F, and the like. In order to reduce repeated description, differences of the semiconductor device 100K from the semiconductor device 100A, the semiconductor device 100F, and the like are mainly described. FIG. 13A is a top view of the semiconductor device 100K. FIG. 13B is a cross-sectional schematic view of a portion indicated by the dashed-dotted line A1-A2 in FIG. 13A. FIG. 13C and FIG. 13D are equivalent circuit diagrams of the semiconductor device 100K.

The semiconductor device 100K includes a conductive layer 118 over the insulating layer 104. Over the substrate 101, the transistor M2 is formed in a region different from the region where the transistor M1 is formed. The transistor M2 includes at least part of the conductive layer 118. In the case where the conductive layer 113 functions as the source electrode of the transistor M2, the conductive layer 118 functions as the drain electrode. In the case where the conductive layer 113 functions as the drain electrode of the transistor M2, the conductive layer 118 functions as the source electrode.

The conductive layer 118 can be formed with the same material at the same time in the same step as the conductive layer 105. In the semiconductor device 100K, the opening 112 is provided in parts of the conductive layer 113, the insulating layer 111, the insulating layer 110, the insulating layer 109, and the insulating layer 106. In the semiconductor device 100K, the opening 107a is provided in parts of the insulating layer 115, the insulating layer 111, the insulating layer 110, the insulating layer 109, the insulating layer 106, and the insulating layer 104, and the opening 107b is provided in other parts.

Part of the conductive layer 116 provided over the insulating layer 115 covers the opening 107a and is electrically connected to the drain region 103a at the bottom portion of the opening 107a. The conductive layer 108b of the semiconductor device 100K can be formed with the same material at the same time in the same step as the conductive layer 116. The conductive layer 108b is electrically connected to the source region 103c at the bottom portion of the opening 107b.

In the semiconductor device 100K, part of the conductive layer 116 functions as the conductive layer 108a of the semiconductor device 100A or the like. Thus, the conductive layer 116 in the semiconductor device 100K functions not only as the gate electrode of the transistor M2 but also as the drain electrode.

As in the semiconductor device 100C illustrated in FIG. 5, the conductive layer 119 functioning as a back gate electrode may be provided between the substrate 101 and the insulating layer 102. Note that although the transistor M1 is illustrated as a p-channel transistor in FIG. 13C, the transistor M1 may be an n-channel transistor as illustrated in FIG. 13D.

### Modification Example 11

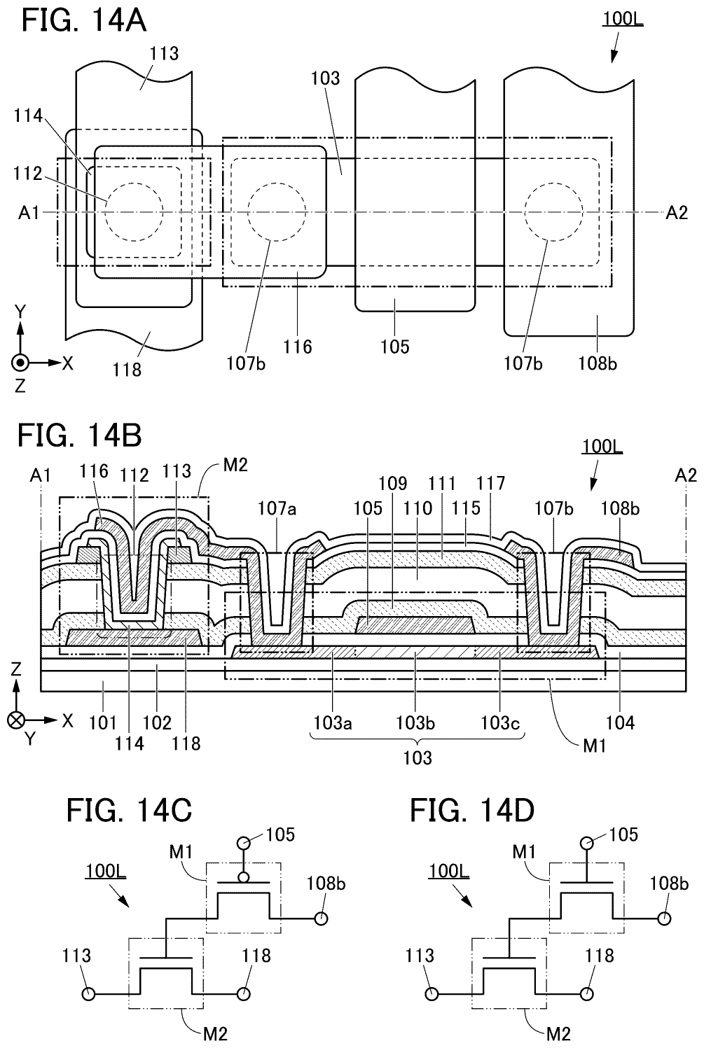

A semiconductor device 100K, which is a modification example of the semiconductor device 100L, is described. In order to reduce repeated description, differences of the semiconductor device 100K from the semiconductor device 100L are mainly described. FIG. 14A is a top view of the semiconductor device 100L. FIG. 14B is a cross-sectional schematic view of a portion indicated by the dashed-dotted line A1-A2 in FIG. 14A. FIG. 14C and FIG. 14D are equivalent circuit diagrams of the semiconductor device 100L.

The semiconductor device 100L is different from the semiconductor device 100K in that the insulating layer 106 is not included. The formation of the insulating layer 106 may be omitted with use of an insulating material through which impurities are less likely to pass for the insulating layer 109. When the insulating layer 106 is not provided, the number of layers to be removed at the time of forming the openings (the opening 107b, the opening 112, and the like) is reduced; thus, the manufacturing process of the semiconductor device can be shortened and the productivity of the semiconductor device can be increased.

### <<Manufacturing Method>>

Next, an example of a method for manufacturing the semiconductor device 100A is described. First, materials and methods for forming the layers are described.

### [Methods for Forming Layers]

The insulating layers, the semiconductor layer, the conductive layers used for forming electrodes and wirings, and the like can be formed by a sputtering method, a chemical vapor deposition (CVD) method, a vacuum evaporation method, a pulsed laser deposition (PLD) method, an atomic layer deposition (ALD) method, or the like. As the CVD method, a plasma-enhanced chemical vapor deposition (PECVD) method or a thermal CVD method may be used. As the thermal CVD method, for example, a metal organic chemical vapor deposition (MOCVD: Metal Organic CVD) method is given.

Alternatively, the insulating layers, the semiconductor layer, the conductive layers, and the like included in the semiconductor device may be formed by a method such as spin coating, dipping, spray coating, ink-jetting, dispensing, screen printing, offset printing, slit coating, roll coating, curtain coating, and knife coating.

A PECVD method can provide a high-quality film at a relatively low temperature. With the use of a film formation method that does not use plasma at the time of film formation, such as an MOCVD method, an ALD method, or a thermal CVD method, damage is not easily caused on a formation surface. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. By contrast, in the case of a film formation method not using plasma, such plasma damage is not caused; thus, the yield of semiconductor devices can be increased. Since plasma damage during film formation is not caused, a film with few defects can be obtained.

Unlike a film formation method in which particles ejected from a target or the like are deposited, a CVD method and an ALD method are film formation methods in which a film is formed by reaction at a surface of an object. Thus, a CVD method and an ALD method are film formation methods that are less likely to be influenced by the shape of an object and thus have favorable step coverage. In particular, an ALD method can provide excellent step coverage and excellent thickness uniformity and thus is suitable for the case of covering a surface of an opening with a high aspect ratio, for example. On the other hand, an ALD method has a relatively low deposition rate; thus, it is sometimes preferable to combine an ALD method with another film formation method with a high deposition rate, such as a CVD method.

A CVD method and an ALD method enable control of the composition of a film to be obtained by using a flow rate ratio of source gases. For example, by a CVD method or an ALD method, a film with a certain composition can be formed depending on the flow rate ratio of source gases. Moreover, by changing the flow rate ratio of source gases during film formation by a CVD method or an ALD method, a film whose composition is continuously changed can be formed. In the case where a film is formed while changing the flow rate ratio of source gases, compared with the case where a film is formed using a plurality of deposition chambers, the time it takes for the film formation can be reduced by the amount of time taken for transfer and pressure adjustment. Thus, semiconductor devices can be manufactured with improved productivity in some cases.

When the layers (thin films) that form the semiconductor device are processed, a photolithography method or the like can be used for the processing. Alternatively, island-shaped layers may be formed by a film formation method using a blocking mask. Alternatively, a nanoimprinting method, a sandblasting method, a lift-off method, or the like may be used for the processing of the layers. As a photolithography method, a method in which a resist mask is formed over a layer (thin film) to be processed, part of the layer (thin film) is selected and removed by using the resist mask as a mask, and the resist mask is removed, and a method in which a photosensitive layer is formed, and then the layer is exposed to light and developed to be processed into a desired shape are given.

In the case of using light in the photolithography method, an i-line (a wavelength of 365 nm), a g-line (a wavelength of 436 nm), and an h-line (a wavelength of 405 nm), or combined light of them can be used for light exposure. Besides, ultraviolet light, KrF laser light, ArF laser light, or the like can be used. Light exposure may be performed by liquid immersion light exposure technique. As the light used for the light exposure, extreme ultra-violet (EUV) light or X-rays may be used. Instead of the light used for the light exposure, an electron beam can be used. It is preferable to use extreme ultra-violet light, X-rays, or an electron beam because extremely minute processing can be performed. Note that in the case of performing light exposure by scanning of a beam such as an electron beam, a photomask is not needed.

For removal (etching) of the layers (thin films), a dry etching method, a wet etching method, a sandblasting method, or the like can be used. Alternatively, the etching methods may be used in combination.

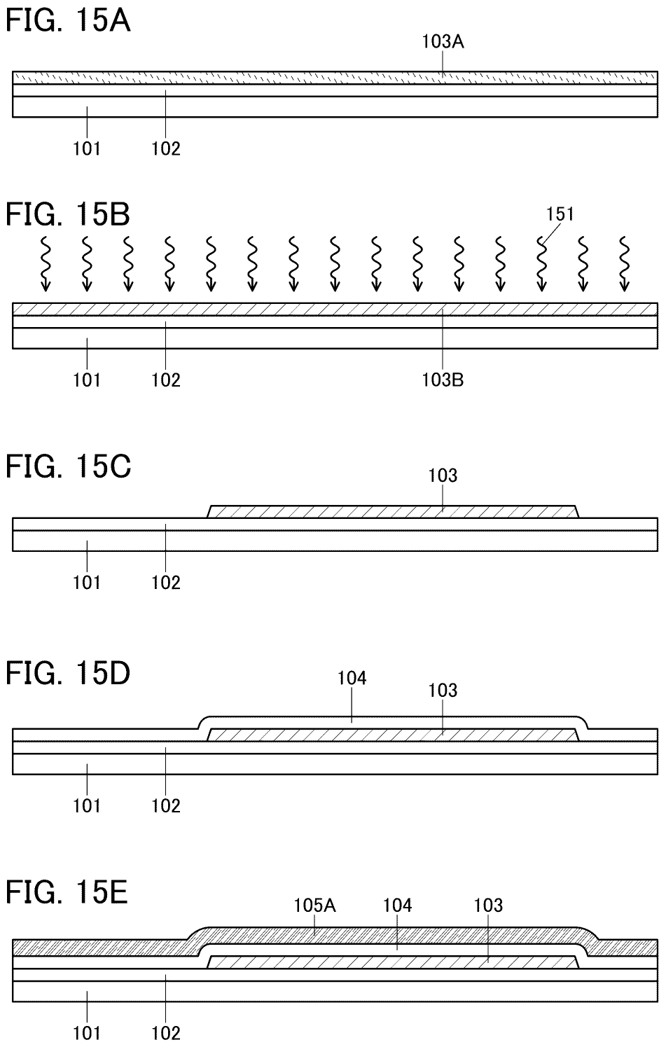

Next, an example of a method for manufacturing the semiconductor device 100A is described. First, the insulating layer 102 is provided over the substrate 101, and a semiconductor layer 103A is provided over the insulating layer 102 (see FIG. 15A).

As the substrate 101, for example, an insulator substrate having an insulating surface is used. Examples of the insulator substrate include a glass substrate, a quartz substrate, a sapphire substrate, a stabilized zirconia substrate (e.g., an yttria-stabilized zirconia substrate), and a resin substrate.

A semiconductor substrate or a conductor substrate may be used as the substrate 101, as needed. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Other examples include any of the above semiconductor substrates including an insulator region, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the elements provided over the substrates include a capacitor element, a resistor, a switching element, a light-emitting element, and a memory element.

As the insulating layer 102, silicon oxide is formed over the substrate 101. Examples of an insulating layer that can be used for the semiconductor device 100A include an oxide, a nitride, an oxynitride, a nitride oxide, a metal oxide, a metal oxynitride, and a metal nitride oxide, each of which has an insulating property.

As miniaturization and high integration of transistors progress, a problem such as a leakage current may arise because of a thinner gate insulator. When a high-k material is used for the insulating layer functioning as a gate insulating layer, the voltage at the time of operation of the transistor can be reduced while the physical thickness is maintained. In contrast, when a material with low dielectric constant is used for the insulating layer functioning as an interlayer film, parasitic capacitance generated between wirings can be reduced. Thus, a material is preferably selected depending on the function of an insulating layer.

Examples of the insulating layer having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulating layer having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

Note that in this specification and the like, a nitride oxide refers to a material that contains more nitrogen than oxygen. An oxynitride refers to a material that contains more oxygen than nitrogen. The content of each element can be measured by Rutherford backscattering spectrometry (RBS), for example.

As the semiconductor layer 103A, amorphous silicon is formed. Depending on the amount of hydrogen contained in the semiconductor layer 103A, it is desirable that dehydrogenation treatment be performed for several hours at a heating temperature of 400° C. to 550° C. to achieve a hydrogen amount less than or equal to 5 at. % and then a crystallization step be performed. Alternatively, a sputtering method, a vacuum evaporation method, or the like may be used for forming the amorphous semiconductor film. In any case, impurity elements contained in the film, such as oxygen and nitrogen, are desirably reduced to a sufficient level.

Note that a semiconductor used for the semiconductor layer 103A is not limited to silicon, and silicon germanium can be used, for example. In the case of using silicon germanium, the concentration of germanium is preferably approximately 0.01 at. % to 4.5 at. %.

Note that the insulating layer 102 and the semiconductor layer 103A may be formed successively without being exposed to the air. Such successive formation without exposure to the air can minimize contamination of the surface due to exposure to the air, so that variation in transistor characteristics can be reduced.

Next, the semiconductor layer 103A is crystallized to form a semiconductor layer 103B having crystallinity (see FIG. 15B). As a method for increasing the crystallinity of the semiconductor layer 103A (also referred to as “crystallization”), a laser annealing method, a thermal annealing method (a solid-phase growth method), or a rapid thermal annealing method (an RTA method) can be used. In the case where a glass substrate or a plastic substrate having low heat resistance is used as the substrate 101, a laser annealing method is particularly preferably employed. As the laser light, excimer laser light using XeCl, the second harmonic or the third harmonic of a YAG laser, or the like can be used. In the RTA method, an infrared lamp, a halogen lamp, a metal halide lamp, a xenon lamp, or the like is used as a light source. Alternatively, the semiconductor layer 103B having crystallinity may be formed by a crystallization method using a catalytic element in accordance with the technology disclosed in Japanese Published Patent Application No. H7-130652, for example.

The semiconductor layer 103A may be crystallized with a combination of the above methods. For example, after the semiconductor layer 103A is crystallized by a solid-phase growth method, laser light irradiation is further performed to obtain the semiconductor layer 103B with few defects and high crystallinity.

In particular, in the case of using a laser annealing method, it is preferable to release hydrogen contained in the amorphous semiconductor layer first. Heat treatment is performed at higher than or equal to 400° C. and lower than or equal to 550° C. for approximately 1 hour, the amount of hydrogen contained is 5 at. % or lower, and then crystallization is performed, whereby roughness of the film surface can be prevented. In this embodiment, the semiconductor layer 103A is crystallized by a laser annealing method. Specifically, the semiconductor layer 103A containing hydrogen at 5 at. % or lower is irradiated with laser light 151 to form the semiconductor layer 103B.

Note that in the case where an oxide semiconductor is used for the semiconductor layer 103A, the above treatment for increasing the crystallinity is not necessarily performed.

Before the semiconductor layer 103A is crystallized, an impurity element that makes the semiconductor layer 103A a p-type semiconductor (also referred to as a “p-type impurity element”) or an impurity element that makes the semiconductor layer 103A an n-type semiconductor (also referred to as an “n-type impurity element”) may be added at a low concentration (also referred to as “channel doping”). The channel doping may be performed on the whole semiconductor layer 103A or may be selectively performed on part of the semiconductor layer 103A.

As the p-type impurity element, one or more selected from Group 13 elements such as boron (B), aluminum (Al), and gallium (Ga) can be used, for example. As the n-type impurity element, one or more of Group 15 elements such as phosphorus (P) and arsenic (As) can be used.

When channel doping is performed on the semiconductor layer, the threshold voltage of a transistor including the semiconductor layer can be controlled. For example, when boron is added to the semiconductor layer at a concentration higher than or equal to 1×10¹⁶ atoms/cm³ and lower than or equal to 5×10¹⁷ atoms/cm³, the threshold voltage of the transistor including the semiconductor layer can be changed in the positive direction.

By performing channel doping, enhancement-mode (normally-off) transistors or depletion-mode (normally-on) transistors can be separately formed.

Next, a resist mask is formed over the semiconductor layer 103B by a photolithography method (not illustrated). With use of the resist mask as a mask, the semiconductor layer 103B is selectively removed to form the semiconductor layer 103 (see FIG. 15C).

Next, the insulating layer 104 is formed over the insulating layer 102 and the semiconductor layer 103. The insulating layer 104 can be formed using a material and a method similar to those of the insulating layer 102 (see FIG. 15D).

In the case where an oxide semiconductor is used for the semiconductor layer 103, microwave treatment is preferably performed in an oxygen-containing atmosphere after the formation of the insulating layer 104. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is set to greater than or equal to 300 MHz and less than or equal to 300 GHz, preferably greater than or equal to 2.4 GHz and less than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide semiconductor efficiently.

The microwave treatment is preferably performed under reduced pressure, and the pressure may be higher than or equal to 10 Pa and lower than or equal to 1000 Pa, preferably higher than or equal to 300 Pa and lower than or equal to 700 Pa. The treatment temperature may be lower than or equal to 750° C., preferably lower than or equal to 500° C., and is approximately 250° C., for example. After the microwave treatment is performed in an atmosphere containing oxygen, heat treatment may be successively performed without exposure to the air. For example, the treatment temperature may be higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The microwave treatment in an oxygen-containing atmosphere reduces hydrogen and oxygen vacancies in the oxide semiconductor. Thus, the carrier concentration in the oxide semiconductor can be reduced.

Next, a conductive layer 105A is formed over the insulating layer 104 (see FIG. 15E). For the conductive layer 105A, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like.

As the conductive layer 105A, a plurality of conductive layers formed using the above-described materials may be stacked and used. The conductive layer may have a stacked-layer structure in which a material containing the above-described metal element and a conductive material containing oxygen are combined, for example. Alternatively, a stacked-layer structure in which a material containing the above-described metal element and a conductive material containing nitrogen are combined may be used. Alternatively, a stacked-layer structure in which a material containing the above-described metal element, a conductive material containing oxygen, and a conductive material containing nitrogen are combined may be used.

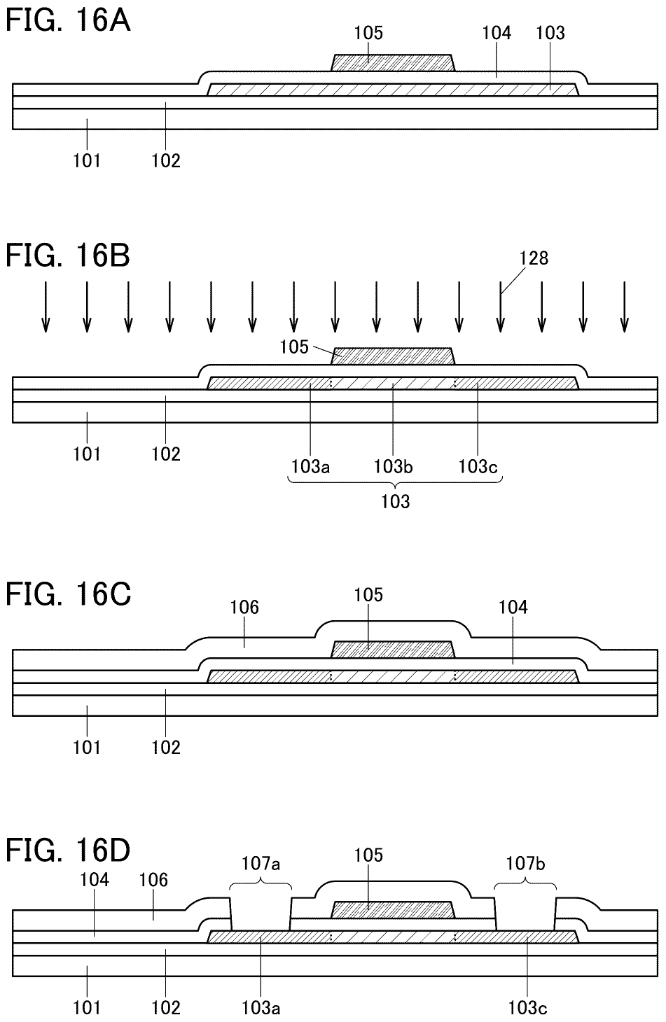

Next, a resist mask is formed over the conductive layer 105A by a photolithography method (not illustrated). With use of the resist mask as a mask, the conductive layer 105A is selectively removed to form the conductive layer 105 (see FIG. 16A).

Next, to form the drain region 103a, the channel formation region 103b, and the source region 103c in the semiconductor layer 103, an impurity element is introduced into the semiconductor layer 103. Specifically, an impurity element (a dopant 128) is introduced into the semiconductor layer 103 using the conductive layer 105 as a mask (see FIG. 16B). The dopant 128 can be introduced by an ion implantation method, a plasma doping method, or the like.

Note that in the case where an oxide semiconductor is used for the semiconductor layer 103, a rare gas element, carbon, nitrogen, or the like may be used as the dopant 128.

The dopant 128 is not introduced into a region of the semiconductor layer 103 which overlaps with the conductive layer 105. The dopant 128 is introduced into a region of the semiconductor layer 103 which does not overlap with the conductive layer 105. In the semiconductor layer 103, a region which overlaps with the conductive layer 105 and into which the dopant 128 is not introduced functions as the channel formation region 103b. In the semiconductor layer 103, a region into which the dopant 128 is introduced functions as the drain region 103a or the source region 103c.

When the conductive layer 105 is used as a mask, the channel formation region 103b is formed in a self-aligned manner. The concentration distribution in the depth direction of the dopant 128 and the concentration of the metal element can be determined by the treatment method and the treatment conditions.

In this embodiment, since silicon is used for the semiconductor layer 103, boron (B), which is one of Group 13 elements, is used for the dopant 128 for making the transistor M1 a p-channel transistor. Note that a Group 15 element (e.g., phosphorus (P)) is used as the dopant 128 for making the transistor M1 an n-channel transistor.

After the introduction of the impurity element into the semiconductor layer 103, heat treatment is performed. By performing the heat treatment, activation of the introduced impurity element and recrystallization of a portion of the semiconductor layer 103 which is made amorphous by the introduction of the impurity element are performed. In this specification and the like, the heat treatment is also referred to as activation treatment.

The hydrogenation treatment is performed after the activation treatment is completed. The hydrogenation treatment is treatment for adding hydrogen excited by heat treatment or plasma treatment to the semiconductor layer 103; in the case of heat treatment, a heat treatment step may be performed for 2 to 6 hours at higher than or equal to 300° C. and lower than or equal to 450° C. in an atmosphere containing hydrogen at 3% to 100%.

Note that in the case where an oxide semiconductor is used for the semiconductor layer 103, the activation treatment and the hydrogenation treatment are not necessarily performed.

Next, the insulating layer 106 is formed over the insulating layer 104 and the conductive layer 105 (see FIG. 16C). The insulating layer 106 functions as an interlayer insulating layer and thus may be formed with a material having a low dielectric constant.

In the case where an oxide semiconductor is used for the semiconductor layer 114 to be formed later, an insulating material through which impurities are less likely to pass is preferably used for the insulating layer 106. When the insulating material through which impurities are less likely to pass is used for the insulating layer 106, impurity diffusion from a component below the insulating layer 106 can be inhibited, and the reliability of the semiconductor device can be improved. For example, hydrogen contained in the transistor M1 side can be prevented from diffusing to the transistor M2 side.

Next, a resist mask is formed over the insulating layer 106 by a photolithography method (not illustrated). Part of the insulating layer 106 and part of the insulating layer 104 are selectively removed using the resist mask as a mask, so that the opening 107a overlapping with the drain region 103a and the opening 107b overlapping with the source region 103c are formed (see FIG. 16D). Part of the drain region 103a is exposed at the bottom portion of the opening 107a, and part of the source region 103c is exposed at the bottom portion of the opening 107b. In the opening 107a and the opening 107b, a side surface of the insulating layer 106 and a side surface of the insulating layer 104 are exposed.

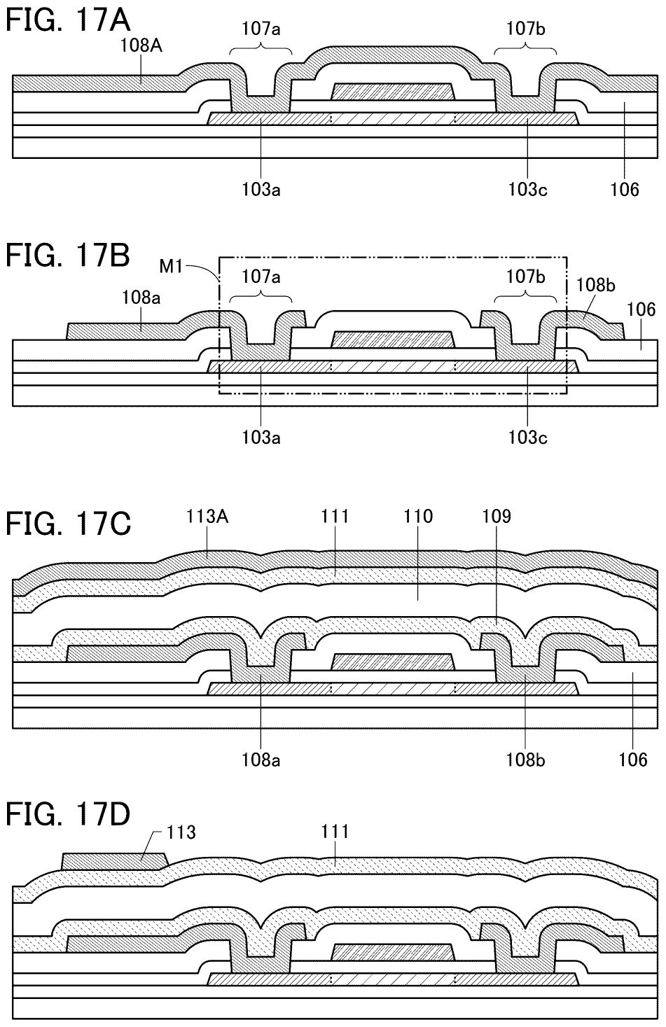

Next, a conductive layer 108A is formed over the insulating layer 106. The conductive layer 108A may be formed using a material and a method similar to those of the conductive layer 105A (see FIG. 17A).

Next, a resist mask is formed over the conductive layer 108A by a photolithography method (not illustrated). The conductive layer 108A is selectively removed using the resist mask as a mask, so that the conductive layer 108 (the conductive layer 108a and the conductive layer 108b) is formed (see FIG. 17B). The conductive layer 108a is electrically connected to the drain region 103a in the opening 107a, and the conductive layer 108b is electrically connected to the source region 103c in the opening 107b. In the above manner, the transistor M1 can be formed.

Next, the insulating layer 109, the insulating layer 110, the insulating layer 111, and a conductive layer 113A are sequentially formed over the insulating layer 106 and the conductive layer 108 (see FIG. 17C). The insulating layer 109 and the insulating layer 111 are formed with an insulating material containing hydrogen. For example, silicon nitride containing hydrogen is used.

The insulating layer 110 is formed with an insulating material with reduced hydrogen. For example, silicon oxide or silicon oxynitride may be used. Note that the insulating layer 110 preferably contains excess oxygen.

The conductive layer 113A may be formed using a material and a method similar to those of the conductive layer 105A or the conductive layer 108A.

Next, a resist mask is formed over the conductive layer 113A by a photolithography method (not illustrated). With use of the resist mask as a mask, the conductive layer 113A is selectively removed to form the conductive layer 113 (see FIG. 17D).

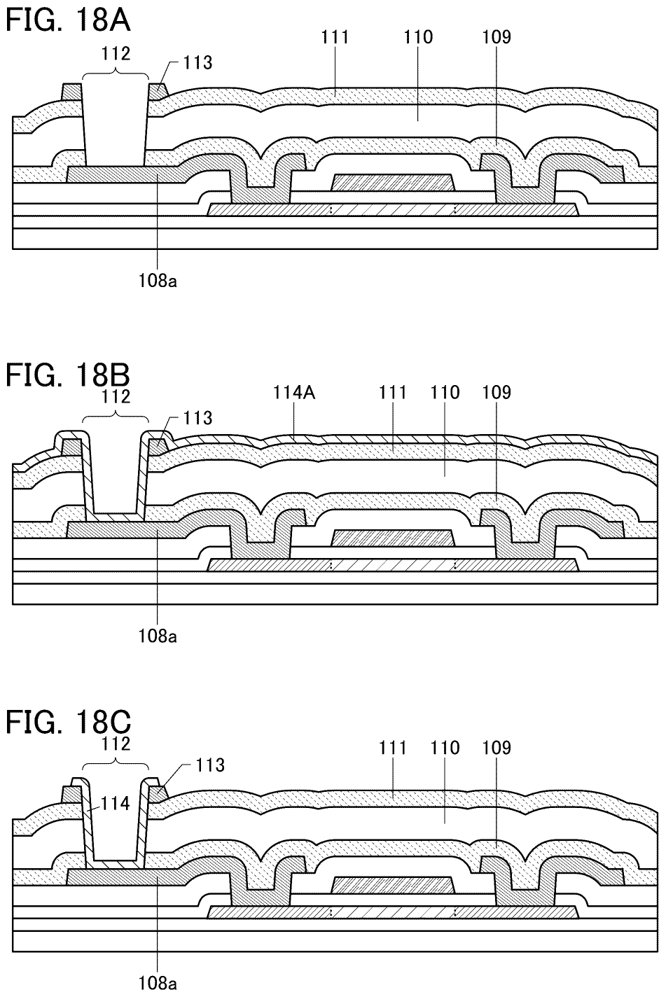

Next, a resist mask is formed over the insulating layer 111 by a photolithography method (not illustrated). With use of the resist mask as a mask, parts of the conductive layer 113, the insulating layer 111, the insulating layer 110, and the insulating layer 109 are selectively removed, so that the opening 112 is formed in a region overlapping with the conductive layer 108a (see FIG. 18A). Part of the conductive layer 108a is exposed at the bottom portion of the opening 112. In the opening 112, the side surface of the insulating layer 111, the side surface of the insulating layer 110, and the side surface of the insulating layer 109 are exposed.

Next, a semiconductor layer 114A to be the semiconductor layer 114 of the transistor M2 later is formed over the insulating layer 111 (see FIG. 18B). In this embodiment, an oxide semiconductor is formed as the semiconductor layer 114A.

The oxide semiconductor preferably contains indium, M (Mis one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is preferable to use an oxide containing indium (In), gallium (Ga), and zinc (Zn) (also referred to as “IGZO”) for the semiconductor layer of the OS transistor. Alternatively, an oxide containing indium (In), aluminum (Al), and zinc (Zn) (also referred to as “IAZO”) may be used for the semiconductor layer. Further alternatively, an oxide containing indium (In), aluminum (Al), gallium (Ga), and zinc (Zn) (also referred to as “IAGZO”) may be used for the semiconductor layer. Further alternatively, an oxide containing indium (In), gallium (Ga), zinc (Zn), and tin (Sn) (also referred to as “IGZTO”) may be used for the semiconductor layer.

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of a desired atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, when the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, when the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The semiconductor layer 114A is formed to cover not only the top surface of the insulating layer 111 but also the inner surface of the opening 112. Therefore, the semiconductor layer 114A is preferably formed by a deposition method with favorable step coverage. For example, the semiconductor layer 114A is preferably formed by an ALD method.

Next, a resist mask is formed over the semiconductor layer 114A by a photolithography method (not illustrated). With use of the resist mask as a mask, part of the semiconductor layer 114A is selectively removed to form the semiconductor layer 114 (see FIG. 18C).

In the opening 112, the semiconductor layer 114 includes a region in contact with the conductive layer 113, a region in contact with the insulating layer 111, a region in contact with the insulating layer 110, a region in contact with the insulating layer 109, and a region in contact with the conductive layer 108a. Specifically, in the opening 112, the semiconductor layer 114 includes a region in contact with the side surface of the conductive layer 113, a region in contact with the side surface of the insulating layer 111, a region in contact with the side surface of the insulating layer 110, and a region in contact with the side surface of the insulating layer 109; in the bottom portion of the opening 112, the semiconductor layer 114 includes a region in contact with the conductive layer 108a.

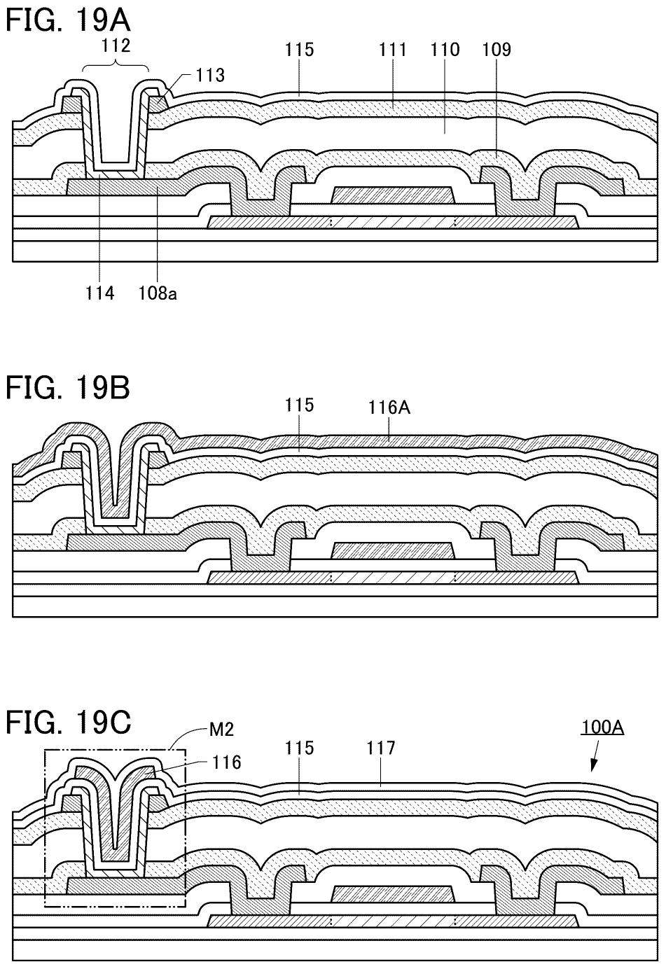

Next, the insulating layer 115 is formed over the insulating layer 111, the conductive layer 113, and the semiconductor layer 114 (see FIG. 19A). The insulating layer 115 functions as a gate insulating layer of the transistor M2. Since an oxide semiconductor is used for the semiconductor layer 114 in this embodiment and the like, an insulating layer containing excess oxygen is preferably used as the insulating layer 115.

In the case where an oxide semiconductor is used for the semiconductor layer 114, microwave treatment is preferably performed in the above-described oxygen-containing atmosphere after the formation of the insulating layer 115.

Next, a resist mask is formed over the insulating layer 115 by a photolithography method, parts of the insulating layer 115, the insulating layer 111, the insulating layer 110, the insulating layer 109, and the insulating layer 106 in a region overlapping with the conductive layer 105 are selectively removed using the resist mask as a mask, so that the opening 127 (not illustrated) is formed. Part of the conductive layer 105 is exposed at a bottom portion of the opening 127.

Next, a conductive layer 116A is formed over the insulating layer 115 (see FIG. 19B).

Next, a resist mask is formed over the conductive layer 116A by a photolithography method (not illustrated). With use of the resist mask as a mask, part of the conductive layer 116A is selectively removed to form the conductive layer 116 (see FIG. 19C). In the above manner, the transistor M2 can be formed.

As described above, the conductive layer 116 functions as the gate electrode of the transistor M2. The conductive layer 116 is electrically connected to the conductive layer 105 through the opening 127 (see FIG. 2).

Next, the insulating layer 117 is formed over the insulating layer 115 and the conductive layer 116 (see FIG. 19C). In this manner, the semiconductor device 100A can be manufactured.

This embodiment can be implemented in combination with the other embodiments described in this specification as appropriate.

### Embodiment 2

Described in this embodiment is a metal oxide (hereinafter, also referred to as an oxide semiconductor) that can be used in the OS transistor described in the above embodiment.

The metal oxide used in the OS transistor preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method such as a metal organic chemical vapor deposition (MOCVD) method, an atomic layer deposition (ALD) method, or the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of a quartz glass substrate, which indicates that the quartz glass substrate is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### [Structure of Oxide Semiconductor]

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS includes a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one minute crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, and/or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### [Structure of Oxide Semiconductor]

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic proportions of In, Ga, and Zn in the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. For example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing indium oxide, indium zinc oxide, or the like as its main component. The second region is a region containing gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure where metal elements are unevenly distributed.

The CAC-OS can be formed by a sputtering method under a condition where a substrate is not heated intentionally, for example. Moreover, in the case of forming the CAC-OS by a sputtering method, any one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region is a region having higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region is a region having a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using the CAC-OS has high reliability. Thus, the CAC-OS is most suitable for a variety of semiconductor devices such as a display device.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor with high reliability can be achieved.

It is particularly preferable to use an oxide containing indium (In), gallium (Ga), and zinc (Zn) (also referred to as “IGZO”) for a semiconductor layer where a channel is formed. Alternatively, an oxide containing indium (In), aluminum (Al), and zinc (Zn) (also referred to as “IAZO”) may be used for the semiconductor layer. Alternatively, an oxide containing indium (In), aluminum (Al), gallium (Ga), and zinc (Zn) (also referred to as “IAGZO”) may be used for the semiconductor layer.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1× 10¹³ cm⁻³, still further preferably lower than or equal to 1× 10¹¹ cm⁻³, yet further preferably lower than 1× 10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charges trapped by the trap states in an oxide semiconductor take a long time to be released and may behave like fixed charges. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 at. % can be regarded as an impurity.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the oxide semiconductor is set lower than or equal to 2× 10¹⁸ atoms/cm³, preferably lower than or equal to 2× 10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2× 10¹⁶ atoms/cm³.

An oxide semiconductor containing nitrogen easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is measured by SIMS, is set lower than 1× 10²⁰ atoms/cm³, preferably lower than 1×10¹⁹ atoms/cm³, further preferably lower than 5×10¹⁸ atoms/cm³, still further preferably lower than 1× 10¹⁸ atoms/cm³.

When an oxide semiconductor with sufficiently reduced impurities is used for the channel formation region of the transistor, stable electrical characteristics can be given.

The structure described in this embodiment can be used in an appropriate combination with any of the structures described in the other embodiments.

### Embodiment 3

In this embodiment, a structure example of a display device 200 for which the semiconductor device 100A or the like of one embodiment of the present invention can be used will be described.

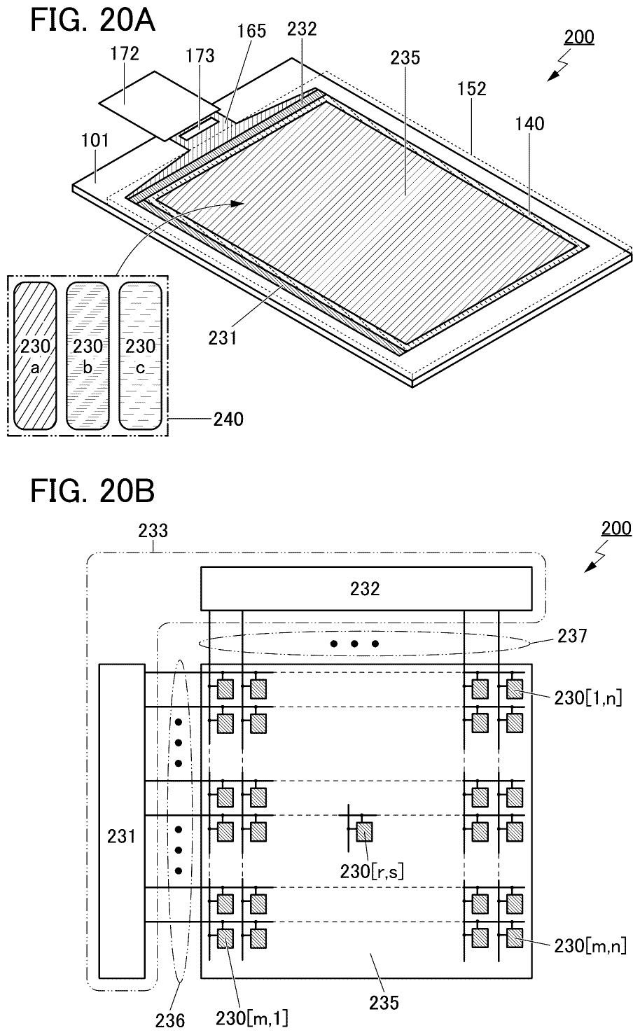

FIG. 20A is a schematic view of the display device 200. In the display device 200, a substrate 152 and the substrate 101 are bonded to each other. In FIG. 20A, the substrate 152 is denoted by a dashed line.

The display device 200 includes a display portion 235, a connection portion 140, a first driver circuit portion 231, a second driver circuit portion 232, a wiring 165, and the like. FIG. 20A illustrates an example in which an IC 173 and an FPC 172 are mounted on the display device 200. Thus, the structure illustrated in FIG. 20A can also be regarded as a display module including the display device 200, the IC (integrated circuit), and the FPC.

The connection portion 140 is provided outside the display portion 235. The connection portion 140 can be provided along one or more sides of the display portion 235. The number of the connection portions 140 can be one or more. FIG. 20A illustrates an example in which the connection portion 140 is provided to surround the four sides of the display portion. A common electrode of a light-emitting device is electrically connected to a conductive layer in the connection portion 140, so that a potential can be supplied to the common electrode.

The wiring 165 has a function of supplying a signal and electric power to the display portion 235, the first driver circuit portion 231, and the second driver circuit portion 232. The signal and electric power are input to the wiring 165 from the outside through the FPC 172 or input to the wiring 165 from the IC 173.

FIG. 20A illustrates an example in which the IC 173 is provided over the substrate 101 by a COG (Chip On Glass) method, a COF (Chip On Film) method, or the like. The IC 173 may include a scan line driver circuit or a signal line driver circuit, for example. Note that the display device 200 and the display module are not necessarily provided with an IC. The IC may be mounted on the FPC by a COF method or the like.

The display portion 235 includes a plurality of pixels 230 arranged in a matrix of m rows (m is an integer greater than or equal to 1) and n columns (n is an integer greater than or equal to 1). The plurality of pixels 230 are classified into, for example, pixels 230a, pixels 230b, and pixels 230c. The pixel 230a, the pixel 230b, and the pixel 230c have a function of emitting light of different colors. For example, the pixel 230a may have a function of emitting red (R) light, the pixel 230b may have a function of emitting green (G) light, and the pixel 230c may have a function of emitting blue (B) light. Alternatively, for example, the pixel 230a may have a function of emitting yellow (Y) light, the pixel 230b may have a function of emitting cyan (C) light, and the pixel 230c may have a function of emitting magenta (M) light.

One pixel 230a, one pixel 230b, and one pixel 230c form one pixel 240, which achieves full-color display. Thus, the pixel 230 functions as a subpixel. The display device 200 illustrated in FIG. 20A shows an example in which the pixels 230 each functioning as a subpixel are arranged in a stripe pattern. The number of subpixels for forming one pixel 240 is not limited to three, and may be four or more. For example, four subpixels which emit light of R, G, B, and white (W) may be included. Alternatively, four subpixels which emit light of four colors, R, G, B, and Y, may be included.

FIG. 20B is a block diagram illustrating the display device 200. The display device 200 includes a display portion 235, a first driver circuit portion 231, and a second driver circuit portion 232. In FIG. 20B, the pixel 230 in the first row and the n-th column is denoted as a pixel 230[1,n], the pixel 230 in the m-th row and the first column is denoted as a pixel 230[m,1], and the pixel 230 in the m-th row and the n-th column is denoted as a pixel 230[m,n]. A given pixel 230 included in the display portion 235 is denoted as a pixel 230[r, s] in some cases. Note that r is an integer greater than or equal to 1 and less than or equal to m, and s is an integer greater than or equal to 1 and less than or equal to n.

A circuit included in the first driver circuit portion 231 functions as, for example, a scan line driver circuit. A circuit included in the second driver circuit portion 232 functions as, for example, a signal line driver circuit. Note that some sort of circuit may be provided at a position facing the first driver circuit portion 231 with the display portion 235 positioned therebetween. Some sort of circuit may be provided at a position facing the second driver circuit portion 232 with the display portion 235 positioned therebetween. Note that circuits included in the first driver circuit portion 231 and the second driver circuit portion 232 are collectively referred to as a peripheral driver circuit 233.

Any of various circuits such as a shift register circuit, a level shifter circuit, an inverter circuit, a latch circuit, an analog switch circuit, a multiplexer circuit, a demultiplexer circuit, and a logic circuit can be used as a peripheral driver circuit 233. In the peripheral driver circuit 233, a transistor, a capacitor, and the like can be used. Transistors included in the peripheral driver circuit 233 may be formed in the same step as the transistors included in the pixels 230.

The display device 200 includes m wirings 236 which are arranged substantially parallel to each other and whose potentials are controlled by the circuit included in the first driver circuit portion 231, and n wirings 237 which are arranged substantially parallel to each other and whose potentials are controlled by the circuit included in the second driver circuit portion 232.

FIG. 20B illustrates an example in which the wiring 236 and the wiring 237 are connected to the pixel 230. Note that the wiring 236 and the wiring 237 are examples, and the wirings connected to the pixel 230 are not limited to the wiring 236 and the wiring 237.

### <Circuit Structure Example>

Structure examples of a NOR circuit and a NAND circuit are described as examples of a logic circuit in which the semiconductor device of one embodiment of the present invention can be used.

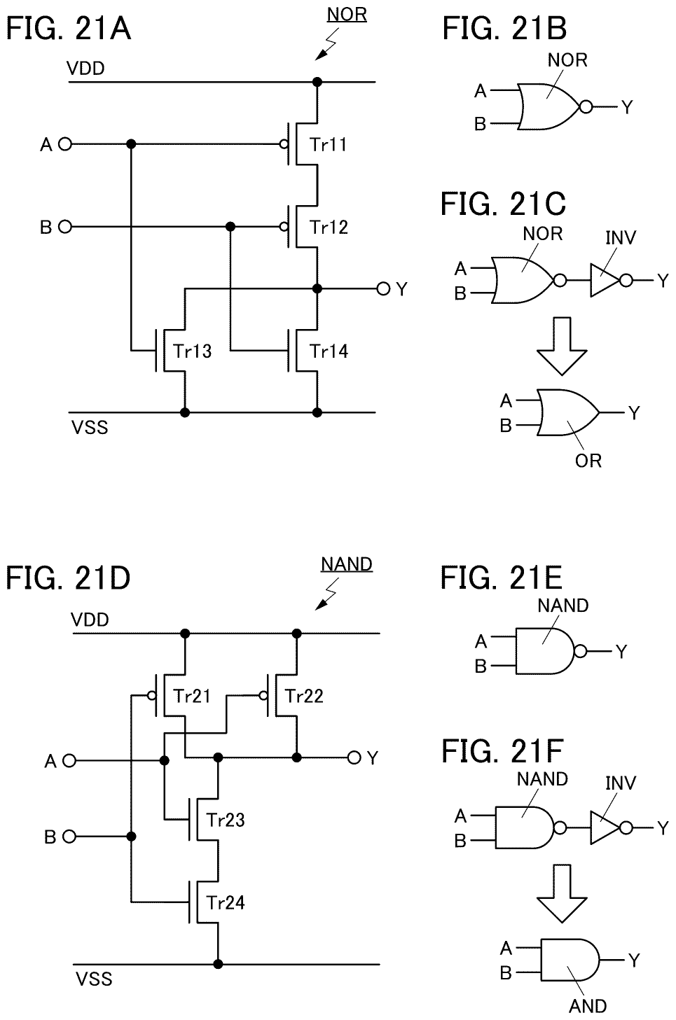

FIG. 21A is a circuit diagram illustrating a structure example of a two-input and one-output NOR circuit (NOR). FIG. 21B illustrates a circuit symbol of the NOR circuit. The NOR circuit illustrated in FIG. 21A includes a transistor Tr11, a transistor Tr12, a transistor Tr13, and a transistor Tr14. P-channel transistors are used as the transistor Tr11 and the transistor Tr12, and n-channel transistors are used as the transistor Tr13 and the transistor Tr14.

Thus, the transistor M1 can be used as each of the transistor Tr11 and the transistor Tr12. The transistor M2 can be used as each of the transistor Tr13 and the transistor Tr14.

The NOR circuit illustrated in FIG. 21A and FIG. 21B has a function of outputting the potential H (VDD) from a terminal Y when the potential L (VSS) is input to both the terminal A and the terminal B. The NOR circuit also has a function of outputting the potential L (VSS) from the terminal Y when the potential H (VDD) is input to one or both of the terminal A and the terminal B.

Furthermore, when an inverter circuit (INV) is combined with the NOR circuit as illustrated in FIG. 21C, an OR circuit (OR) can be obtained.

FIG. 21D is a circuit diagram illustrating a structure example of a two-input and one-output NAND circuit (NAND). FIG. 21E illustrates a circuit symbol of the NAND circuit. The NAND circuit illustrated in FIG. 21D includes a transistor Tr21, a transistor Tr22, a transistor Tr23, and a transistor Tr24. P-channel transistors are used as the transistor Tr21 and the transistor Tr22, and n-channel transistors are used as the transistor Tr23 and the transistor Tr24.

Thus, the transistor M1 can be used as each of the transistor Tr21 and the transistor Tr22. The transistor M2 can be used as each of the transistor Tr23 and the transistor Tr24.

The NAND circuit illustrated in FIG. 21D and FIG. 21E has a function of outputting the potential L (VSS) from the terminal Y when the potential H (VDD) is input to both the terminal A and the terminal B. The NAND circuit also has a function of outputting the potential H (VDD) from the terminal Y when the potential L (VSS) is input to one or both of the terminal A and the terminal B.

Furthermore, when an inverter circuit (INV) is combined with the NAND circuit as illustrated in FIG. 21F, an AND circuit (AND) can be obtained.

Next, a structure example of a D flip-flop circuit (DFF: Delay Flip Flop) is described as an example of a circuit in which the semiconductor device of one embodiment of the present invention can be used.

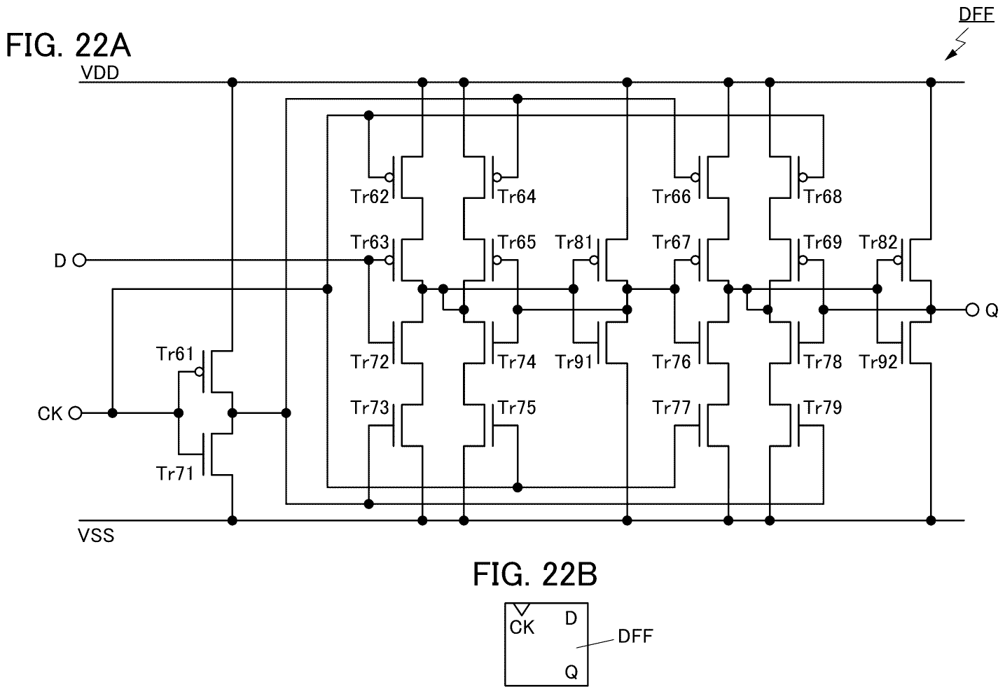

FIG. 22A is a circuit diagram illustrating a structure example of a D flip-flop circuit (DFF). FIG. 22B illustrates a circuit symbol of the D flip-flop circuit. The D flip-flop circuit illustrated in FIG. 22A includes a transistor Tr61 to a transistor Tr69, a transistor Tr71 to a transistor Tr79, a transistor Tr81, a transistor Tr82, a transistor Tr91, and a transistor Tr92. P-channel transistors are used as the transistor Tr61 to the transistor Tr69, the transistor Tr81, and the transistor Tr82, and n-channel transistors are used as the transistor Tr71 to the transistor Tr79, the transistor Tr91, and the transistor Tr92.

Thus, the transistor M1 can be used as each of the transistor Tr61 to the transistor Tr69, the transistor Tr81, and the transistor Tr82. The transistor M2 can be used as each of the transistor Tr71 to the transistor Tr79, the transistor Tr91, and the transistor Tr92.

The DFF illustrated in FIG. 22A and FIG. 22B includes a clock signal input terminal CK, an input terminal D, and an output terminal Q. In the DFF illustrated in FIG. 22A and FIG. 22B, data (potential) of the input terminal D is written while the potential H is input to the clock signal input terminal CK. When a signal that is input to the clock signal input terminal CK is changed from the potential H to the potential L, the DFF has a function of storing the data until the potential H is input to the clock signal input terminal CK next. A signal (the potential H or the potential L) based on the data held in the DFF is constantly continually output from the output terminal Q.

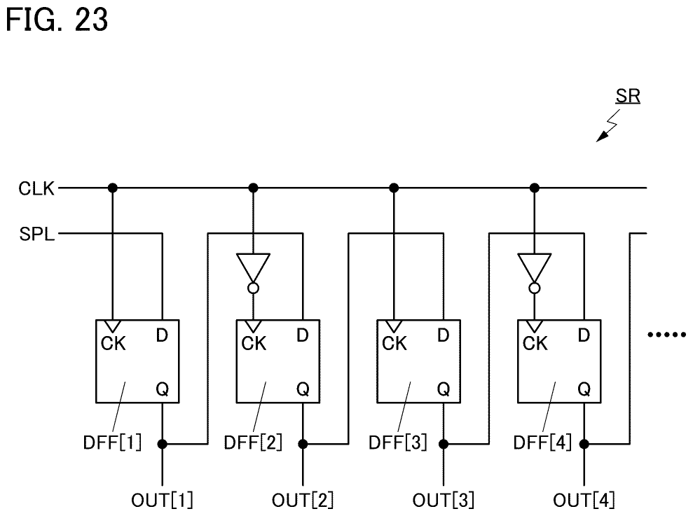

FIG. 23 is a block diagram illustrating a structure example of a shift register circuit (SR). The SR includes a plurality of DFFs. In this specification and the like, the DFF in the first stage is denoted by “DFF[1]”, and a potential (data) output from the output terminal Q of the DFF[1] is denoted by “data OUT1”. FIG. 23 is a block diagram of SR including four stages of DFFs (the DFF[1] to the DFF[4]). In FIG. 23, data output from the output terminals Q of DFF[1] to DFF[4] is referred to as data OUT [1] to data OUT [4], respectively.

The data OUT [1] is input to the input terminal D of the DFF[2], the data OUT [2] is input to the input terminal D of the DFF[3], and the data OUT [3] is input to the input terminal D of the DFF[4].

A signal SPL is input to the input terminal D of DFF[1]. The signal SPL input to the DFF[1] is sequentially transferred to the DFF in the subsequent stage in synchronization with the clock signal CLK. The data OUT is a value corresponding to data held in the DFF. The timing at which the value of the data OUT changes is synchronized with the clock signal CLK. The SR can sequentially switch the data OUT output from the plurality of DFFs in synchronization with the clock signal CLK.

A structure example of a latch circuit LAT is described as an example of a circuit in which the semiconductor device of one embodiment of the present invention can be used.

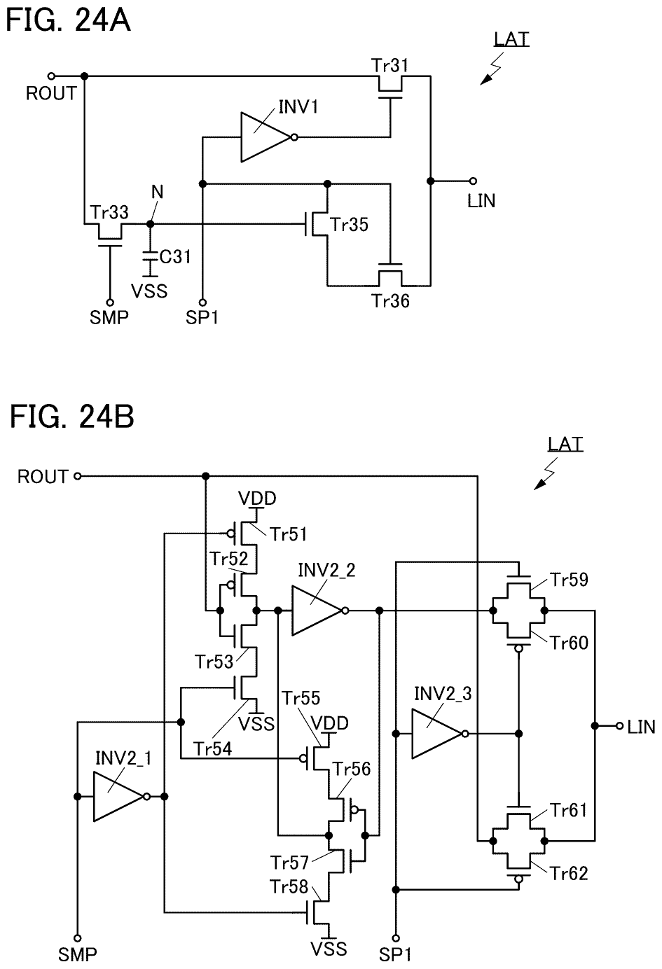

FIG. 24A is a circuit diagram illustrating a structure example of a latch circuit LAT. The latch circuit LAT illustrated in FIG. 24A includes a transistor Tr31, a transistor Tr33, a transistor Tr35, a transistor Tr36, a capacitor C31, and an inverter circuit INV1. In FIG. 24A, a node that is electrically connected to one of a source and a drain of the transistor Tr33, a gate of the transistor Tr35, and one electrode of the capacitor C31 is referred to as a node N.

In the latch circuit LAT illustrated in FIG. 24A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is held and the data written to the latch circuit LAT is held. Specifically, when the potential of the node N is a low potential, data “0” is held in the latch circuit LAT and when the potential of the node N is a high potential, data “1” is held in the latch circuit LAT, for example.

A transistor with a low off-state current, such as an OS transistor, is preferably used as the transistor Tr33. Thus, the latch circuit LAT can hold data for a long period. Thus, the frequency of rewriting data in the latch circuit LAT can be lowered.

FIG. 24B illustrates a structure example of a latch circuit LAT that is different from the latch circuit LAT in FIG. 24A. The latch circuit LAT illustrated in FIG. 24B includes a transistor Tr51, a transistor Tr52, a transistor Tr53, a transistor Tr54, a transistor Tr55, a transistor Tr56, a transistor Tr57, a transistor Tr58, a transistor Tr59, a transistor Tr60, a transistor Tr61, a transistor Tr62, an inverter circuit INV 2_1, an inverter circuit INV 2_2, and an inverter circuit INV 2_3.

The transistor Tr59 and the transistor Tr60 form one analog switch circuit. The transistor Tr61 and the transistor Tr62 form one analog switch circuit.

The transistor Tr53, the transistor Tr54, the transistor Tr57, the transistor Tr58, the transistor Tr59, and the transistor Tr61 can be n-channel transistors. The transistor Tr51, the transistor Tr52, the transistor Tr55, the transistor Tr56, the transistor Tr60, and the transistor Tr62 can be p-channel transistors.

The transistor Tr53, the transistor Tr54, the transistor Tr57, the transistor Tr58, the transistor Tr59, and the transistor Tr61 can be OS transistors or Si transistors, for example. The transistor Tr51, the transistor Tr52, the transistor Tr55, the transistor Tr56, the transistor Tr60, and the transistor Tr62 can be Si transistors, for example.

As described above, by inputting a high-potential signal to the terminal SMP, data corresponding to a signal input to the latch circuit LAT from the terminal ROUT is written to the latch circuit LAT. For example, when the potential of the terminal ROUT is a low potential, data “0” can be written to the latch circuit LAT, and when the potential of the terminal ROUT is a high potential, data “1” can be written to the latch circuit LAT. After data is written to the latch circuit LAT, the potential of the terminal SMP is set to a low potential, whereby data written to the latch circuit LAT is held.

When the potential of the terminal SP1 is a low potential, the latch circuit LAT can output a signal input from the terminal ROUT to the terminal LIN. In the latch circuit LAT, when the potential of the terminal SP1 is a high potential and data “0” is held in the latch circuit LAT, it is possible that a signal is not output from the terminal LIN or the potential of the terminal LIN is a low potential. In addition, when the potential of the terminal SP1 is a high potential and data “1” is held in the latch circuit LAT, the latch circuit LAT can output a signal input from the terminal SP1 to the terminal LIN.

In this specification and the like, data that allows a signal input from a terminal SP1 to be output to a terminal LIN is written to the latch circuit LAT, which is referred to simply as “writing data to the latch circuit LAT” in some cases. That is, for example, data “1” is written to the latch circuit LAT, which is referred to simply as “writing data to the latch circuit LAT” in some cases.

The semiconductor device 100A or the like of one embodiment of the present invention can be used as the inverter circuit INV1, the inverter circuit INV2_1, the inverter circuit INV2_2, and the inverter circuit INV2_3.

The transistor M1 can be used as a p-channel transistor included in the latch circuit LAT. The transistor M1 or the transistor M2 can be used as an n-channel transistor included in the latch circuit LAT. The semiconductor device 100A or the like of one embodiment of the present invention can be used in a variety of circuits.

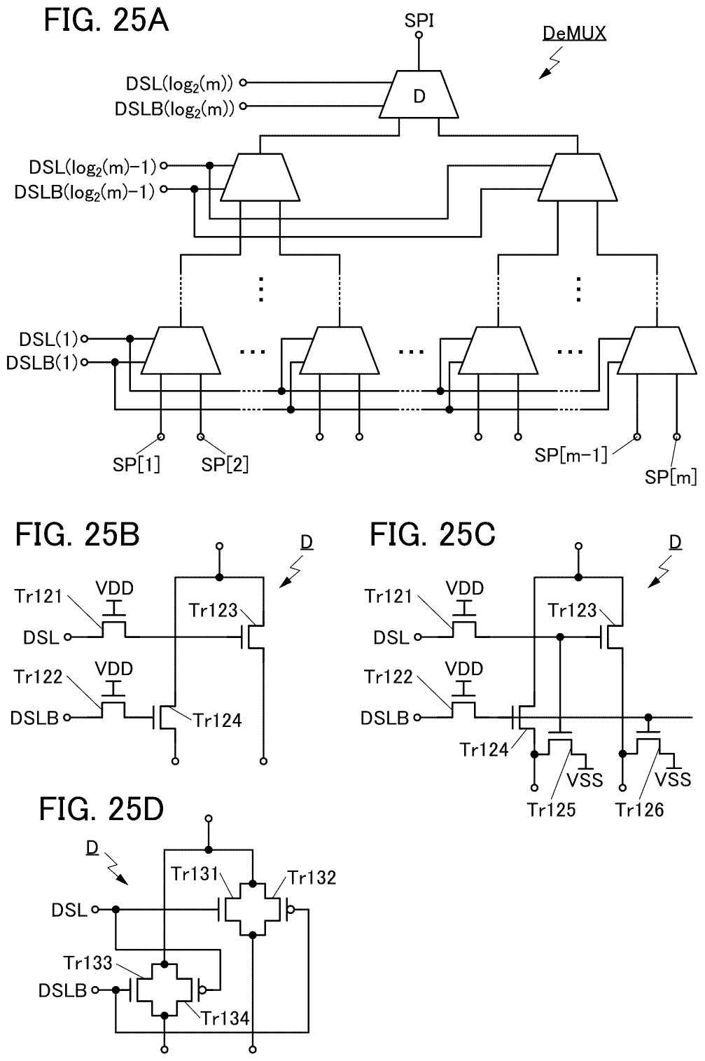

FIG. 25A is a circuit diagram illustrating a structure example of a demultiplexer circuit DeMUX. The demultiplexer circuit DeMUX includes a demultiplexer circuit D.

The demultiplexer circuit DeMUX has a structure in which one path is branched into two paths in every stage, and includes m paths in total. In other words, the demultiplexer circuits D are connected to each other in a tournament system. An input terminal of the demultiplexer circuit D in the first stage is electrically connected to the terminal SPI. Output terminals of each of the demultiplexer circuits D in the log₂(m)-th stage, which is the final stage, are electrically connected to two terminals SP (a terminal SP[1] and a terminal SP[2]).

Selection signal input terminals of the demultiplexer circuit D are electrically connected to the terminal DSL and a terminal DSLB. In this case, a complementary signal of a signal input to the terminal DSL is input to the terminal DSLB. For example, when a 1-bit digital signal with the value of “0” is input to the terminal DSL(1), a 1-bit digital signal with the value of “1” is input to a terminal DSLB(1). In contrast, when a 1-bit digital signal with the value of “1” input to the terminal DSL(1), a 1-bit digital signal with the value of “0” is input to the terminal DSLB(1). The same applies to a terminal DSLB(2) to a terminal DSLB(log₂(m)).

Having the structure illustrated in FIG. 25A, the demultiplexer circuit DeMUX can output a signal input to the terminal SPI, to the terminals SP corresponding to the values expressed by the signals input to the terminal DSL(1) to the terminal DSL(log₂(m)).

FIG. 25B, FIG. 25C, and FIG. 25D are circuit diagrams each illustrating a structure example of the demultiplexer circuit D. The demultiplexer circuit D having the structure illustrated in FIG. 25B includes a transistor Tr121, a transistor Tr122, a transistor Tr123, and a transistor Tr124. The transistor Tr121 to the transistor Tr124 can be n-channel transistors, for example.

In the demultiplexer circuit D having the structure illustrated in FIG. 25B, the terminal DSL is electrically connected to one of a source and a drain of the transistor Tr121. The other of the source and the drain of the transistor Tr121 is electrically connected to a gate of the transistor Tr123. The terminal DSLB is electrically connected to one of a source and a drain of the transistor Tr122. The other of the source and the drain of the transistor Tr122 is electrically connected to a gate of the transistor Tr124. One of a source and a drain of the transistor Tr123 and one of a source and a drain of the transistor Tr124 are electrically connected to the input terminal of the demultiplexer circuit D. The other of the source and the drain of the transistor Tr123 is electrically connected to a first output terminal of the demultiplexer circuit D. The other of the source and the drain of the transistor Tr124 is electrically connected to a second output terminal of the demultiplexer circuit D. Furthermore, a high potential can be supplied to a gate of the transistor Tr121 and a gate of the transistor Tr122.

In the demultiplexer circuit D having the structure illustrated in FIG. 25B, when the potential of the terminal DSL is a high potential and the potential of the terminal DSLB is a low potential, the transistor Tr123 is in an on state and the transistor Tr124 is in an off state. Thus, a signal input from the input terminal of the demultiplexer circuit D is output from the first output terminal of the demultiplexer circuit D. In contrast, when the potential of the terminal DSL is a low potential and the potential of the terminal DSLB is a high potential, the transistor Tr123 is in an off state and the transistor Tr124 is in an on state. Thus, the signal input from the input terminal of the demultiplexer circuit D is output from the second output terminal of the demultiplexer circuit D.

FIG. 25C is a variation example of the demultiplexer circuit D illustrated in FIG. 25B. The demultiplexer circuit D illustrated in FIG. 25C is different from the demultiplexer circuit D illustrated in FIG. 25B in that a transistor Tr125 and a transistor Tr126 are included.

In the demultiplexer circuit D having the structure illustrated in FIG. 25C, one of a source and a drain of the transistor Tr125 is electrically connected to the second output terminal of the demultiplexer circuit D, and a gate of the transistor Tr125 is electrically connected to the gate of the transistor Tr123. One of a source and a drain of the transistor Tr126 is electrically connected to the first output terminal of the demultiplexer circuit D, and a gate of the transistor Tr126 is electrically connected to the gate of the transistor Tr124. A low potential can be supplied to the other of the source and the drain of the transistor Tr125 and the other of the source and the drain of the transistor Tr126.

In the demultiplexer circuit D having the structure illustrated in FIG. 25C, when the potential of the terminal DSL is a high potential and the potential of the terminal DSLB is a low potential, the transistor Tr123 and the transistor Tr125 are in on states and the transistor Tr124 and the transistor Tr126 are in off states. Thus, the signal input from the input terminal of the demultiplexer circuit D is output from the first output terminal of the demultiplexer circuit D and the potential of the second output terminal of the demultiplexer circuit D becomes a low potential. On the other hand, in the case where the potential of the terminal DSL is a low potential and the potential of the terminal DSLB is a high potential, the transistor Tr123 and the transistor Tr125 are in off states and the transistor Tr124 and the transistor Tr126 are in on states. Thus, the signal input from the input terminal of the demultiplexer circuit D is output from the second output terminal of the demultiplexer circuit D and the potential of the first output terminal of the demultiplexer circuit D becomes a low potential.

The demultiplexer circuit D having the structure illustrated in FIG. 25D includes a transistor Tr131, a transistor Tr132, a transistor Tr133, and a transistor Tr134. The transistor Tr131 and the transistor Tr133 can be n-channel transistors, and the transistor Tr132 and the transistor Tr134 can be p-channel transistors.

In the demultiplexer circuit D having the structure illustrated in FIG. 25D, the terminal DSL is electrically connected to a gate of the transistor Tr131 and a gate of the transistor Tr134. The terminal DSLB is electrically connected to a gate of the transistor Tr132 and a gate of the transistor Tr133. An input terminal of the demultiplexer circuit D is electrically connected to one of a source and a drain of the transistor Tr131, one of a source and a drain of the transistor Tr132, one of a source and a drain of the transistor Tr133, and one of a source and a drain of the transistor Tr134. The other of the source and the drain of the transistor Tr131 and the other of the source and the drain of the transistor Tr132 are electrically connected to the first output terminal of the demultiplexer circuit D. The other of the source and the drain of the transistor Tr133 and the other of the source and the drain of the transistor Tr134 are electrically connected to the second output terminal of the demultiplexer circuit D.

In the demultiplexer circuit D having the structure illustrated in FIG. 25D, when the potential of the terminal DSL is a high potential and the potential of the terminal DSLB is a low potential, the transistor Tr131 and the transistor Tr132 are in on states and the transistor Tr133 and the transistor Tr134 are in off states. Thus, the signal input from the input terminal of the demultiplexer circuit D is output from the first output terminal of the demultiplexer circuit D. On the other hand, when the potential of the terminal DSL is a low potential and the potential of the terminal DSLB is a high potential, the transistor Tr131 and the transistor Tr132 are in off states and the transistor Tr133 and the transistor Tr134 are in on states. Thus, the signal input from the input terminal of the demultiplexer circuit D is output from the second output terminal of the demultiplexer circuit D.

The semiconductor device of one embodiment of the present invention can be used in the demultiplexer circuit D. The transistor M1 can be used as a p-channel transistor included in the demultiplexer circuit D. The transistor M1 or the transistor M2 can be used as the n-channel transistor included in the demultiplexer circuit D.

### <Structure Example of Pixel Circuit>

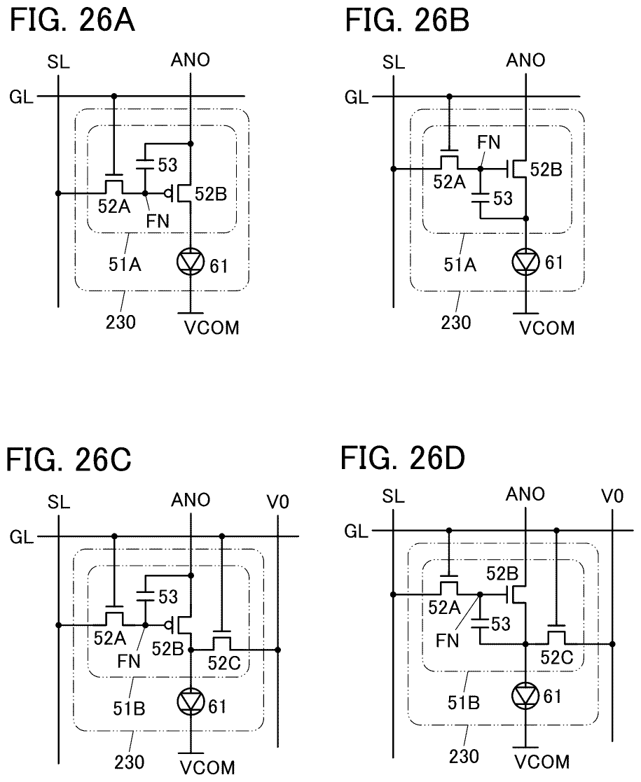

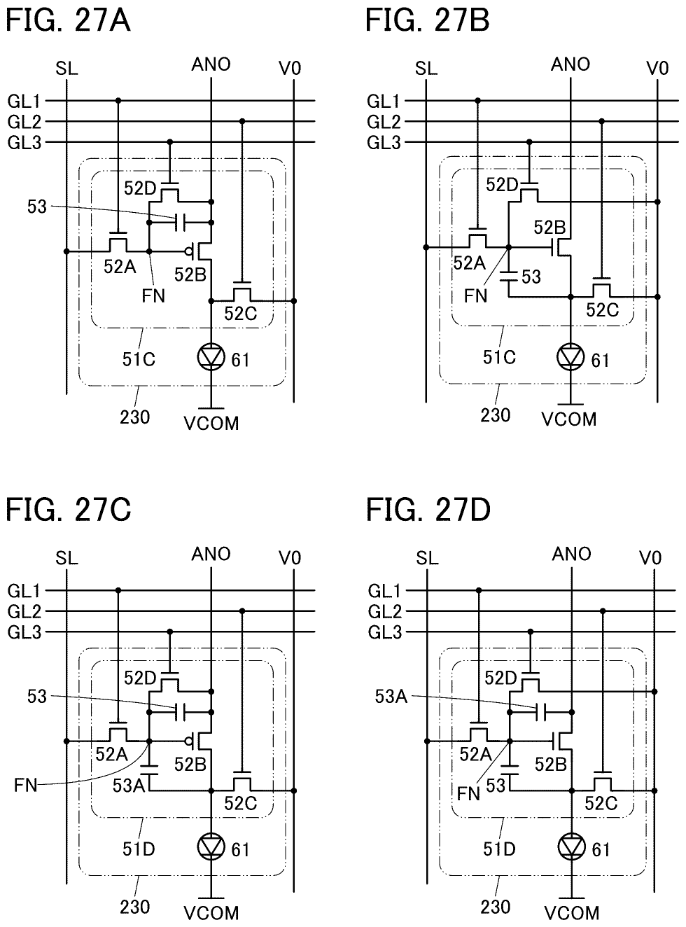

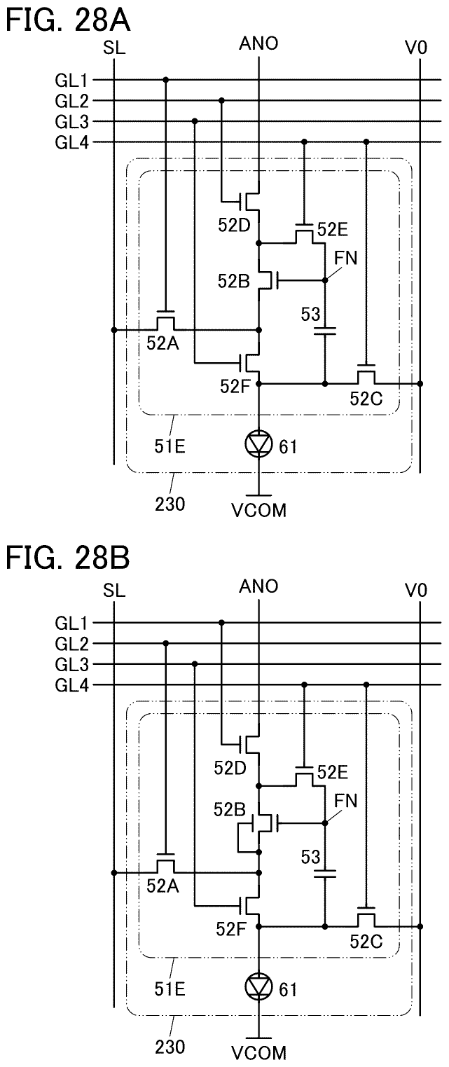

FIG. 26A to FIG. 26D, FIG. 27A to FIG. 27D, FIG. 28A, and FIG. 28B illustrate structure examples of the pixel 230. The pixel 230 includes a pixel circuit 51 (a pixel circuit 51A, a pixel circuit 51B, a pixel circuit 51C, a pixel circuit 51D, or a pixel circuit 51E) and a light-emitting device 61.

The light-emitting element (also referred to as a light-emitting device) described in this embodiment and the like refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

The pixel circuit 51A illustrated in FIG. 26A is a 2Tr1C-type pixel circuit including a transistor 52A, a transistor 52B, and a capacitor 53.

One of a source and a drain of the transistor 52A is electrically connected to a wiring SL, and a gate of the transistor 52A is electrically connected to a wiring GL. The other of the source and the drain of the transistor 52A is electrically connected to a gate of the transistor 52B. The one of the source and the drain of the transistor 52B and one terminal of the capacitor 53 are electrically connected to a wiring ANO. The other terminal of the capacitor 53 is electrically connected to the gate of the transistor 52B. A region where the other of the source and the drain of the transistor 52A, the gate of the transistor 52B, and the other terminal of the capacitor 53 are electrically connected serves as a node FN. The other of the source and the drain of the transistor 52B is electrically connected to an anode of the light-emitting element 61. A cathode of the light-emitting element 61 is electrically connected to a wiring VCOM.

The wiring GL corresponds to the wiring 236, and the wiring SL corresponds to the wiring 237. The wiring VCOM is a wiring for supplying a potential for supplying current to the light-emitting element 61. The transistor 52A has a function of controlling the conduction state and the non-conduction state between the wiring SL and the gate of the transistor 52B in accordance with the potential of the wiring GL. For example, VDD is supplied to the wiring ANO, and VSS is supplied to the wiring VCOM.

When the transistor 52A is turned on, an image signal is supplied from the wiring SL to the node FN. After that, when the transistor 52A is turned off, the image signal is held in the node FN. In order to surely hold the image signal supplied to the node FN, a transistor with a low off-state current is preferably used as the transistor 52A. For example, an OS transistor is preferably used as the transistor 52A.

The transistor 52B has a function of controlling the amount of current flowing through the light-emitting element 61. The capacitor 53 has a function of holding a gate potential of the transistor 52B. The intensity of light emitted by the light-emitting element 61 is controlled in accordance with an image signal supplied to the gate of the transistor 52B (the node FN).

In the pixel circuit 51A illustrated in FIG. 26A, an n-channel transistor is used as the transistor 52A and a p-channel transistor is used as the transistor 52B. Note that an n-channel transistor may be used as the transistor 52B as in the pixel circuit 51A illustrated in FIG. 26B. When an n-channel transistor is used as the transistor 52B, the one terminal of the capacitor 53 may be electrically connected to the other of the source or the drain of the transistor 52B.

The pixel circuit 51B illustrated in FIG. 26C is a 3Tr1C-type pixel circuit including the transistor 52A, the transistor 52B, a transistor 52C, and a capacitor 53. The pixel circuit 51B illustrated in FIG. 26C has a structure in which a transistor 52C is added to the pixel circuit 51A illustrated in FIG. 26A.

When an n-channel transistor is used as the transistor 52B, a circuit configuration of the pixel circuit 51B in FIG. 26D may be employed. The pixel circuit 51B illustrated in FIG. 26D has a structure in which the transistor 52C is added to the pixel circuit 51A illustrated in FIG. 26B.

One of a source and a drain of the transistor 52C is electrically connected to the other of the source and the drain of the transistor 52B. The other of the source and the drain of the transistor 52C is electrically connected to a wiring V0. For example, a reference potential is supplied to the wiring V0.

The transistor 52C has a function of controlling the conduction state or the non-conduction state between the wiring V0 and the other of the source and the drain of the transistor 52B in accordance with the potential of the wiring GL. The wiring V0 is a wiring for supplying a reference potential. In the case where an n-channel transistor is used as the transistor 52B, a variation in the gate-source potential of the transistor 52B can be reduced by the reference potential of the wiring V0 supplied through the transistor 52C.

A current value that can be used for setting of pixel parameters can be obtained using the wiring V0. Specifically, the wiring V0 can function as a monitor line for outputting a current flowing through the transistor 52B or a current flowing through the light-emitting element 61 to the outside. A current output to the wiring V0 can be converted into a voltage by a source follower circuit or the like and output to the outside. For another example, the current can be converted into a digital signal by an A/D converter or the like and can be output to the outside.

The pixel circuit 51C illustrated in FIG. 27A has a structure in which a transistor 52D is added to the pixel circuit 51B illustrated in FIG. 26C. The pixel circuit 51 C illustrated in FIG. 27A is a 4Tr1C-type pixel circuit including the transistor 52A, the transistor 52B, the transistor 52C, the transistor 52D, and the capacitor 53.

One of a source and a drain of the transistor 52D is electrically connected to the wiring ANO, and the other is electrically connected to the other of the source and the drain of the transistor 52A, the other terminal of the capacitor 53, and the gate of the transistor 52B. A region where the other of the source and the drain of the transistor 52D, the other of the source and the drain of the transistor 52A, the other terminal of the capacitor 53, and the gate of the transistor 52B are electrically connected to one another functions as the node FN.

A wiring GL1, a wiring GL2, and a wiring GL3 are electrically connected to the pixel circuit 51C. Note that in this embodiment and the like, the wiring GL1, the wiring GL2, and the wiring GL3 are collectively referred to as the wiring GL in some cases. Thus, the wiring GL is not limited to one wiring and consists of a plurality of wirings in some cases.

The wiring GL1 is electrically connected to the gate of the transistor 52A, the wiring GL2 is electrically connected to the gate of the transistor 52C, and the wiring GL3 is electrically connected to a gate of the transistor 52D.

When the transistor 52D is turned on, the source and the gate of the transistor 52B have the same potential, so that the transistor 52B can be turned off. Thus, a current flowing through the light-emitting element 61 can be blocked forcibly. Such a pixel circuit is suitable for the case of using a display method in which a display period and a non-lighting period are alternately provided. The transistor 52C may be turned on at the same time when the transistor 52D is turned on.

In the pixel circuit 51C illustrated in FIG. 27A, n-channel transistors are used as the transistor 52A, the transistor 52C, and the transistor 52D and a p-channel transistor is used as the transistor 52B. Note that an n-channel transistor may be used as the transistor 52B as in the pixel circuit 51C illustrated in FIG. 27B. In the case where an n-channel transistor is used as the transistor 52B, the one terminal of the capacitor 53 is electrically connected to the other of the source and the drain of the transistor 52B. The one of the source and the drain of the transistor 52D is electrically connected to the wiring V0.

The pixel circuit 51D illustrated in FIG. 27C has a configuration in which a capacitor 53A is added to the pixel circuit 51C illustrated in FIG. 27A. In the pixel circuit 51D illustrated in FIG. 27C, one terminal of the capacitor 53A is electrically connected to the other of the source and the drain of the transistor 52B, and the other terminal is electrically connected to the gate of the transistor 52B. A region where the other of the source and the drain of the transistor 52D, the other of the source and the drain of the transistor 52A, the other terminal of the capacitor 53, the other terminal of the capacitor 53A, and the gate of the transistor 52B are electrically connected to one another functions as the node FN.

The pixel circuit 51D illustrated in FIG. 27D has a configuration in which the capacitor 53A is added to the pixel circuit 51C illustrated in FIG. 27B. In the pixel circuit 51D illustrated in FIG. 27D, the one terminal of the capacitor 53A is electrically connected to the wiring ANO, and the other terminal is electrically connected to the gate of the transistor 52B. The capacitor 53 and the capacitor 53A function as a storage capacitor. The pixel circuits 51D illustrated in FIG. 27C and FIG. 27D are 4Tr2C-type pixel circuits.

Each of the transistor 52A, the transistor 52B, the transistor 52C, and the transistor 52D preferably includes a back gate electrode, in which case the same signal can be supplied to the back gate electrode and the gate electrode or different signals can be supplied to the back gate electrode and the gate electrode.

P-channel transistors may be used not only as the transistor 52B but also as the transistor 52A, the transistor 52C, and the transistor 52D.

The pixel circuit 51E illustrated in FIG. 28A is a 6Tr1C-type pixel circuit including the transistor 52A, the transistor 52B, the transistor 52C, the transistor 52D, a transistor 52E, a transistor 52F, and the capacitor 53.

The one of the source and the drain of the transistor 52A is electrically connected to the wiring SL, and the gate of the transistor 52A is electrically connected to the wiring GL1. The one of the source and the drain of the transistor 52D is electrically connected to the wiring ANO, and the gate of the transistor 52D is electrically connected to the wiring GL2. The other of the source and the drain of the transistor 52D is electrically connected to the one of the source and the drain of the transistor 52B. The other of the source and the drain of the transistor 52B is electrically connected to the other of the source and the drain of the transistor 52A and one of a source and a drain of the transistor 52F. A gate of the transistor 52F is electrically connected to the wiring GL3.

One of a source and a drain of the transistor 52E is electrically connected to the other of the source and the drain of the transistor 52D and the one of the source and the drain of the transistor 52B. The other of the source and the drain of the transistor 52E is electrically connected to the gate of the transistor 52B and the one terminal of the capacitor 53. The other terminal of the capacitor 53 is electrically connected to the other of the source and the drain of the transistor 52F, the anode of the light-emitting element 61, and one of a source and the drain of the transistor 52C. A gate of the transistor 52E and the gate of the transistor 52C are electrically connected to a wiring GL4. The other of the source and the drain of the transistor 52C is electrically connected to the wiring V0. A region where the other of the source and the drain of the transistor 52E, the gate of the transistor 52B, and the one terminal of the capacitor 53 are electrically connected serves as the node FN.

In the pixel circuit 51E illustrated in FIG. 28A, n-channel transistors are used as the transistor 52A to the transistor 52F. For example, an n-channel Si transistor may be used as the transistor 52B functioning as a driving transistor, and OS transistors may be used as the transistor 52A and the transistor 52C to the transistor 52F. The transistor M1 described in the above embodiment may be used as the Si transistor, and the transistor M2 described in the above embodiment may be used as the OS transistor. Specifically, in order to surely hold the image signal supplied to the node FN, an OS transistor is preferably used as the transistor 52E.

The transistor 52B functioning as a driving transistor is preferably a normally-off transistor. In particular, a Si transistor is suitable for the transistor 52B because the Si transistor can easily become a normally-off transistor by channel doping. Note that an OS transistor may be used as the transistor 52B as long as the OS transistor is a normally-off transistor.

As illustrated in FIG. 28B, a transistor having a back gate may be used as the transistor 52B. The back gate of the transistor 52B is electrically connected to the gate of the transistor 52B or the other of the source and the drain of the transistor 52B.

Although an n-channel transistor is used as the transistor 52B functioning as a driving transistor in FIG. 28A and FIG. 28B, a p-channel transistor may be used as the transistor 52B.

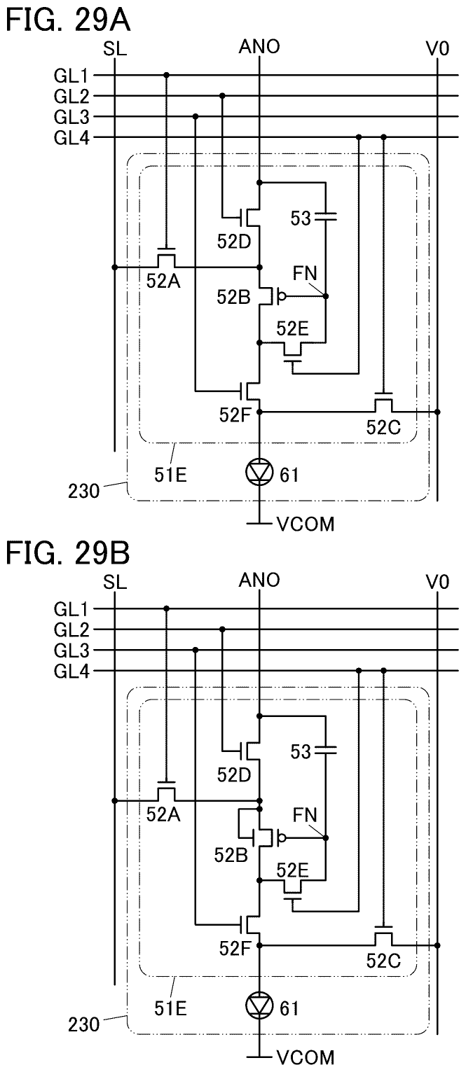

FIG. 29A illustrates the pixel circuit 51E in which a p-channel transistor is used as the transistor 52B. The pixel circuit 51E illustrated in FIG. 29A is different from the pixel circuit 51E illustrated in FIG. 28A in connection between the transistor 52A, the transistor 52E, and the capacitor 53. In the pixel circuit 51E illustrated in FIG. 29A, the other of the source and the drain of the transistor 52A is electrically connected to the other of the source and the drain of the transistor 52D and one of the source and the drain of the transistor 52B. The other terminal of the capacitor 53 is electrically connected to the one of the source and the drain of the transistor 52D. The one of the source and the drain of the transistor 52E is electrically connected to the other of the source and the drain of the transistor 52B.

As the pixel circuit 51E illustrated in FIG. 29B, a p-channel transistor having a back gate may be used as the transistor 52B. In the case where a p-channel transistor is used as the transistor 52B, the back gate of the transistor 52B is electrically connected to the gate of the transistor 52B or the one of the source and the drain of the transistor 52B. FIG. 29B illustrates an example in which the back gate of the transistor 52B is electrically connected to the one of the source and the drain of the transistor 52B.

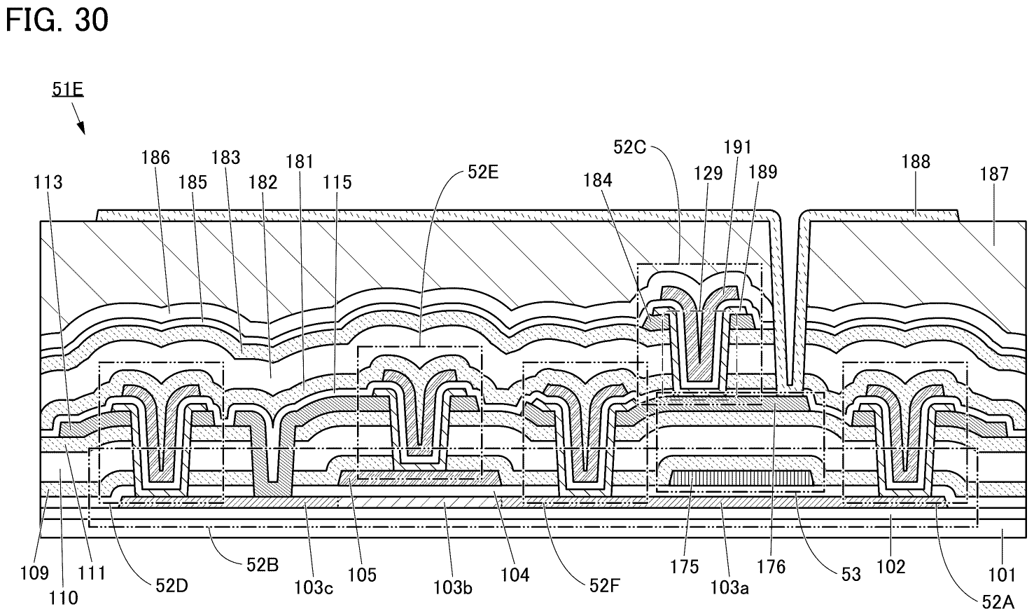

The structure of the semiconductor device 100 (the semiconductor device 100A to the semiconductor device 100L) of one embodiment of the present invention can be employed not only for a driver circuit of a display device but also for a pixel circuit. FIG. 30 is a cross-sectional view illustrating a structure example of the pixel circuit 51E. In order to reduce repeated description, portions that are not described in the other embodiments are mainly described in this embodiment. Thus, the other embodiments may be referred to for matters not described in this embodiment.

In the structure example of the pixel circuit 51E illustrated in FIG. 30, the transistor 52A, the transistor 52D, and the transistor 52F each have a structure similar to that of the transistor M2 illustrated in FIG. 12B. The transistor 52E has a structure similar to that of the transistor M2 illustrated in FIG. 9B. The transistor 52B has a structure similar to that of the transistor M1 illustrated in FIG. 9B.

In the structure example of the pixel circuit 51E illustrated in FIG. 30, a conductive layer 175 is provided over the insulating layer 104. The conductive layer 175 is formed over the insulating layer 104 after the step of introducing an impurity element for forming the drain region 103a and the source region 103c into the semiconductor layer 103 and before the formation of the insulating layer 109. The conductive layer 175 may be formed using the same material and the same manufacturing method as those of the conductive layer 105.

A conductive layer 176 is provided over the insulating layer 111. The conductive layer 176 can be formed with the same material and in the same manufacturing step as the conductive layer 113 at the same time. The conductive layer 176 functions as the other of the source and the drain of the transistor 52F. A region where the conductive layer 175 and the conductive layer 176 overlap with each other functions as the capacitor 53. The conductive layer 175 functions as one terminal of the capacitor 53. The conductive layer 175 is electrically connected to the conductive layer 105 in a region which is not illustrated in the drawing.

In the structure example of the pixel circuit 51E illustrated in FIG. 30, an insulating layer 181 is provided instead of the insulating layer 117. An insulating layer 182 is provided over the insulating layer 181, and an insulating layer 183 is provided over the insulating layer 182. The insulating layer 181 may be formed using a material and a method similar to those of the insulating layer 109. The insulating layer 182 may be formed using a material and a method similar to those of the insulating layer 110. The insulating layer 183 may be formed using a material and a method similar to those of the insulating layer 111.

A conductive layer 184 is provided over the insulating layer 183. The conductive layer 184 may be formed using a material and a method similar to those of the conductive layer 113. In a region overlapping with the conductive layer 176, an opening 129 is provided in parts of the conductive layer 184, the insulating layer 183, the insulating layer 182, the insulating layer 181, and the insulating layer 115, and the transistor 52C is provided in a region including the opening 129.

The transistor 52C has a structure similar to that of the transistor M2 illustrated in FIG. 1B. Specifically, the transistor 52C includes a semiconductor layer 189 in the opening 129, part of the semiconductor layer 189 is electrically connected to the conductive layer 176, and another part of the semiconductor layer 189 is electrically connected to the conductive layer 184. The conductive layer 176 functions as one of the source and the drain of the transistor 52C. The conductor 184 functions as the other of the source and the drain of the transistor 52C. The semiconductor layer 189 may be formed using a material and a method similar to those of the semiconductor layer 114. An insulating layer 185 is provided over the insulating layer 183 and the semiconductor layer 189. The insulating layer 185 may be formed using a material and a method similar to those of the insulating layer 115. Part of the insulating layer 185 functions as a gate insulating layer of the transistor 52C.

A conductive layer 191 including a region overlapping with the opening 129 is provided over the insulating layer 185. The conductive layer 191 may be formed using a material and a method similar to those of the conductive layer 116. Part of the conductive layer 191 functions as a back gate electrode of the transistor 52C. An insulating layer 186 is provided over the insulating layer 185 and the conductive layer 191, and an insulating layer 187 is provided over the insulating layer 186. The insulating layer 186 may be formed using a material and a method similar to those of the insulating layer 117.

The insulating layer 187 preferably serves as a planarization layer for reducing a difference in level generated by a transistor, a capacitor, a wiring, and the like below the insulating layer 187. An organic insulating film is suitable as a material functioning as a planarization layer. Examples of materials that can be used for the organic insulating film include an acrylic resin, an epoxy resin, polyimide, polyamide, polyimide amide, a siloxane resin, a benzocyclobutene-based resin, a phenol resin, and precursors of these resins. After the insulating layer 187 is formed with an inorganic material or an organic material, planarization treatment using a chemical mechanical polishing (CMP) method or the like may be performed on the insulating layer 187.

In the structure example of the pixel circuit 51E illustrated in FIG. 30, a conductive layer 188 functioning as an anode of the light-emitting element 61 is provided over the insulating layer 187. In a region overlapping with the conductive layer 176, an opening is provided in parts of the insulating layer 187, the insulating layer 186, the insulating layer 185, the conductive layer 184, the insulating layer 183, the insulating layer 182, the insulating layer 181, and the insulating layer 115. The conductive layer 188 is electrically connected to the conductive layer 176 at a bottom portion of the opening. The conductive layer 188 corresponds to, for example, a lower electrode 761 to be described later.

With the use of the structure of the semiconductor device 100 of one embodiment of the present invention for a pixel circuit of a display device, the area occupied by the pixel circuit can be reduced. Thus, the resolution of the display device can be improved. For example, a display device with a resolution of higher than or equal to 1000 ppi, preferably higher than or equal to 2000 ppi, further preferably higher than or equal to 3000 ppi, still further preferably higher than or equal to 4000 ppi, yet further preferably higher than or equal to 5000 ppi, and yet still further preferably higher than or equal to 6000 ppi, and lower than or equal to 10000 ppi, lower than or equal to 9000 ppi, or lower than or equal to 8000 ppi can be achieved.

The reduction in the area occupied by the pixel circuit can increase the number of pixels of the display device (can increase the definition). For example, a display device with an extremely high definition of HD (number of pixels: 1280×720), FHD (number of pixels: 1920×1080), WQHD (number of pixels: 2560×1440), WQXGA (number of pixels: 2560× 1600), 4K2K (number of pixels: 3840× 2160), or 8K4K (number of pixels: 7680× 4320) can be achieved in some cases.

Accordingly, the use of the structure of the semiconductor device 100 of one embodiment of the present invention for a pixel circuit of the display device can increase the display quality of the display device. A bottom-emission display device including the EL element can have a high aperture ratio of a pixel. A pixel with a high aperture ratio can have a lower current density than a pixel with a low aperture ratio when the pixel with a high aperture ratio and the pixel with a low aperture ratio emit light with the same luminance. Thus, the reliability of the display device can be improved.

### <Pixel Layout>

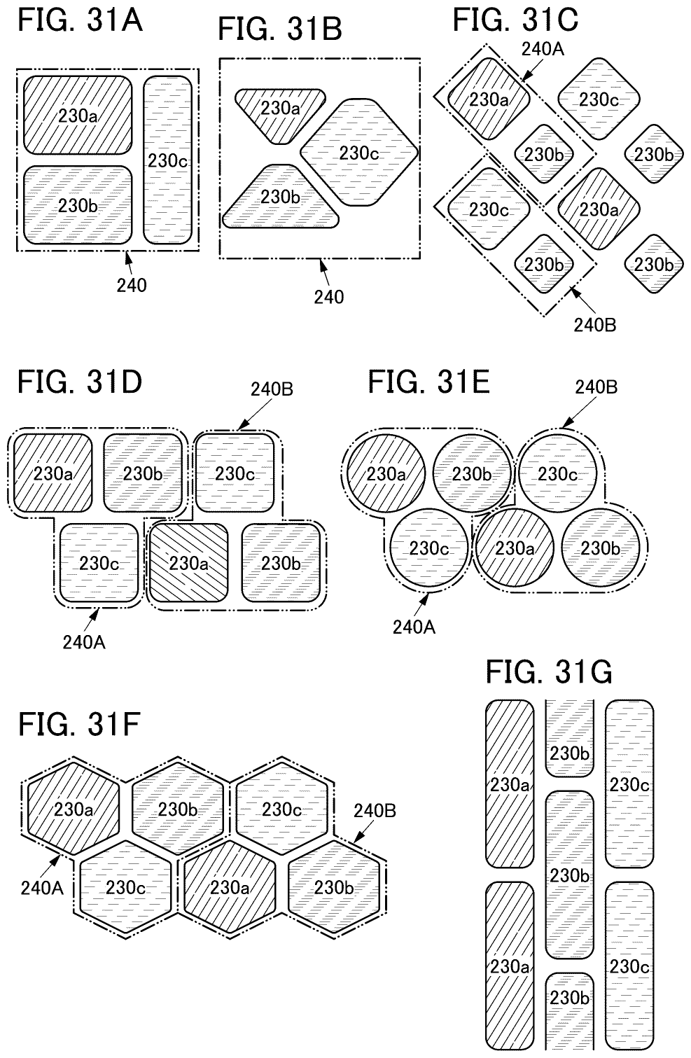

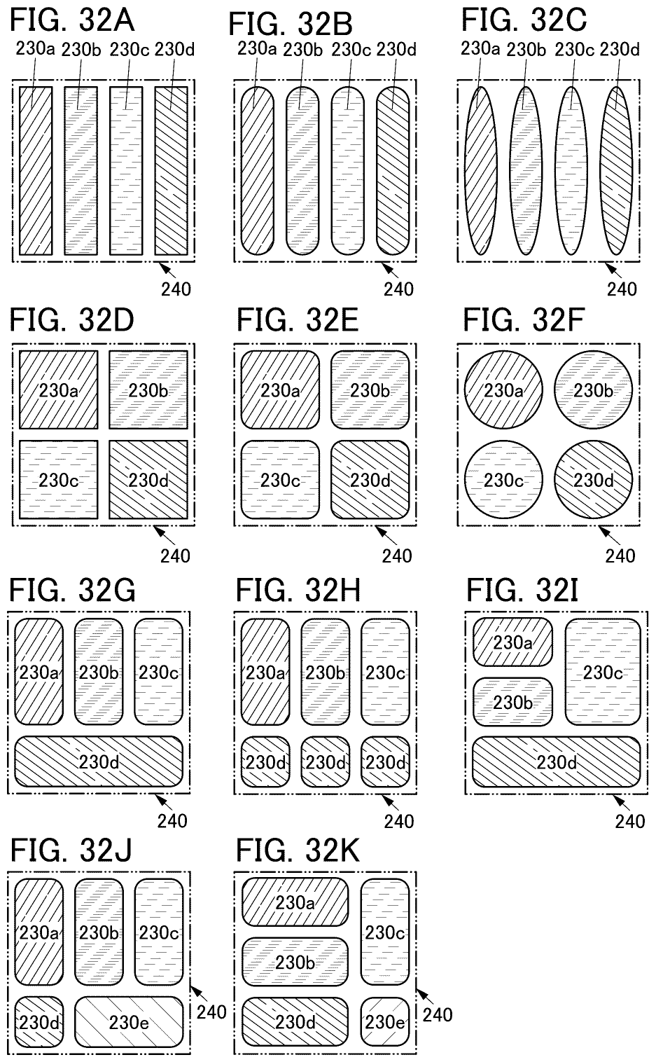

Pixel layouts different from the pixel layout in FIG. 20A are mainly described with reference to FIG. 31A to FIG. 31G and FIG. 32A to FIG. 32K. There is no particular limitation on the arrangement of subpixels, and a variety of pixel layouts can be employed. Examples of the arrangement of subpixels include stripe arrangement, S-stripe arrangement, matrix arrangement, delta arrangement, Bayer arrangement, and PenTile arrangement.

Note that top surface shapes of the subpixels illustrated in FIG. 20A, FIG. 31A to FIG. 31G, and FIG. 32A to FIG. 32K correspond to top surface shapes of light-emitting regions.

Examples of a top surface shape of the subpixel include polygons such as a triangle, a tetragon (including a rectangle and a square), and a pentagon; polygons with rounded corners; an ellipse; and a circle.

The pixel circuit 51 included in the subpixel (the pixel 230) may be placed to overlap with a light-emitting region or may be placed outside the light-emitting region.

The pixel 240 illustrated in FIG. 31A employs S-stripe arrangement. The pixel 240 illustrated in FIG. 31A is composed using the pixel 230a, the pixel 230b, and the pixel 230c as subpixels.

The pixel 240 illustrated in FIG. 31B includes the pixel 230a whose top surface has a rough trapezoidal or rough triangle shape with rounded corners, the pixel 230b whose top surface has a rough trapezoidal or rough triangle shape with rounded corners, and the pixel 230c whose top surface has a rough tetragonal or rough hexagonal shape with rounded corners. The pixel 230b has a larger light-emitting area than the pixel 230a. In this manner, the shapes and sizes of the subpixels can be determined independently. For example, the size of a subpixel including a light-emitting device with higher reliability can be smaller.

A pixel 240A and a pixel 240B illustrated in FIG. 31C employ PenTile arrangement. FIG. 31C illustrates an example in which the pixels 240A including the pixel 230a and the pixel 230b and the pixels 240B including the pixel 230b and the pixel 230c are alternately arranged.

The pixel 240A and the pixel 240B illustrated in FIG. 31D to FIG. 31F employ delta arrangement. The pixel 240A includes two subpixels (the pixel 230a and the pixel 230b) in the upper row (first row) and one subpixel (the pixel 230c) in the lower row (second row). The pixel 240B includes one subpixel (the pixel 230c) in the upper row (first row) and two subpixels (the pixel 230a and the pixel 230b) in the lower row (second row).

FIG. 31D illustrates an example in which each subpixel has a rough tetragonal top surface shape with rounded corners, FIG. 31E illustrates an example in which each subpixel has a circular top surface shape, and FIG. 31F illustrates an example in which each subpixel has a rough hexagonal top surface shape with rounded corners.

In FIG. 31F, each of the subpixels is placed inside one of the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the pixel 230a, three pixels 230b and three pixels 230c are arranged to surround the pixel 230a, so that the pixel 230a, the pixel 230b, and the pixel 230c are alternately arranged.

FIG. 31G illustrates an example in which subpixels of different colors are arranged in a zigzag manner. Specifically, the positions of the top sides of two subpixels arranged in the column direction (e.g., the pixel 230a and the pixel 230b or the pixel 230b and the pixel 230c) are not aligned in a top view.

For example, in each pixel illustrated in FIG. 31A to FIG. 31G, it is preferable that the pixel 230a be a subpixel R emitting red light, the pixel 230b be a subpixel G emitting green light, and the pixel 230c be a subpixel B emitting blue light. Note that the structure of the subpixels is not limited to this, and the colors and arrangement order of the subpixels can be determined as appropriate. For example, the pixel 230b may be the subpixel R emitting red light and the pixel 230a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel has a polygonal shape with rounded corners, an elliptical shape, a circular shape, or the like, in some cases.

In the case where the EL layer is processed into an island shape using a resist mask, a resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 32A to FIG. 32I, the pixel can include four types of subpixels.

The pixels 240 illustrated in FIG. 32A to FIG. 32C employ stripe arrangement.

FIG. 32A illustrates an example in which each subpixel has a rectangular top surface shape, FIG. 32B illustrates an example in which each subpixel has a top surface shape formed by combining two half circles and a rectangle, and FIG. 32C illustrates an example in which each subpixel has an elliptical top surface shape.

The pixels 240 illustrated in FIG. 32D to FIG. 32F employ matrix arrangement.

FIG. 32D illustrates an example in which each subpixel has a square top surface shape, FIG. 32E illustrates an example in which each subpixel has a rough square top surface shape with rounded corners, and FIG. 32F illustrates an example in which each subpixel has a circular top surface shape.

FIG. 32G and FIG. 32H each illustrate an example in which one pixel 240 is composed of subpixels arranged in two rows and three columns.

The pixel 240 illustrated in FIG. 32G includes three subpixels (the pixel 230a, the pixel 230b, and the pixel 230c) in the upper row (first row) and one subpixel (a pixel 230d) in the lower row (second row) in the pixel 240. In other words, the pixel 240 includes the pixel 230a in the left column (first column), the pixel 230b in the center column (second column), the pixel 230c in the right column (third column), and the pixel 230d across these three columns.

The pixel 240 illustrated in FIG. 32H includes three subpixels (the pixel 230a, the pixel 230b, and the pixel 230c) in the upper row (first row) and three pixels 230d in the lower row (second row). In other words, the pixel 240 includes the pixel 230a and the pixel 230d in the left column (first column), the pixel 230b and the pixel 230d in the center column (second column), and the pixel 230c and the pixel 230d in the right column (third column) in the pixel 240. Matching the positions of the subpixels in the upper row and the lower row as illustrated in FIG. 32H enables efficient removal of dust and the like that would be produced in the manufacturing process. Thus, a display device with high display quality can be provided.

FIG. 32I illustrates an example in which one pixel 240 is composed of subpixels arranged in three rows and two columns.

The pixel 240 illustrated in FIG. 32I includes the pixel 230a in the upper row (first row), the pixel 230b in the center row (second row), the pixel 230c across the first row and the second row, and one subpixel (the pixel 230d) in the lower row (third row) in the pixel 240. In other words, the pixel 240 includes the pixel 230a and the pixel 230b in the left column (first column), the pixel 230c in the right column (second column), and the pixel 230d across these two columns in the pixel 240.

The pixels 240 illustrated in FIG. 32A to FIG. 32I are each composed of four subpixels: the pixel 230a, the pixel 230b, the pixel 230c, and the pixel 230d.

The pixel 230a, the pixel 230b, the pixel 230c, and the pixel 230d can include light-emitting devices whose emission colors are different. The pixel 230a, the pixel 230b, the pixel 230c, and the pixel 230d are, for example, subpixels of four colors of R, G, B, and white (W), subpixels of four colors of R, G, B, and Y, or subpixels of R, G, B, and infrared light (IR).

In the pixels 240 illustrated in FIG. 32A to FIG. 32I, the pixel 230a may be the subpixel R emitting red light, the pixel 230b may be the subpixel G emitting green light, the pixel 230c may be the subpixel B emitting blue light, and the pixel 230d may be any of a subpixel W emitting white light, a subpixel Y emitting yellow light, and a subpixel IR emitting near-infrared light, for example. In the case of such a structure, stripe arrangement is employed as the layout of R, G, and B in the pixels 240 illustrated in FIG. 32G and FIG. 32H, leading to higher display quality. In addition, what is called S-stripe arrangement is employed as the layout of R, G, and B in the pixel 240 illustrated in FIG. 32I, leading to higher display quality.

The pixel 240 may include a subpixel including a light-receiving element (also referred to as a light-receiving device).

In the pixels 240 illustrated in FIG. 32A to FIG. 32I, any one of the pixel 230a to the pixel 230d may be a subpixel including a light-receiving device.

In the pixels 240 illustrated in FIG. 32A to FIG. 32I, the pixel 230a may be the subpixel R emitting red light, the pixel 230b may be the subpixel G emitting green light, the pixel 230c may be the subpixel B emitting blue light, and the pixel 230d may be a subpixel S including a light-receiving device, for example. In the case of such a structure, stripe arrangement is employed as the layout of R, G, and B in the pixels 240 illustrated in FIG. 32G and FIG. 32H, leading to higher display quality. In addition, what is called S-stripe arrangement is employed as the layout of R, G, and B in the pixel 240 illustrated in FIG. 32I, leading to higher display quality.

There is no particular limitation on the wavelength of light detected by the subpixel S including a light-receiving device. The subpixel S can have a structure in which one or both of visible light and infrared light are detected.

As illustrated in FIG. 32J and FIG. 32K, one pixel 240 may include five types of subpixels.

FIG. 32J illustrates an example in which one pixel 240 is composed of subpixels arranged in two rows and three columns.

The pixel 240 illustrated in FIG. 32J includes three subpixels (the pixel 230a, the pixel 230b, and the pixel 230c) in the upper row (first row) and two subpixels (the pixel 230d and a pixel 230e) in the lower row (second row) in the pixel 240. In other words, the pixel 240 includes the pixel 230a and the pixel 230d in the left column (first column), the pixel 230b in the center column (second column), the pixel 230c in the right column (third column), and the pixel 230e across the second column and the third column in the pixel 240.

FIG. 32K illustrates an example in which one pixel 240 is composed of subpixels arranged in three rows and two columns.

The pixel 240 illustrated in FIG. 32K includes the pixel 230a in the upper row (first row), the pixel 230b in the center row (second row), the pixel 230c across the first row and the second row, and two subpixels (the pixel 230d and the pixel 230e) in the lower row (third row) in the pixel 240. In other words, the pixel 240 includes the pixel 230a, the pixel 230b, and the pixel 230d in the left column (first column) and the pixel 230c and the pixel 230e in the right column (second column).

In the pixels 240 illustrated in FIG. 32J and FIG. 32K, it is preferable that the pixel 230a be the subpixel R emitting red light, the pixel 230b be the subpixel G emitting green light, and the pixel 230c be the subpixel B emitting blue light, for example. In the case of such a structure, stripe arrangement is employed as the layout of subpixels in the pixels 240 illustrated in FIG. 32J, leading to higher display quality. In addition, what is called S-stripe arrangement is employed as the layout of subpixels in the pixel 240 illustrated in FIG. 32K, leading to higher display quality.

In the pixels 240 illustrated in FIG. 32J and FIG. 32K, for example, the subpixel S including a light-receiving device may be used as at least one of the pixel 230d and the pixel 230e. In the case where light-receiving devices are used in both the pixel 230d and the pixel 230e, the light-receiving devices may have different structures. For example, the wavelength ranges of detected light may be different at least partly. Specifically, one of the pixel 230d and the pixel 230e may include a light-receiving device mainly detecting visible light and the other may include a light-receiving device mainly detecting infrared light.

In the pixels 240 illustrated in FIG. 32J and FIG. 32K, for example, the subpixel S including a light-receiving device may be used as one of the pixel 230d and the pixel 230e and a subpixel including a light-emitting device that can be used as a light source may be used as the other. For example, one of the pixel 230d and the pixel 230e may be the subpixel IR emitting infrared light and the other may be the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, in the display device of one embodiment of the present invention, various layouts of the subpixels (the pixels 230) can be employed for the pixel 240. Furthermore, the pixel 240 may be configured to include both a light-emitting device and a light-receiving device. Also in this case, any of various layouts can be employed.

The structure described in this embodiment can be used in an appropriate combination with any of the structures described in the other embodiments.

### Embodiment 4

In this embodiment, a light-emitting device that can be used as the light-emitting element 61 is described.

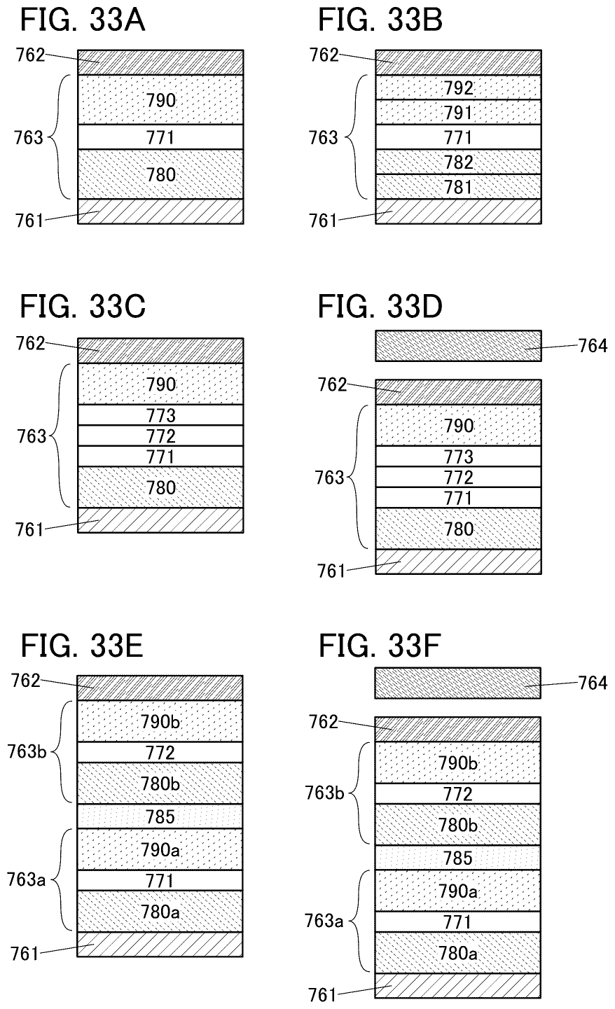

As illustrated in FIG. 33A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer including a substance having a high hole-injection property (hole-injection layer), a layer including a substance having a high hole-transport property (hole-transport layer), and a layer including a substance having a high electron-blocking property (electron-blocking layer). Furthermore, the layer 790 includes one or more of a layer including a substance having a high electron-injection property (electron-injection layer), a layer including a substance having a high electron-transport property (electron-transport layer), and a layer including a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 33A is referred to as a single structure in this specification.

FIG. 33B is a modification example of the EL layer 763 included in the light-emitting device illustrated in FIG. 33A. Specifically, the light-emitting device illustrated in FIG. 33B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771, a light-emitting layer 772, and a light-emitting layer 773) are provided between the layer 780 and the layer 790 as illustrated in FIG. 33C and FIG. 33D are other variations of the single structure. Although FIG. 33C and FIG. 33D each illustrate an example in which three light-emitting layers are included, the number of light-emitting layers in a light-emitting device having a single structure may be two or four or more. A light-emitting device having a single structure may include a buffer layer between two light-emitting layers. A carrier-transport layer (a hole-transport layer or an electron-transport layer) can be used as the buffer layer, for example.

A structure in which a plurality of light-emitting units (a light-emitting unit 763a and a light-emitting unit 763b) are connected in series with a charge-generation layer (also referred to as an intermediate layer) 785 therebetween as illustrated in FIG. 33E and FIG. 33F is referred to as a tandem structure in this specification. The tandem structure may be referred to as a stack structure. The tandem structure enables a light-emitting device capable of high-luminance light emission. Furthermore, the tandem structure allows the amount of current needed for obtaining the same luminance to be reduced as compared with the case of using a single structure, and thus can improve the reliability.

Note that FIG. 33D and FIG. 33F each illustrate an example in which the display device includes a layer 764 overlapping with the light-emitting device. FIG. 33D illustrates an example in which the layer 764 overlaps with the light-emitting device illustrated in FIG. 33C, and FIG. 33F illustrates an example in which the layer 764 overlaps with the light-emitting device illustrated in FIG. 33E. In FIG. 33D and FIG. 33F, a conductive film that transmits visible light is used for the upper electrode 762 so that light is extracted through the upper electrode 762.

One or both of a color conversion layer and a color filter (coloring layer) can be used as the layer 764

In FIG. 33C and FIG. 33D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 33D for converting blue light emitted from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 33C and FIG. 33D, light-emitting substances that emit light of different colors may be used for the light-emitting layer 771, the light-emitting layer 772, and the light-emitting layer 773. White light emission can be obtained in the case where colors of light emitted from the light-emitting layer 771, the light-emitting layer 772, and the light-emitting layer 773 are complementary colors. The light-emitting device having a single structure preferably includes a light-emitting layer including a light-emitting substance that emits blue light and a light-emitting layer including a light-emitting substance that emits visible light with a longer wavelength than blue light, for example.

A color filter may be provided as the layer 764 illustrated in FIG. 33D. When white light passes through the color filter, light of a desired color can be obtained.

In the case where the light-emitting device having a single structure includes three light-emitting layers, for example, a light-emitting layer including a light-emitting substance that emits red (R) light, a light-emitting layer including a light-emitting substance that emits green (G) light, and a light-emitting layer including a light-emitting substance that emits blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance that emits blue (B) light and a light-emitting layer including a light-emitting substance that emits yellow (Y) light are preferably included. Such a structure may be referred to as a BY single structure.

In the light-emitting device that emits white light, two or more kinds of light-emitting substances are preferably included. To obtain white light emission, the two or more kinds of light-emitting substances are selected so as to emit light of complementary colors. For example, when emission colors of a first light-emitting layer and a second light-emitting layer are complementary colors, the light-emitting device can emit white light as a whole. The same applies to a light-emitting device including three or more light-emitting layers.

In FIG. 33C and FIG. 33D, the layer 780 and the layer 790 may each have a stacked-layer structure of two or more layers as illustrated in FIG. 33B.

In FIG. 33E and FIG. 33F, light-emitting substances that emit light of the same color, or the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In the subpixel that emits blue light, blue light emitted from the light-emitting device can be extracted. In each of the subpixel that emits red light and the subpixel that emits green light, a color conversion layer is provided as the layer 764 illustrated in FIG. 33F for converting blue light emitted from the light-emitting device into light with a longer wavelength, so that red light or green light can be extracted. As the layer 764, both a color conversion layer and a coloring layer are preferably used.

In the case where light-emitting devices with the structure illustrated in FIG. 33E or FIG. 33F are used in subpixels emitting light of different colors, light-emitting substances may be different between the subpixels. Specifically, in the light-emitting device included in the subpixel that emits red light, a light-emitting substance that emits red light may be used for each of the light-emitting layer 771 and the light-emitting layer 772. Similarly, in the light-emitting device included in the subpixel that emits green light, a light-emitting substance that emits green light may be used for each of the light-emitting layer 771 and the light-emitting layer 772. In the light-emitting device included in the subpixel that emits blue light, a light-emitting substance that emits blue light may be used for each of the light-emitting layer 771 and the light-emitting layer 772. A display device with such a structure includes a light-emitting device with a tandem structure and can be regarded to have an SBS structure. Thus, the display device can have advantages of both of a tandem structure and an SBS structure. Accordingly, a highly reliable light-emitting device capable of high-luminance light emission can be obtained.

In FIG. 33E and FIG. 33F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter may be provided as the layer 764 illustrated in FIG. 33F. When white light passes through the color filter, light of a desired color can be obtained.

Although FIG. 33E and FIG. 33F each illustrate an example in which the light-emitting unit 763a includes one light-emitting layer 771 and the light-emitting unit 763b includes one light-emitting layer 772, one embodiment of the present invention is not limited to the example. Each of the light-emitting unit 763a and the light-emitting unit 763b may include two or more light-emitting layers.

Although FIG. 33E and FIG. 33F each illustrate an example of a light-emitting device including two light-emitting units, one embodiment of the present invention is not limited to the example. The light-emitting device may include three or more light-emitting units. Note that a structure including two light-emitting units and a structure including three light-emitting units may be referred to as a two-unit tandem structure and a three-unit tandem structure, respectively. In each of FIG. 33E and FIG. 33F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

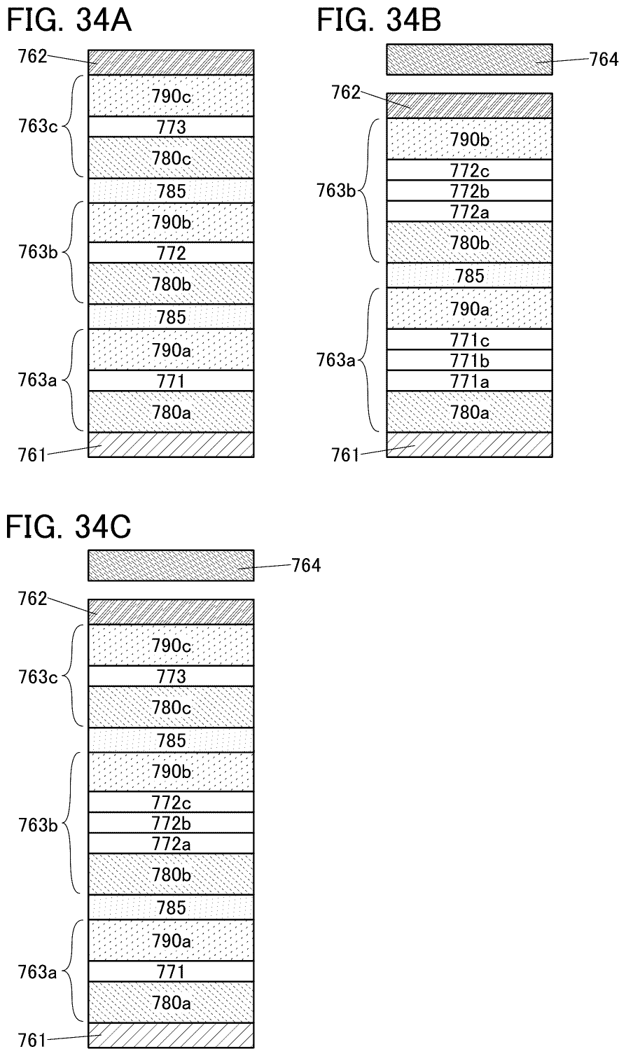

Examples of the light-emitting device with a tandem structure are structures illustrated in FIG. 34A to FIG. 34C.

FIG. 34A illustrates a structure including three light-emitting units. In FIG. 34A, a plurality of light-emitting units (a light-emitting unit 763a, a light-emitting unit 763b, and a light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 34A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (what is called an R\R\R three-unit tandem structure), the light-emitting layer 771, the light-emitting layer 772, and the light-emitting layer 773 can each include a light-emitting substance that emits green (G) light (what is called a G\G\G three-unit tandem structure), or the light-emitting layer 771, the light-emitting layer 772, and the light-emitting layer 773 can each include a light-emitting substance that emits blue (B) light (what is called a B\B\B three-unit tandem structure). Note that “a\b” means that a light-emitting unit including a light-emitting substance that emits light of a color “b” is provided over a light-emitting unit including a light-emitting substance that emits light of a color “a” with a charge-generation layer therebetween, and “a” and “b” each mean a color.

In FIG. 34A, light-emitting substances that emit light of different colors may be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

Note that the light-emitting substances that emit light of the same color is not limited to the above structure. For example, a light-emitting device with a tandem structure may be employed in which light-emitting units each including a plurality of light-emitting layers are stacked as illustrated in FIG. 34B. FIG. 34B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 34B, the light-emitting unit 763a is configured to emit white (W) light by selecting light-emitting substances for the light-emitting layer 771a, the light-emitting layer 771b, and the light-emitting layer 771c such that their emission colors are complementary colors. Furthermore, the light-emitting unit 763b is configured to emit white (W) light by selecting light-emitting substances for the light-emitting layer 772a, the light-emitting layer 772b, and the light-emitting layer 772c such that their emission colors are complementary colors. That is, the structure illustrated in FIG. 34B is a two-unit tandem structure of W\W. Note that there is no particular limitation on the stacking order of the light-emitting substances having complementary emission colors. A practitioner can select an optimum stacking order as appropriate. Although not illustrated, a three-unit tandem structure of W\W\W or a tandem structure with four or more units may be employed.

In the case of a light-emitting device with a tandem structure, any of the following structures may be employed: a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a color “a” and a light-emitting substance that emits light of a color “b”. Alternatively, a light-emitting unit including one light-emitting layer and a light-emitting unit including a plurality of light-emitting layers may be used in combination as illustrated in FIG. 34C.

Specifically, in the structure illustrated in FIG. 34C, a plurality of light-emitting units (the light-emitting unit 763a, the light-emitting unit 763b, and the light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 34C can be, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display device includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table that is not exemplified above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device preferably includes an electrode having properties of transmitting and reflecting visible light (transflective electrode), and the other preferably includes an electrode having a visible-light-reflecting property (reflective electrode). When the light-emitting device has a microcavity structure, light obtained from the light-emitting layer can be resonated between the electrodes, whereby light emitted from the light-emitting device can be intensified.

The transmittance of light of the electrode having a visible-light-transmitting property is greater than or equal to 40%. For example, in the case of using an electrode having a visible-light-transmitting property in the light-emitting device, an electrode having a visible light (light at a wavelength greater than or equal to 400 nm and less than 750 nm) transmittance higher than or equal to 40% is preferably used. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellow green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use any of after-mentioned substances each having a high hole-transport property that can be used for the hole-transport layer. As the electron-transport material, it is possible to use any of after-mentioned substances each having a high electron-transport property that can be used for the electron-transport layer. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and includes a substance having a high hole-injection property. Examples of a substance having a high hole-injection property include an aromatic amine compound and a composite material including a hole-transport material and an acceptor material (electron-accepting material).

As the hole-transport material, any of after-mentioned substances each having a high hole-transport property that can be used for a hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferred because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the substance having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material is preferably a substance having a hole mobility higher than or equal to 1×10⁻⁶ cm²/Vs. Note that other substances can also be used as long as the substances have a hole-transport property higher than an electron-transport property. As the hole-transport material, substances having a high hole-transport property, such as a π-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

The electron-blocking layer has a hole-transport property, and thus can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material is preferably a substance having an electron mobility higher than or equal to 1×10⁻⁶ cm²/Vs. Note that other substances can also be used as long as the substances have an electron-transport property higher than a hole-transport property. As the electron-transport material, any of the following substances having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

The hole-blocking layer has an electron-transport property, and thus can also be referred to as an electron-transport layer. Among electron-transport layers, a layer having a hole-blocking property can also be referred to as a hole-blocking layer.

The electron-injection layer injects electrons from the cathode to the electron-transport layer and includes a substance having a high electron-injection property. As the substance having a high electron-injection property, an alkali metal, an alkaline earth metal, or a compound thereof can be used. As the substance having a high electron-injection property, a composite material including an electron-transport material and a donor material (electron-donating material) can also be used.

The lowest unoccupied molecular orbital (LUMO) level of the substance having a high electron-injection property preferably has a small difference (specifically, 0.5 eV or less) from the work function of a material used for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation:Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino [2,3-a:2′,3′-c]phenazine (abbreviation: HATNA), 2,4,6-tris [3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a substance having a high electron-injection property. The layer can also be referred to as an electron-injection buffer layer. The electron-injection buffer layer is preferably provided between the charge-generation region and the electron-transport layer. The electron-injection buffer layer can reduce an injection barrier between the charge-generation region and the electron-transport layer; thus, electrons generated in the charge-generation region can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the charge-generation region, the electron-injection buffer layer, and the electron-relay layer cannot be clearly distinguished from one another on the basis of the cross-sectional shape or properties in some cases.

The charge-generation layer may contain a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

The structure described in this embodiment can be used in an appropriate combination with any of the structures described in the other embodiments.

### Embodiment 5

In this embodiment, structure examples of the light-emitting elements 61 that achieve full-color display in the display device 200 will be described.

The plurality of light-emitting elements 61 provided in the display portion 235 of the display device 200 can be formed by a photolithography method without a shadow mask such as a metal mask. Accordingly, it is possible to achieve a display device with high resolution and a high aperture ratio, which has been difficult to achieve. Furthermore, leakage current between adjacent EL layers is reduced, enabling the display device to perform extremely clear display with high contrast and high display quality.

Although it is difficult to set the distance between adjacent light-emitting elements 61 to be less than 10 μm by a formation method using a metal mask, for example, a photolithography method can shorten the distance to be less than or equal to 8 μm, less than or equal to 3 μm, less than or equal to 2 μm, or less than or equal to 1 μm. Here, the distance between adjacent light-emitting elements 61 can be determined by the distance between end portions of two adjacent pixel electrodes. Alternatively, the distance between adjacent light-emitting elements 61 can be determined by the distance between end portions of two adjacent EL layers.

In this specification and the like, a display device formed using a metal mask or an FMM (fine metal mask, high-definition metal mask) may be referred to as a display device having an MM (metal mask) structure. In this specification and the like, a display device formed without using a metal mask or an FMM may be referred to as a display device having an MML (metal maskless) structure.

By shortening the distance between adjacent light-emitting elements 61 in the above manner, the area of a non-light-emitting region that may exist between two light-emitting elements can be significantly reduced, and the aperture ratio can be close to 100%. For example, the aperture ratio is higher than or equal to 50%, higher than or equal to 60%, higher than or equal to 70%, higher than or equal to 80%, or higher than or equal to 90%; that is, an aperture ratio lower than 100% can be achieved.

Furthermore, a pattern of the EL layer itself (also referred to as a processing size) can be made much smaller than that in the case of using a metal mask. For example, in the case of using a metal mask for forming EL layers separately, a variation in the thickness occurs between the center and the edge of the EL layer. This causes a reduction in an effective area that can be used as a light-emitting region with respect to the area of the EL layer. In contrast, in the above manufacturing method, an EL layer is formed by processing a film deposited to have a uniform thickness, which enables a uniform thickness in the EL layer. Thus, even in a fine pattern, almost the whole area can be used as a light-emitting region. Therefore, the above manufacturing method makes it possible to obtain a high resolution display device with a high aperture ratio.

In many cases, an organic film formed using a fine metal mask (FMM) has an extremely small taper angle (e.g., a taper angle of greater than 0° and less than) 30° so that the thickness of the film becomes smaller in a portion closer to an end portion. Therefore, it is difficult to clearly observe a side surface of an organic film formed using an FMM because the side surface and a top surface are continuously connected. In contrast, an EL layer included in one embodiment of the present invention is processed without using an FMM, and has a clear side surface. In particular, part of the taper angle of the EL layer included in one embodiment of the present invention is preferably greater than or equal to 30° and less than or equal to 120°, further preferably greater than or equal to 60° and less than or equal to 120°.

Note that in this specification and the like, an end portion of an object having a tapered shape indicates that the end portion of the object has a cross-sectional shape in which the angle between a surface (a side surface) of the object and a bottom surface (a surface on which the object is formed) is greater than 0° and less than 90° in a region of the end portion, and the thickness continuously increases from the end portion. A taper angle refers to an angle between a bottom surface (a surface on which an object is formed) and a side surface (a surface) at an end portion of the object.

More specific structure examples are described below.

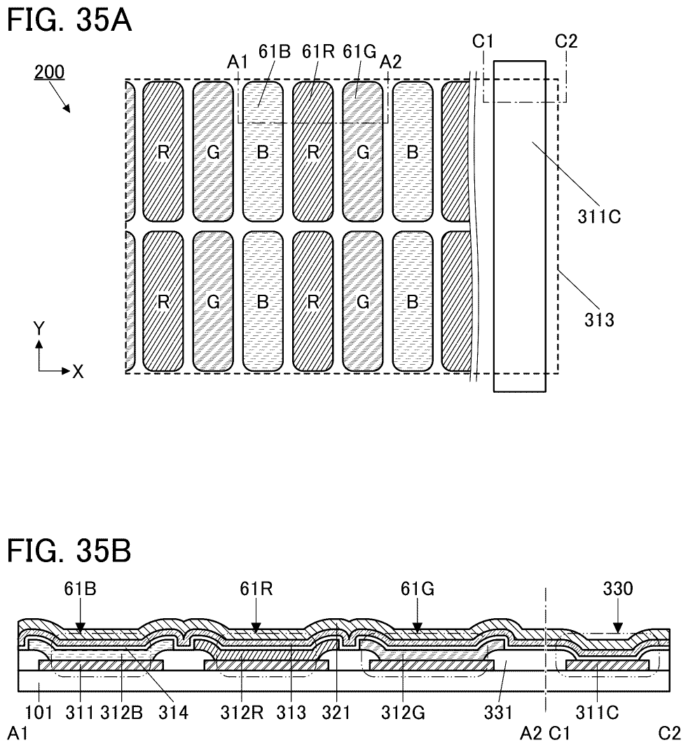

FIG. 35A illustrates a schematic top view of part of the display portion 235 included in the display device 200. The display device 200 includes a plurality of light-emitting elements 61R emitting red light, a plurality of light-emitting elements 61G emitting green light, and a plurality of light-emitting elements 61B emitting blue light over a substrate 101 provided with a semiconductor circuit. In FIG. 35A, light-emitting regions of the light-emitting elements are denoted by R, G, and B to easily differentiate the light-emitting elements. Note that the substrate 101 is a substrate over which the semiconductor device described in the above embodiment is formed and the description of the above embodiment can be referred to for the details. Note that the semiconductor device provided over the substrate 101 is not illustrated in FIG. 35.

The light-emitting elements 61R, the light-emitting elements 61G, and the light-emitting elements 61B are arranged in a stripe pattern. In FIG. 35A, two elements are alternately arranged in one direction. Note that the arrangement method of the light-emitting elements is not limited thereto; another method such as an S stripe, delta, Bayer, zigzag, PenTile, or diamond arrangement may also be used.

FIG. 35A also illustrates a connection electrode 311C that is electrically connected to a common electrode 313. The connection electrode 311C is supplied with a potential (e.g., an anode potential or a cathode potential) that is to be supplied to the common electrode 313. The connection electrode 311C is provided outside a display region where the light-emitting elements 61R and the like are arranged. In FIG. 35A, the common electrode 313 is denoted by a dashed line.

The connection electrode 311C can be provided along the outer periphery of the display region. For example, the connection electrode 311C may be provided along one side of the outer periphery of the display region or two or more sides of the outer periphery of the display region. That is, in the case where the display region has a rectangular top surface, the top surface of the connection electrode 311C can have a band shape, an L shape, a square bracket shape, a quadrangular shape, or the like.

FIG. 35B is a schematic cross-sectional view taken along dashed-dotted lines A1-A2 and C1-C2 in FIG. 35A. FIG. 35B is a schematic cross-sectional view of the light-emitting element 61B, the light-emitting element 61R, the light-emitting element 61G, and the connection electrode 311C.

The light-emitting element 61B includes a pixel electrode 311, an organic layer 312B, an organic layer 314, and the common electrode 313. The light-emitting element 61R includes the pixel electrode 311, an organic layer 312R, the organic layer 314, and the common electrode 313. The light-emitting element 61G includes the pixel electrode 311, an organic layer 312G, the organic layer 314, and the common electrode 313. The organic layer 314 and the common electrode 313 are shared by the light-emitting element 61B, the light-emitting element 61R, and the light-emitting element 61G. The organic layer 314 can also be referred to as a common layer. The pixel electrodes 311 are provided to be isolated from each other between the light-emitting elements.

The organic layer 312R, the organic layer 312G, and the organic layer 312B correspond to the EL layer 763 in the above embodiment.

The organic layer 312R contains at least a light-emitting organic compound that emits light with intensity in the red wavelength range. The organic layer 312G contains at least a light-emitting organic compound that emits light with intensity in the green wavelength range. The organic layer 312B contains at least a light-emitting organic compound that emits light with intensity in the blue wavelength range. Each of the organic layer 312R, the organic layer 312G, and the organic layer 312B can also be referred to as an EL layer.

The organic layer 312R, the organic layer 312B, and the organic layer 312G may each include one or more of an electron-injection layer, an electron-transport layer, a hole-injection layer, and a hole-transport layer. The organic layer 314 does not necessarily include the light-emitting layer. For example, the organic layer 314 includes one or more of an electron-injection layer, an electron-transport layer, a hole-injection layer, and a hole-transport layer.

Here, the uppermost layer in the stacked-layer structure of the organic layer 312R, the organic layer 312B, and the organic layer 312G, i.e., the layer in contact with the organic layer 314 is preferably a layer other than the light-emitting layer. For example, a structure is preferable in which an electron-injection layer, an electron-transport layer, a hole-injection layer, a hole-transport layer, or a layer other than those covers the light-emitting layer so as to be in contact with the organic layer 314. When a top surface of the light-emitting layer is protected by another layer in manufacturing each light-emitting element, the reliability of the light-emitting element can be improved.

By processing the EL layers by a photolithography method, the distance between pixels can be shortened to less than or equal to 8 μm, less than or equal to 3 μm, less than or equal to 2 μm, or less than or equal to 1 μm. Here, the distance between pixels can be determined by the distance between opposite end portions of the organic layer 312B and the organic layer 312R, the distance between opposite end portions of the organic layer 312B and the organic layer 312G, and the distance between opposite end portions of the organic layer 312R and the organic layer 312G, for example. Alternatively, the distance between pixels can be determined by the distance between opposite end portions of adjacent EL layers for the same color. Alternatively, the distance between pixels can be determined by the distance between opposite end portions of the adjacent pixel electrodes 311. The distance between pixels is shortened in this manner, whereby a display device with high resolution and a high aperture ratio can be provided.

The pixel electrode 311 is provided for each element. The common electrode 313 and the organic layer 314 are provided as layers common to the light-emitting elements. A conductive film that transmits visible light is used for either the respective pixel electrodes or the common electrode 313, and a reflective conductive film is used for the other. When the respective pixel electrodes are light-transmitting electrodes and the common electrode 313 is a reflective electrode, a bottom-emission display device is obtained. When the respective pixel electrodes are reflective electrodes and the common electrode 313 is a light-transmitting electrode, a top-emission display device is obtained. Note that when both the respective pixel electrodes and the common electrode 313 transmit light, a dual-emission display device can be obtained.

The pixel electrode 311 is electrically connected to a transistor provided in a semiconductor circuit of the substrate 101. The transistor provided on the substrate 101 has a reduced channel length and is miniaturized as described in the above embodiment. For this reason, even when the display device has high resolution and the pixel area is reduced, the pixel circuit can be disposed in the reduced pixel area.

The insulating layer 331 is provided to cover end portions of the pixel electrode 311. The end portions of the insulating layer 331 are preferably tapered. Note that in this specification and the like, an end portion of an object having a tapered shape indicates that the end portion of the object has a cross-sectional shape in which the angle between a surface of the object and a surface on which the object is formed is greater than 0° and less than 90° in a region of the end portion, and the thickness continuously increases from the end portion.

When an organic resin is used for the insulating layer 331, a surface of the insulating layer 331 can be moderately curved. Thus, coverage with a film formed over the insulating layer 331 can be improved.

Examples of materials that can be used for the insulating layer 331 include an acrylic resin, polyimide, an epoxy resin, polyamide, polyimide amide, a siloxane resin, a benzocyclobutene-based resin, a phenol resin, and precursors of these resins.

Alternatively, the insulating layer 331 may be formed using an inorganic insulating material. Examples of inorganic insulating materials that can be used for the insulating layer 331 include oxides and nitrides such as silicon oxide, silicon oxynitride, silicon nitride oxide, silicon nitride, aluminum oxide, aluminum oxynitride, and hafnium oxide. Yttrium oxide, zirconium oxide, gallium oxide, tantalum oxide, magnesium oxide, lanthanum oxide, cerium oxide, neodymium oxide, or the like may be used.

As illustrated in FIG. 35B, there are gaps between two organic layers of light-emitting elements that emit light of different colors, and the organic layers are provided apart from each other. The organic layer 312R, the organic layer 312B, and the organic layer 312G are thus preferably provided so as not to be in contact with each other. This favorably prevents unintentional light emission from being caused by current flowing through adjacent two organic layers. As a result, the contrast can be increased to achieve a display device with high display quality.

The organic layer 312R, the organic layer 312B, and the organic layer 312G each preferably have a taper angle of greater than or equal to 30°. In an end portion of each of the organic layer 312R, the organic layer 312G, and the organic layer 312B, the angle between a side surface (a surface) of the layer and a bottom surface of the layer (a surface on which the layer is formed) is preferably greater than or equal to 30° and less than or equal to 120°, further preferably greater than or equal to 45° and less than or equal to 120°, still further preferably greater than or equal to 60° and less than or equal to 120°. Alternatively, the organic layer 312R, the organic layer 312G, and the organic layer 312B each preferably have a taper angle of 90° or a neighborhood thereof (greater than or equal to 80° and less than or equal to 100°, for example).

A protective layer 321 is provided over the common electrode 313. The protective layer 321 has a function of preventing diffusion of impurities such as water into each light-emitting element from the above.

The protective layer 321 can have, for example, a single-layer structure or a stacked-layer structure including at least an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as indium gallium oxide or indium gallium zinc oxide may be used for the protective layer 321.

As the protective layer 321, a stacked film of an inorganic insulating film and an organic insulating film can be used. For example, a structure in which an organic insulating film is sandwiched between a pair of inorganic insulating films is preferable. Furthermore, it is preferable that the organic insulating film function as a planarization layer. With this structure, the top surface of the organic insulating film can be flat, and accordingly, coverage with the inorganic insulating film over the organic insulating film is improved, leading to an improvement in barrier properties. Moreover, since the top surface of the protective layer 321 is flat, a preferable effect can be obtained; when a component (e.g., a color filter, an electrode of a touch sensor, or a lens array) is provided above the protective layer 321, the component is less affected by an uneven shape caused by the lower structure.

In the connection portion 330, the common electrode 313 is provided on and in contact with the connection electrode 311C and the protective layer 321 is provided to cover the common electrode 313. In addition, the insulating layer 331 is provided to cover end portions of the connection electrode 311C.

A structure example of a display device that is partly different from that in FIG. 35B is described below. Specifically, an example in which the insulating layer 331 is not provided is described.

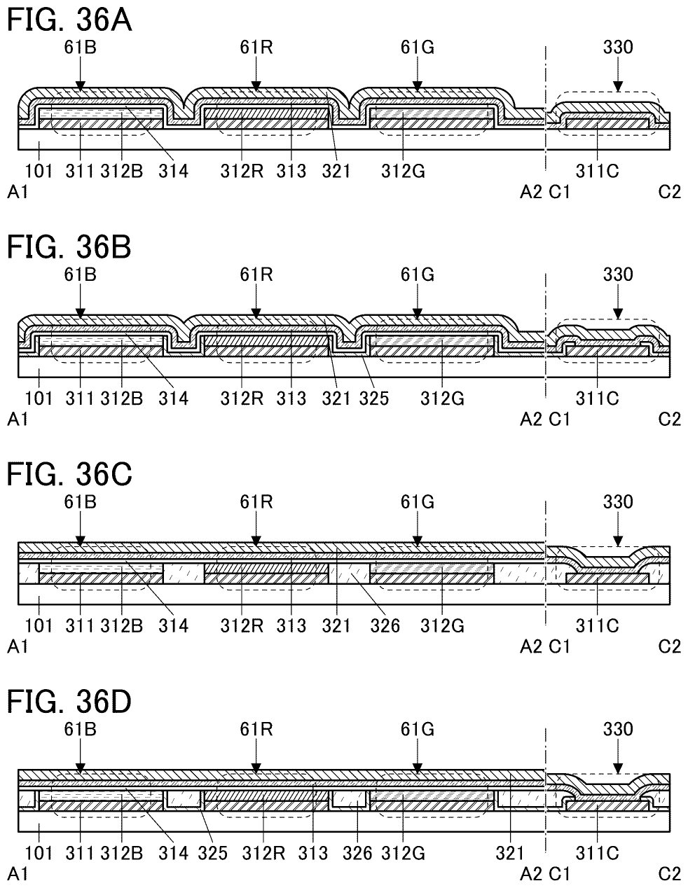

FIGS. 36A to 36C show examples of the case where a side surface of the pixel electrode 311 is substantially aligned with side surfaces of the organic layer 312R, the organic layer 312B, or the organic layer 312G.

In FIG. 36A, the organic layer 314 is provided to cover top surfaces and side surfaces of the organic layer 312R, the organic layer 312B, and the organic layer 312G. The organic layer 314 can prevent the pixel electrode 311 and the common electrode 313 from being in contact with each other and being electrically short-circuited.

FIG. 36B shows an example in which an insulating layer 325 is provided to be in contact with the side surfaces of the organic layer 312R, the organic layer 312B, the organic layer 312G, and the pixel electrode 311. The insulating layer 325 can prevent the pixel electrode 311 and the common electrode 313 from being electrically short-circuited and effectively inhibit leakage current therebetween.

The insulating layer 325 can be an insulating layer containing an inorganic material. As the insulating layer 325, an inorganic insulating film such as an oxide insulating film, a nitride insulating film, an oxynitride insulating film, or a nitride oxide insulating film can be used, for example. The insulating layer 325 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when an inorganic insulating film such as an aluminum oxide film, a hafnium oxide film, or a silicon oxide film formed by an ALD method is used as the insulating layer 325, the insulating layer 325 has a small number of pin holes and excels in a function of protecting the organic layer.

The insulating layer 325 can be formed by a sputtering method, a CVD method, a PLD method, an ALD method, or the like. The insulating layer 325 is preferably formed by an ALD method achieving good coverage.

In FIG. 36C, resin layers 326 are provided between two adjacent light-emitting elements so as to fill the space between two facing pixel electrodes and two facing organic layers. The resin layer 326 can planarize the surface on which the organic layer 314, the common electrode 313, and the like are formed, which prevents disconnection of the common electrode 313 due to poor coverage in a step between adjacent light-emitting elements.

As the resin layer 326, an insulating layer containing an organic material can be favorably used. For example, the resin layer 326 can be formed using an acrylic resin, an epoxy resin, polyimide, polyamide, polyimide amide, a silicone resin, a siloxane resin, a benzocyclobutene-based resin, a phenol resin, precursors of these resins, or the like. The resin layer 326 may be formed using an organic material such as polyvinyl alcohol (PVA), polyvinyl butyral, polyvinylpyrrolidone, polyethylene glycol, polyglycerin, pullulan, water-soluble cellulose, or alcohol-soluble polyamide. Moreover, the resin layer 326 can be formed using a photosensitive resin. A photoresist may be used as the photosensitive resin. The photosensitive resin can be of positive or negative type.

A colored material (e.g., a material containing a black pigment) may be used for the resin layer 326 so that the resin layer 326 has a function of blocking stray light from an adjacent pixel and inhibiting color mixture.

In FIG. 36D, the insulating layer 325 and the resin layer 326 over the insulating layer 325 are provided. Since the insulating layer 325 prevents the organic layer 312R or the like from being in contact with the resin layer 326, impurities such as moisture included in the resin layer 326 can be prevented from being diffused into the organic layer 312R or the like, whereby a highly reliable display device can be provided.

A reflective film (e.g., a metal film containing one or more of silver, palladium, copper, titanium, aluminum, and the like) may be provided between the insulating layer 325 and the resin layer 326 so that light emitted from the light-emitting layer is reflected by the reflective film; hence, the display device may be provided with a function of increasing the light extraction efficiency.

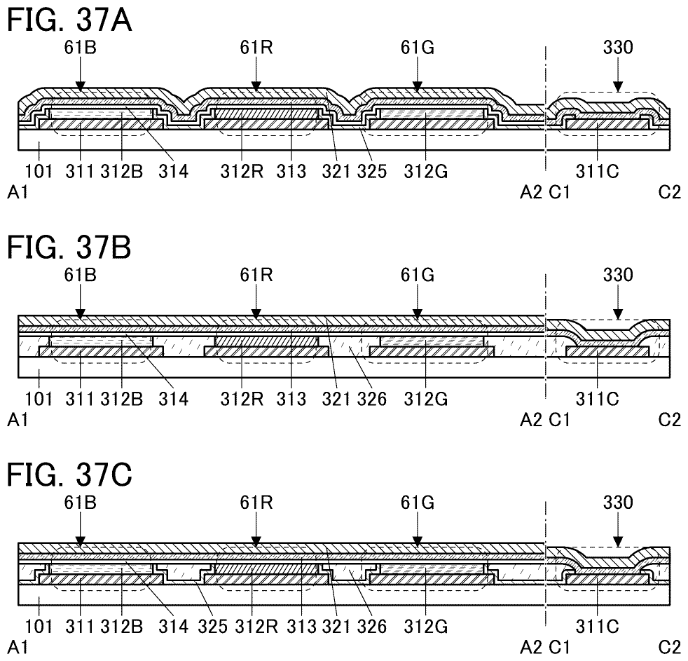

FIGS. 37A to 37C show examples in which the width of the pixel electrode 311 is larger than the width of the organic layer 312R, the organic layer 312B, or the organic layer 312G. The organic layer 312R or the like is provided on the inner side than end portions of the pixel electrode 311.

FIG. 37A shows an example in which the insulating layer 325 is provided. The insulating layer 325 is provided to cover the side surfaces of the organic layers included in the light-emitting elements and the side surfaces and parts of the top surfaces of the pixel electrodes 311.

FIG. 37B shows an example in which the resin layer 326 is provided. The resin layer 326 is positioned between two adjacent light-emitting elements, and covers the side surfaces of the organic layers and the top surfaces and the side surfaces of the pixel electrodes 311.

FIG. 37C shows an example in which both the insulating layer 325 and the resin layer 326 are provided. The insulating layer 325 is provided between the organic layer 312R or the like and the resin layer 326.

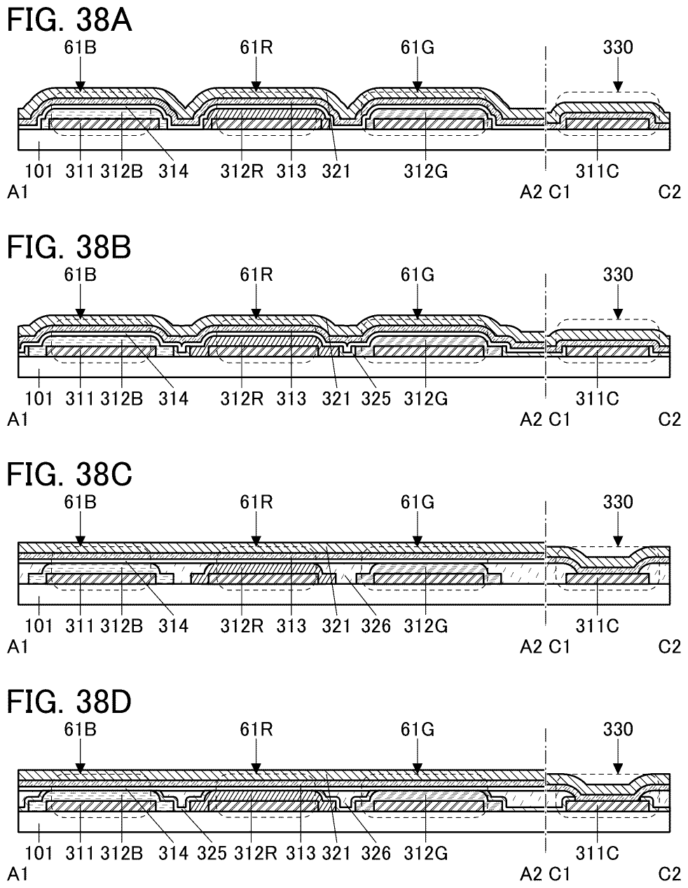

FIG. 38A to FIG. 38D show examples in which the width of the pixel electrode 311 is smaller than the width of the organic layer 312R, the organic layer 312B, or the organic layer 312G. The organic layer 312R or the like extends to an outer side beyond the end portions of the pixel electrode 311.

FIG. 38B shows an example in which the insulating layer 325 is provided. The insulating layer 325 is provided in contact with the side surfaces of the organic layers of two adjacent light-emitting elements. The insulating layer 325 may be provided to cover not only the side surface but also part of a top surface of the organic layer 312R or the like.

FIG. 38C shows an example in which the resin layer 326 is provided. The resin layer 326 is positioned between two adjacent light-emitting elements and covers the side surface and part of the top surface of the organic layer 312R or the like. The resin layer 326 may be formed to be in contact with the side surface of the organic layer 312R or the like and not to cover the top surface thereof.

FIG. 38D shows an example in which both the insulating layer 325 and the resin layer 326 are provided. The insulating layer 325 is provided between the organic layer 312R or the like and the resin layer 326.

Here, a structure example of the resin layer 326 is described.

A top surface of the resin layer 326 is preferably as flat as possible; however, the surface of the resin layer 326 may be depressed or projecting depending on an uneven shape of a surface on which the resin layer 326 is formed, the formation conditions of the resin layer 326, or the like.

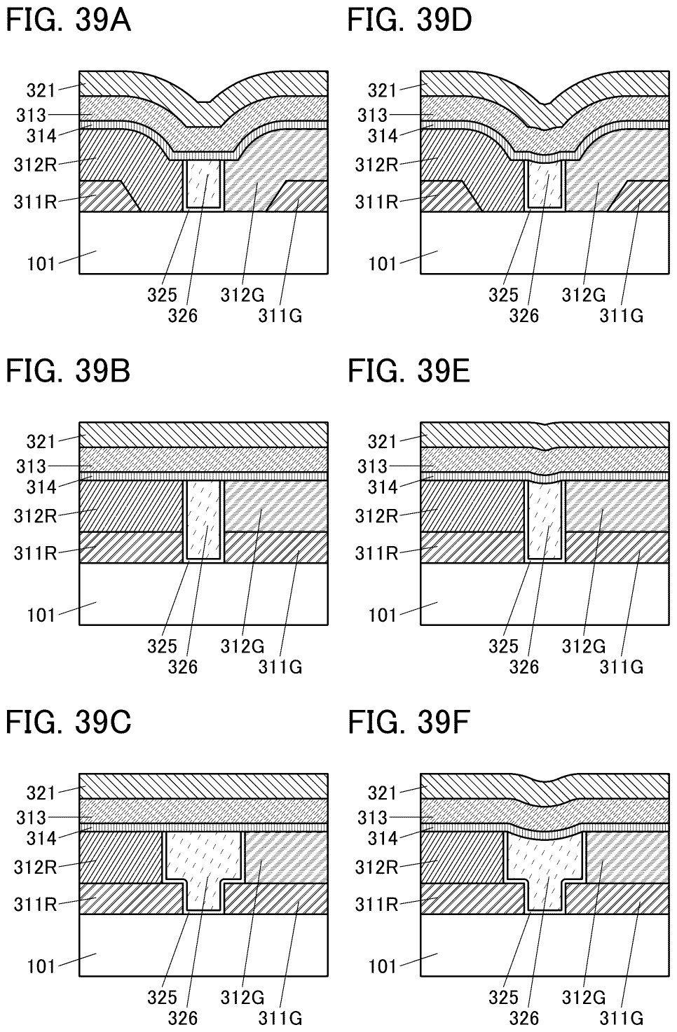

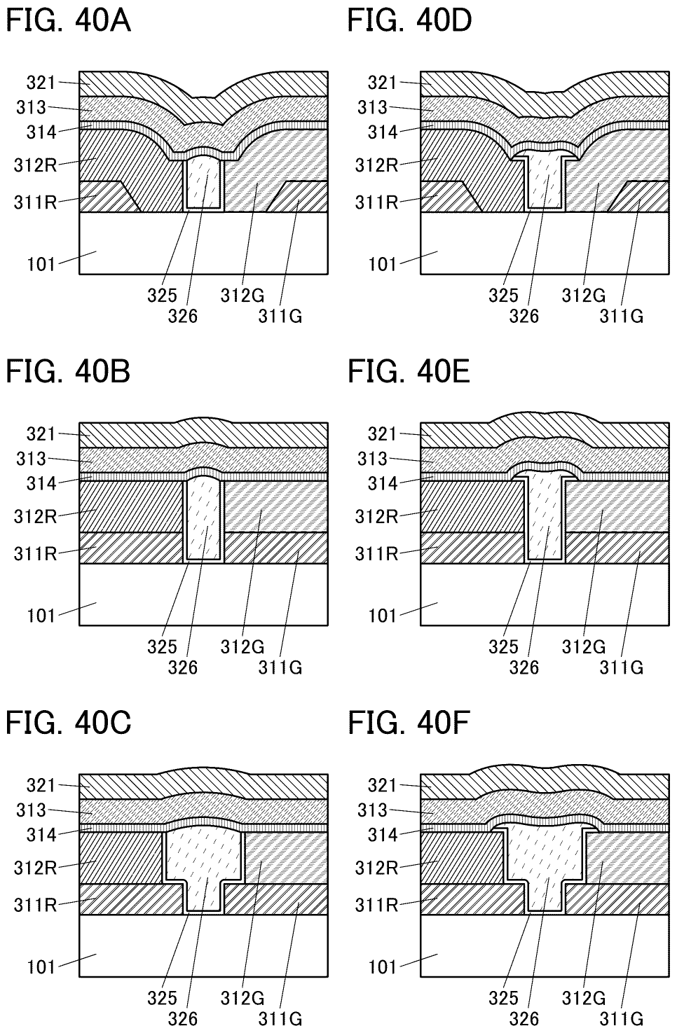

FIG. 39A to FIG. 40F are each an enlarged view of an end portion of the pixel electrode 311R included in the light-emitting element 61R, an end portion of the pixel electrode 311G included in the light-emitting element 61G, and the vicinity thereof.

FIG. 39A, FIG. 39B, and FIG. 39C are each an enlarged view of the resin layer 326 having a flat top surface and the vicinity thereof. FIG. 39A shows an example of the case where the organic layer 312R or the like has a larger width than the pixel electrode 311. FIG. 39B shows an example in which these widths are substantially the same. FIG. 39C shows an example of the case where the organic layer 312R or the like has a smaller width than the pixel electrode 311.

The organic layer 312R and the like is provided to cover the end portions of the pixel electrode 311 as illustrated in FIG. 39A, so that the end portion of the pixel electrode 311 is preferably tapered. Accordingly, the step coverage with the organic layer 312R and the like is improved and a highly reliable display device can be provided.

FIG. 39D, FIG. 39E, and FIG. 39F illustrate examples of the case where the top surface of the resin layer 326 has a depressed portion. Here, FIG. 39D corresponds to FIG. 39A, FIG. 39E corresponds to FIG. 39B, and FIG. 39F corresponds to FIG. 39C. In this case, a depressed portion that reflects the depressed top surface of the resin layer 326 is formed on each of top surfaces of the organic layer 314, the common electrode 313, and the protective layer 321.

FIG. 40A, FIG. 40B, and FIG. 40C illustrate examples of the case where the top surface of the resin layer 326 has a projecting portion. Here, FIG. 40A corresponds to FIG. 39A, FIG. 40B corresponds to FIG. 39B, and FIG. 40C corresponds to FIG. 39C. In this case, a projecting portion that reflects the projecting top surface of the resin layer 326 is formed on each of top surfaces of the organic layer 314, the common electrode 313, and the protective layer 321.

FIG. 40D, FIG. 40E, and FIG. 40F illustrate examples of the case where part of the resin layer 326 covers an upper end portion and part of the top surface of the organic layer 312R and an upper end portion and part of a top surface of the organic layer 312G. Here, FIG. 40D corresponds to FIG. 39A, FIG. 40E corresponds to FIG. 39B, and FIG. 40F corresponds to FIG. 39C. In this case, the insulating layer 325 is provided between the resin layer 326 and the top surfaces of the organic layer 312R and the organic layer 312G.

FIG. 40D, FIG. 40E, and FIG. 40F show examples of the case where the top surface of the resin layer 326 is partly depressed. In this case, unevenness that reflects the shape of the resin layer 326 is formed on each of the organic layer 314, the common electrode 313, and the protective layer 321.

The above is the description of the structure example of the resin layer.

The structure described in this embodiment can be used in an appropriate combination with any of the structures described in the other embodiments.

### Embodiment 6

In this embodiment, electronic devices in which the semiconductor device of one embodiment of the present invention can be used will be described.

The semiconductor device of one embodiment of the present invention can be used for a display portion of an electronic device. Thus, an electronic device having high display quality can be obtained. Alternatively, an electronic device with extremely high definition can be obtained. Alternatively, a highly reliable electronic device can be obtained.

Examples of electronic devices using the semiconductor device or the like of one embodiment of the present invention include display devices such as televisions and monitors, lighting devices, desktop or laptop personal computers, word processors, image reproduction devices that reproduce still images and moving images stored in recording media such as DVDs (Digital Versatile Discs), portable CD players, radios, tape recorders, headphone stereos, stereos, table clocks, wall clocks, cordless phone handsets, transceivers, car phones, mobile phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, electrical tools such as chain saws, smoke detectors, and medical equipment such as dialyzers. Other examples include industrial equipment such as guide lights, traffic lights, belt conveyors, elevators, escalators, industrial robots, power storage systems, and power storage devices for leveling the amount of power supply and smart grid. In addition, moving objects and the like driven by fuel engines and electric motors using power from power storage units may also be included in the category of electronic devices. Examples of the moving objects include electric vehicles (EVs), hybrid electric vehicles (HVs) that include both an internal-combustion engine and a motor, plug-in hybrid electric vehicles (PHVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic device of one embodiment of the present invention may include a secondary battery (battery), and it is preferable that the secondary battery be capable of being charged by contactless power transmission.

Examples of the secondary battery include a lithium-ion secondary battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display a video, information, and the like on a display portion. When the electronic device includes an antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, a smell, or infrared rays).

The electronic device of one embodiment of the present invention can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading a program or data stored in a recording medium.

Furthermore, an electronic device including a plurality of display portions can have a function of displaying image information mainly on one display portion while displaying text information mainly on another display portion, a function of displaying a three-dimensional image by displaying images on the plurality of display portions with a parallax taken into account, or the like. Furthermore, an electronic device including an image receiving portion can have a function of taking a still image or a moving image, a function of automatically or manually correcting a taken image, a function of storing a taken image in a recording medium (an external recording medium or a recording medium incorporated in the electronic device), a function of displaying a taken image on a display portion, or the like. Note that the functions of the electronic device of one embodiment of the present invention are not limited to these, and the electronic device can have a variety of functions.

The semiconductor device of one embodiment of the present invention can display a high-definition image. Thus, the semiconductor device can be suitably used especially for a portable electronic device, a wearable electronic device (wearable device), an e-book reader, and the like. For example, the semiconductor device can be suitably used for xR devices such as a VR device and an AR device.

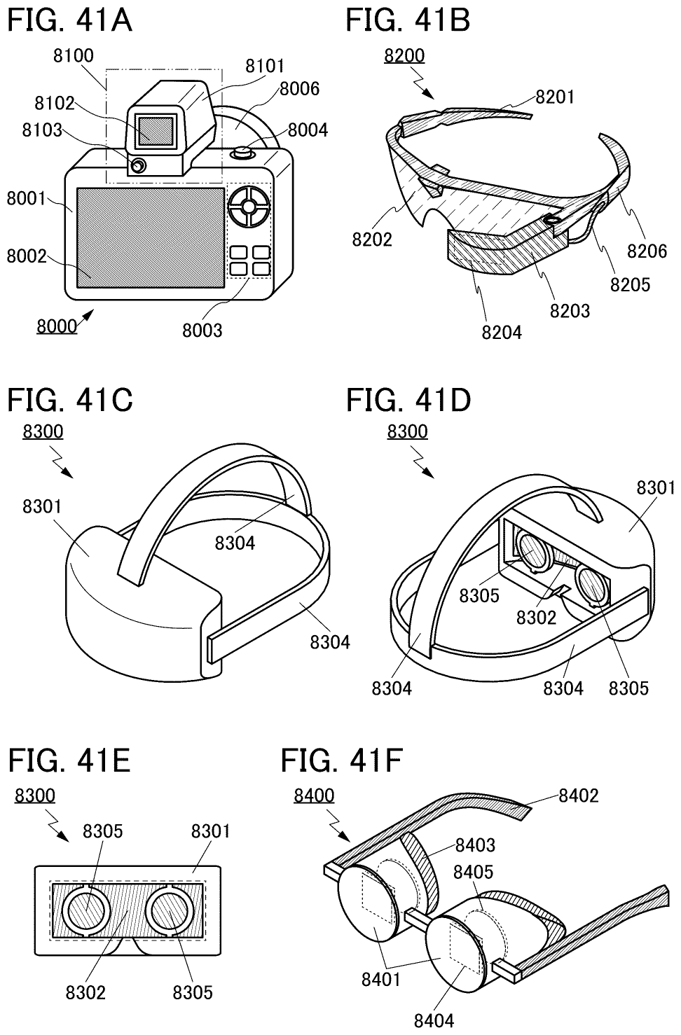

FIG. 41A is an external view of a camera 8000 to which a finder 8100 is attached.

The camera 8000 includes a housing 8001, a display portion 8002, operation buttons 8003, a shutter button 8004, and the like. Furthermore, a detachable lens 8006 is attached to the camera 8000. Note that the lens 8006 and the housing may be integrated with each other in the camera 8000.

Images can be taken with the camera 8000 at the press of the shutter button 8004 or the touch of the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 by a mount for engagement with the mount of the camera 8000. The finder 8100 can display a video and the like received from the camera 8000 on the display portion 8102.

The button 8103 functions as a power button or the like.

The semiconductor device of one embodiment of the present invention can be used in the display portion 8002 of the camera 8000 and the display portion 8102 of the finder 8100. Note that the finder 8100 may be incorporated in the camera 8000.

FIG. 41B is an external view of a head-mounted display 8200.

The head-mounted display 8200 includes a mounting portion 8201, a lens 8202, a main body 8203, a display portion 8204, a cable 8205, and the like. A battery 8206 is incorporated in the mounting portion 8201.

The cable 8205 supplies power from the battery 8206 to the main body 8203. The main body 8203 includes a wireless receiver or the like to receive video information and display it on the display portion 8204. The main body 8203 includes a camera, and information on the movement of the eyeballs or the eyelids of the user can be used as an input means.

The mounting portion 8201 may include a plurality of electrodes capable of sensing current flowing in response to the movement of the user's eyeball at a position in contact with the user to recognize the user's sight line. The mounting portion 8201 may also have a function of monitoring the user's pulse with the use of current flowing through the electrodes. The mounting portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, and the like.

The semiconductor device of one embodiment of the present invention can be used in the display portion 8204.

FIG. 41C to FIG. 41E are external views of a head-mounted display 8300. The head-mounted display 8300 includes a housing 8301, a display portion 8302, a band-like fixing member 8304, and a pair of lenses 8305.

A user can see display on the display portion 8302 through the lenses 8305. The display portion 8302 is preferably curved because the user can feel a high realistic sensation. Another image displayed on another region of the display portion 8302 is viewed through the lenses 8305, so that three-dimensional display using parallax or the like can be performed. Note that the number of display portions 8302 is not limited to one; two display portions 8302 may be provided for the user's respective eyes.

The semiconductor device of one embodiment of the present invention can be used for the display portion 8302. The semiconductor device of one embodiment of the present invention can achieve extremely high resolution. For example, a pixel is not easily seen by the user even when the user sees display that is magnified by the lenses 8305 as illustrated in FIG. 41E. That is, a video with a strong sense of reality can be seen by the user with the use of the display portion 8302.

FIG. 41F is an external view of a goggles-type head-mounted display 8400. The head-mounted display 8400 includes a pair of housings 8401, a mounting portion 8402, and a cushion 8403. A display portion 8404 and a lens 8405 are provided in each of the pair of housings 8401. Furthermore, when the pair of display portions 8404 display different images, three-dimensional display using parallax can be performed.

A user can see display on the display portion 8404 through the lens 8405. The lens 8405 has a focus adjustment mechanism and can adjust the position according to the user's eyesight. The display portion 8404 is preferably a square or a horizontal rectangle. This can improve a realistic sensation.

The mounting portion 8402 preferably has plasticity and elasticity so as to be adjusted to fit the size of the user's face and not to slide down. In addition, part of the mounting portion 8402 preferably has a vibration mechanism functioning as a bone conduction earphone. Thus, audio devices such as an earphone and a speaker are not necessarily provided separately, and the user can enjoy videos and sounds only by wearing the head-mounted display 8400. Note that the housing 8401 may have a function of outputting sound data by wireless communication.

The mounting portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge or the like whose surface is covered with cloth, leather (natural leather or synthetic leather), or the like is used, a gap is unlikely to be generated between the user's face and the cushion 8403, whereby light leakage can be suitably prevented. Furthermore, using such a material is preferable because it has a soft texture and the user does not feel cold when wearing the device in a cold season, for example. The member in contact with user's skin, such as the cushion 8403 or the mounting portion 8402, is preferably detachable because cleaning or replacement can be easily performed.

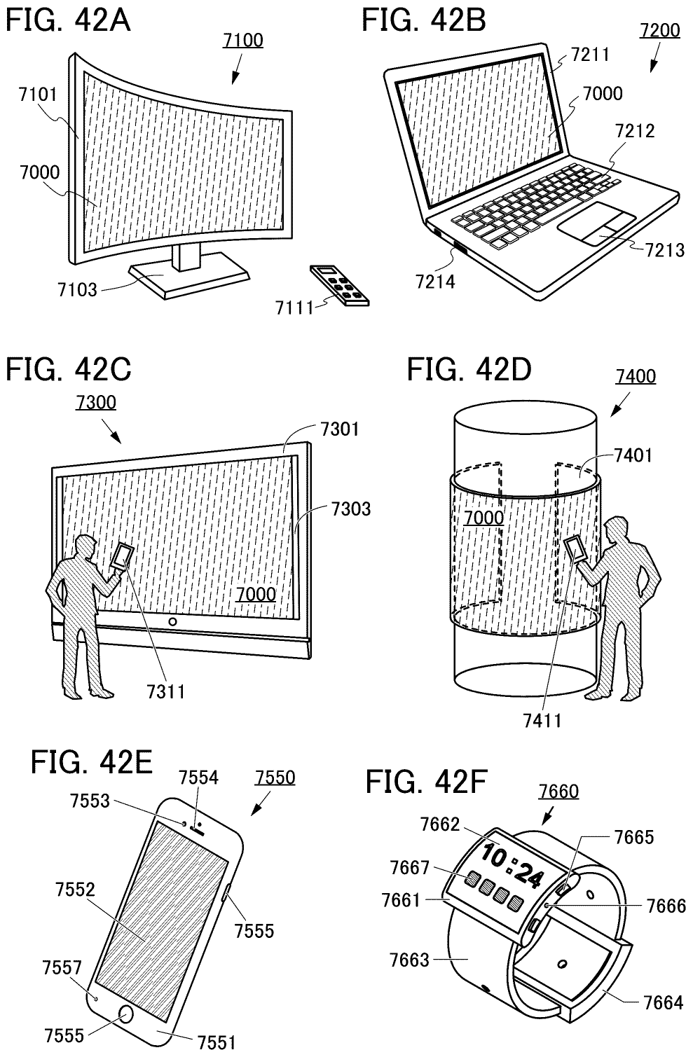

FIG. 42A illustrates an example of a television device. In a television device 7100, a display portion 7000 is incorporated in a housing 7101. Here, the housing 7101 is supported by a stand 7103.

The semiconductor device of one embodiment of the present invention can be used for the display portion 7000.

Operation of the television device 7100 illustrated in FIG. 42A can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 42B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The semiconductor device of one embodiment of the present invention can be used for the display portion 7000.

FIG. 42C and FIG. 42D illustrate examples of digital signage.

Digital signage 7300 illustrated in FIG. 42C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 42D illustrates digital signage 7400 attached to a cylindrical pillar 7401. The digital signage 7400 includes the display portion 7000 provided along a curved surface of the pillar 7401.

In FIG. 42C and FIG. 42D, the semiconductor device of one embodiment of the present invention can be used for the display portion 7000.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 42C and FIG. 42D, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

An information terminal 7550 illustrated in FIG. 42E includes a housing 7551, a display portion 7552, a microphone 7557, a speaker portion 7554, a camera 7553, operation switches 7555, and the like. The semiconductor device of one embodiment of the present invention can be used for the display portion 7552. The display portion 7552 has a touch panel function. The information terminal 7550 also includes an antenna, a battery, and the like inside the housing 7551. The information terminal 7550 can be used as, for example, a smartphone, a mobile phone, a tablet information terminal, a tablet personal computer, an e-book reader, or the like.

FIG. 42F illustrates an example of a watch-type information terminal. An information terminal 7660 includes a housing 7661, a display portion 7662, a band 7663, a buckle 7664, an operation switch 7665, an input/output terminal 7666, and the like. The information terminal 7660 also includes an antenna, a battery, and the like inside the housing 7661. The information terminal 7660 is capable of executing a variety of applications such as mobile phone calls, e-mailing, text viewing and editing, music reproduction, Internet communication, and computer games.

The display portion 7662 includes a touch sensor, and operation can be performed by touching the screen with a finger, a stylus, or the like. For example, by touching an icon 7667 displayed on the display portion 7662, an application can be started. With the operation switch 7665, a variety of functions such as time setting, power on/off, on/off of wireless communication, setting and cancellation of a silent mode, and setting and cancellation of a power saving mode can be performed. For example, the functions of the operation switch 7665 can be set by the operating system incorporated in the information terminal 7660.

The information terminal 7660 can execute near field communication conformable to a communication standard. For example, mutual communication between the information terminal 7660 and a headset capable of wireless communication enables hands-free calling. The information terminal 7660 includes the input/output terminal 7666, and can perform data transmission and reception with another information terminal through the input/output terminal 7666. Charging through the input/output terminal 7666 is also possible. Note that the charging operation may be performed by wireless power feeding without using the input/output terminal 7666.

The structure described in this embodiment can be used in an appropriate combination with any of the structures described in the other embodiments and the like.

### REFERENCE NUMERALS

100: semiconductor device, 101: substrate, 102: insulating layer, 103: semiconductor layer, 104: insulating layer, 105: conductive layer, 106: insulating layer, 107: opening, 108: conductive layer, 109: insulating layer, 110: insulating layer, 111: insulating layer

1. A semiconductor device comprising:
a first semiconductor layer provided over an insulating surface;
a first insulating layer over the first semiconductor layer;
a first conductive layer over the first insulating layer;
a second conductive layer electrically connected to the first semiconductor layer;
a third conductive layer electrically connected to the first semiconductor layer;
a second insulating layer covering the first conductive layer, the second conductive layer, and the third conductive layer;
a third insulating layer over the second insulating layer;
a fourth insulating layer over the third insulating layer;
a fourth conductive layer over the fourth insulating layer;
an opening penetrating the second insulating layer, the third insulating layer, the fourth insulating layer, and the fourth conductive layer;
a second semiconductor layer comprising a region covering a side surface and a bottom portion of the opening;
a fifth insulating layer comprising a region overlapping with the side surface of the opening and a region overlapping with the bottom portion of the opening, with the second semiconductor layer therebetween; and
a fifth conductive layer comprising a region overlapping with the side surface of the opening and a region overlapping with the bottom portion of the opening, with the second semiconductor layer and the fifth insulating layer therebetween,
wherein the second semiconductor layer and the second conductive layer are electrically connected to each other.

2. The semiconductor device according to claim 1, wherein the second semiconductor layer comprises a region overlapping with the first semiconductor layer with the second conductive layer therebetween.

3. A semiconductor device comprising:
a first semiconductor layer provided over an insulating surface;
a first insulating layer over the first semiconductor layer;
a first conductive layer over the first insulating layer;
a second conductive layer electrically connected to the first semiconductor layer;
a third conductive layer electrically connected to the first semiconductor layer;
a second insulating layer covering the first conductive layer, the second conductive layer, and the third conductive layer;
a third insulating layer over the second insulating layer;
a fourth insulating layer over the third insulating layer;
a fourth conductive layer over the fourth insulating layer;
an opening penetrating the second insulating layer, the third insulating layer, the fourth insulating layer, and the fourth conductive layer;
a second semiconductor layer comprising a region covering a side surface and a bottom portion of the opening;
a fifth insulating layer comprising a region overlapping with the side surface of the opening and a region overlapping with the bottom portion of the opening, with the second semiconductor layer therebetween; and
a fifth conductive layer comprising a region overlapping with the side surface of the opening and a region overlapping with the bottom portion of the opening, with the second semiconductor layer and the fifth insulating layer therebetween,
wherein the second semiconductor layer and the first conductive layer are electrically connected to each other.

4. The semiconductor device according to claim 1, wherein the first semiconductor layer comprises a Group 13 element.

5. The semiconductor device according to claim 1, wherein the first semiconductor layer comprises a Group 15 element.

6. The semiconductor device according to claim 1, wherein the second insulating layer comprises silicon and nitrogen.

7. The semiconductor device according to claim 1, wherein the third insulating layer comprises silicon and oxygen.

8. The semiconductor device according to claim 1, wherein the fourth insulating layer comprises silicon and nitrogen.

9. The semiconductor device according to claim 1, wherein the first semiconductor layer has a composition different from a composition of the second semiconductor layer.

10. The semiconductor device according to claim 1, wherein the first semiconductor layer comprises silicon.

11. The semiconductor device according to claim 1, wherein the second semiconductor layer comprises an oxide semiconductor.

12. The semiconductor device according to claim 11, wherein the oxide semiconductor comprises one or both of indium and zinc.

13. The semiconductor device according to claim 3, wherein the first semiconductor layer comprises a Group 13 element.

14. The semiconductor device according to claim 3, wherein the first semiconductor layer comprises a Group 15 element.

15. The semiconductor device according to claim 3, wherein the second insulating layer comprises silicon and nitrogen.

16. The semiconductor device according to claim 3, wherein the third insulating layer comprises silicon and oxygen.

17. The semiconductor device according to claim 3, wherein the fourth insulating layer comprises silicon and nitrogen.

18. The semiconductor device according to claim 3, wherein the first semiconductor layer has a composition different from a composition of the second semiconductor layer.

19. The semiconductor device according to claim 3, wherein the first semiconductor layer comprises silicon.

20. The semiconductor device according to claim 3, wherein the second semiconductor layer comprises an oxide semiconductor.

21. The semiconductor device according to claim 20, wherein the oxide semiconductor comprises one or both of indium and zinc.
